(19) United States
(12) Patent Application Publication
(10) Pub. No.: US 2023/0305403 A1
(43) Pub. Date: Sep. 28, 2023

(54) PATTERN FORMING METHOD, MANUFACTURING METHOD OF CIRCUIT BOARD, AND LAMINATE

(71) Applicant: FUJIFILM Corporation, Tokyo (JP)

(72) Inventors: Akio KATAYAMA, Shizuoka (JP); Soji ISHIZAKA, Shizuoka (JP); Morimasa SATO, Shizuoka (JP)

(73) Assignee: FUJIFILM Corporation, Tokyo (JP)

(21) Appl. No.: 18/057,495

(22) Filed: Nov. 21, 2022

Related U.S. Application Data
(63) Continuation of application No. PCT/JP2021/019393, filed on May 21, 2021.

(30) Foreign Application Priority Data
May 22, 2020 (JP) 2020-090044
Jul. 31, 2020 (JP) 2020-130726
Sep. 30, 2020 (JP) 2020-165594
Nov. 30, 2020 (JP) 2020-199018
Dec. 24, 2020 (JP) 2020-215028
Apr. 16, 2021 (JP) 2021-069927

(51) Int. Cl. G03F 7/095; G03F 7/20; G03F 7/26

(52) U.S. Cl. CPC G03F 7/095; G03F 7/26; G03F 7/2022

(57) ABSTRACT

Provided are a pattern forming method which includes a step of preparing a laminate having a first photosensitive layer, a substrate having a region transparent to an exposure wavelength, and a second photosensitive layer in this order, a step of exposing the first photosensitive layer, a step of exposing the second photosensitive layer, a step of developing the exposed first photosensitive layer to form a first resin pattern, and a step of developing the exposed second photosensitive layer to form a second resin pattern, and in which a dominant wavelength λ₁ of an exposure wavelength in the step of exposing the first photosensitive layer and a dominant wavelength λ₂ of an exposure wavelength in the step of exposing the second photosensitive layer satisfy a relation of λ₁ ≠ λ₂, a laminate, and applications of these.

### CROSS-REFERENCE TO RELATED APPLICATIONS

This application is a continuation application of International Application No. PCT/JP2021/019393, filed May 21, 2021, the disclosure of which is incorporated herein by reference in its entirety. Further, this application claims priority from Japanese Patent Application No. 2020-090044, filed May 22, 2020, Japanese Patent Application No. 2020-130726, filed Jul. 31, 2020, Japanese Patent Application No. 2020-165594, filed Sep. 30, 2020, Japanese Patent Application No. 2020-199018, filed Nov. 30, 2020, Japanese Patent Application No. 2020-215028, filed Dec. 24, 2020, and Japanese Patent Application No. 2021-069927, filed Apr. 16, 2021, the disclosures of which are incorporated herein by reference in their entirety.

### BACKGROUND OF THE INVENTION

### 1. Field of the Invention

The present disclosure relates to a pattern forming method, a manufacturing method of a circuit board, and a laminate.

### 2. Description of the Related Art

For example, in the field of touch panels, for manufacturing a touch sensor, a method of forming a pattern on both surfaces of a film-like substrate is used. For example, by a photolithography in which photosensitive layers disposed on both surfaces of a substrate having excellent light shielding properties, such as copper, are exposed and then developed, it is possible to form a resin pattern on both surfaces of the substrate.

Incidentally, in a case where the same process as the aforementioned photolithography is used to form a resin pattern on both surfaces of a transparent conductive film substrate, and a photosensitive layer disposed on one surface of the transparent substrate is exposed in a step of exposing the disposed photosensitive layer, sometimes a phenomenon where a photosensitive layer disposed on the other surface of the transparent substrate is also exposed occurs (hereinafter, called “exposure fogging”). In a case where exposure fogging occurs, it is difficult to process the photosensitive layers disposed on both surfaces of the transparent substrate into a desired shape.

As a technique of suppressing the occurrence of exposure fogging, for example, a pattern forming method using a photosensitive layer having optical density controlled to fall into a specific range has been proposed (see WO2016/022090A).

### SUMMARY OF THE INVENTION

The optical density of a photosensitive layer can be adjusted, for example, by adding an ultraviolet absorbing material (for example, carbon black) to the photosensitive layer (see WO2016/022090A). However, for example, in a case where the ultraviolet absorbing material is used to increase the optical density of a photosensitive layer (that is, to reduce the transmittance of the photosensitive layer), sometimes the reactivity of the photosensitive layer is affected. As a result, for example, the resolution of the obtained resin pattern is likely to deteriorate, or the exposure sensitivity is likely to decrease and lead to deterioration of process suitability.

The present disclosure has been made in consideration of the circumstances described above.

An object of one aspect of the present disclosure is to provide a pattern forming method capable of suppressing the occurrence of exposure fogging and forming a resin pattern having excellent resolution.

An object of another aspect of the present disclosure is to provide a manufacturing method of a circuit board that uses a pattern forming method capable of suppressing the occurrence of exposure fogging and forming a resin pattern having excellent resolution.

An object of still another aspect of the present disclosure is to provide a laminate capable of suppressing the occurrence of exposure fogging and making it possible to form a resin pattern having excellent resolution.

The present disclosure includes the following aspects.
<1> A pattern forming method including a step of preparing a laminate having a first photosensitive layer, a substrate having a region transparent to an exposure wavelength, and a second photosensitive layer in this order, a step of exposing the first photosensitive layer, a step of exposing the second photosensitive layer, a step of developing the exposed first photosensitive layer to form a first resin pattern, and a step of developing the exposed second photosensitive layer to form a second resin pattern, in which a dominant wavelength λ₁ of an exposure wavelength in the step of exposing the first photosensitive layer and a dominant wavelength λ₂ of an exposure wavelength in the step of exposing the second photosensitive layer satisfy a relation of λ₁ ≠ λ₂.
<2> The pattern forming method described in <1>, in which a photosensitive compound contained in the first photosensitive layer is different from a photosensitive compound contained in the second photosensitive layer.
<3> The pattern forming method described in <1> or <2>, in which the following relations 1 and 2 are satisfied for the first photosensitive layer and the second photosensitive layer.
$$1.1 \leq {\text{E}}_{1 \text{r}} / {\text{E}}_{2} \qquad \text{Relation 1:}$$
$$1.1 \leq {\text{E}}_{2 \text{r}} / {\text{E}}_{1} \qquad \text{Relation 2:}$$
E₁ᵣ represents a maximum exposure amount at which the first photosensitive layer does not react in a case where the first photosensitive layer is exposed to light having the dominant wavelength λ₂ from a side of the second photosensitive layer of the laminate, E₂ represents an exposure amount in a case where the second photosensitive layer is exposed to light having the dominant wavelength λ₂ in the step of exposing the second photosensitive layer, E₂ᵣ represents a maximum exposure amount at which the second photosensitive layer does not react in a case where the second photosensitive layer is exposed to light having the dominant wavelength λ₁ from a side of the first photosensitive layer of the laminate, and E₁ represents an exposure amount in a case where the first photosensitive layer is exposed to light having the dominant wavelength λ₁ in the step of exposing the first photosensitive layer.
<4> The pattern forming method described in any one of <1> to <3>, in which the following relations 3 and 4 are satisfied for the first photosensitive layer and the second photosensitive layer.
$$3 \leq {\text{S}}_{12} / {\text{S}}_{11} \qquad \text{Relation 3:}$$
$$2 \leq {\text{S}}_{21} / {\text{S}}_{22} \qquad \text{Relation 4:}$$
S₁₂ represents a spectral sensitivity of the first photosensitive layer to the dominant wavelength λ₂, S₁₁ represents a spectral sensitivity of the first photosensitive layer to the dominant wavelength λ₁, S₂₁ represents a spectral sensitivity of the second photosensitive layer to the dominant wavelength λ₁, and S₂₂ represents a spectral sensitivity of the second photosensitive layer to the dominant wavelength λ₂.
<5> The pattern forming method described in any one of < 1> to <4>, in which the first photosensitive layer contains a substance absorbing light having the dominant wavelength λ₂, and/or the second photosensitive layer contains a substance absorbing light having the dominant wavelength λ₁.
<6> The pattern forming method described in any one of <1> to <5>, in which the laminate has at least one layer selected from the group consisting of a layer that is disposed between the substrate and the first photosensitive layer and contains a substance absorbing light having the dominant wavelength λ₂, a layer that is disposed on the substrate via the first photosensitive layer and contains a substance absorbing light having the dominant wavelength λ₂, a layer that is disposed between the substrate and the second photosensitive layer and contains a substance absorbing light having the dominant wavelength λ₁, and a layer that is disposed on the substrate via the second photosensitive layer and contains a substance absorbing light having the dominant wavelength λ₁.
<7> The pattern forming method described in <5> or <6>, in which either the substance absorbing light having the dominant wavelength λ₂ or the substance absorbing light having the dominant wavelength λ₁ is a substance having a maximum absorption wavelength λₘₐₓ in a wavelength range of 400 nm or more.
<8> The pattern forming method described in any one of <1> to <7>, in which a member absorbing light having the dominant wavelength λ₂ is disposed between the first photosensitive layer and a light source for exposing the first photosensitive layer and/or a member absorbing light having the dominant wavelength λ₁ is disposed between the second photosensitive layer and a light source for exposing the second photosensitive layer.
<9> The pattern forming method described in <8>, in which either the member absorbing light having the dominant wavelength λ₂ or the member absorbing light having the dominant wavelength λ₁ is a member containing a substance having a maximum absorption wavelength λₘₐₓ in a wavelength range of 400 nm or more.
<10> The pattern forming method described in any one of <1> to <9>, in which the step of exposing the first photosensitive layer and the step of exposing the second photosensitive layer are simultaneously performed.
<11> The pattern forming method described in any one of < 1 > to <9>, in which the step of exposing the first photosensitive layer and the step of exposing the second photosensitive layer are separately performed.
<12> The pattern forming method described in any one of <1> to <11 >, in which the step of developing the exposed first photosensitive layer to form a first resin pattern and the step of developing the exposed second photosensitive layer to form a second resin pattern are simultaneously performed.
<13> The pattern forming method described in any one of <1> to <11>, in which the step of developing the exposed first photosensitive layer to form a first resin pattern and the step of developing the exposed second photosensitive layer to form a second resin pattern are separately performed.
<14> The pattern forming method described in any one of <1> to <13>, in which the laminate has at least one conductive layer on at least one surface of the substrate.
<15> The pattern forming method described in any one of <1> to <13>, in which the laminate has at least one conductive layer on both surfaces of the substrate.
<16> The pattern forming method described in any one of <1> to <13>, in which the laminate has at least one conductive layer on at least one surface of the substrate, and a conductive layer having a composition different from a composition of the conductive layer is additionally formed on at least a partial region of the conductive layer.
<17> The pattern forming method described in any one of <1> to <13>, in which the laminate has at least one conductive layer on at least one surface of the substrate, and the conductive layer has two or more regions having different compositions within the substrate.
<18> The pattern forming method described in any one of <14> to <17>, in which at least one of the conductive layers is a layer containing a metal oxide.
<19> The pattern forming method described in any one of <14> to <17>, in which at least one of the conductive layers is a layer containing at least one material selected from the group consisting of metal nanowires and metal nanoparticles.
<20> The pattern forming method described in any one of <14> to <19>, further including a step of etching the conductive layers by using at least either the first resin pattern or the second resin pattern as a mask.
<21> The pattern forming method described in any one of <1> to <20>, in which the first photosensitive layer is a negative tone photosensitive layer whose solubility in a developer decreases by exposure.
<22> The pattern forming method described in any one of <1> to <20>, in which the first photosensitive layer is a positive tone photosensitive layer whose solubility in a developer increases by exposure.
<23> The pattern forming method described in any one of <1> to <22>, in which the second photosensitive layer is a negative tone photosensitive layer whose solubility in a developer decreases by exposure.
<24> The pattern forming method described in any one of <1> to <22>, in which the second photosensitive layer is a positive tone photosensitive layer whose solubility in a developer increases by exposure.
<25> The pattern forming method described in any one of <1> to <24>, in which the exposure wavelength in the step of exposing the first photosensitive layer does not include a wavelength of 365 nm.
<26> The pattern forming method described in <25>, in which the exposure wavelength in the step of exposing the second photosensitive layer does not include a wavelength of 405 nm.
<27> The pattern forming method described in any one of <1> to <24>, in which the exposure wavelength in the step of exposing the first photosensitive layer does not include a wavelength of 405 nm.
<28> The pattern forming method described in <27>, in which the exposure wavelength in the step of exposing the second photosensitive layer does not include a wavelength of 365 nm.
<29> A manufacturing method of a circuit board, including the pattern forming method described in any one of <1> to <28>.
<30> A laminate comprising a first photosensitive layer, a substrate, and a second photosensitive layer in this order, in which the laminate has the following characteristics A and B.
   Characteristic A: in a case where λₘ₁ represents a maximum sensitivity wavelength of the first photosensitive layer and λₘ₂ represents a maximum sensitivity wavelength of the second photosensitive layer, λₘ₁ and λₘ₂ satisfy a relation of λₘ₁ ≠ λₘ₂. The maximum sensitivity wavelength refers to a wavelength at which a minimum exposure amount is the smallest in a case where the minimum exposure amount at which the photosensitive layers react is determined as a spectral sensitivity for each wavelength of light.
   Characteristic B: the substrate has a transmittance of at least 50% or more for light having the wavelengths λₘ₁ and λₘ₂.
<31> The laminate described in <30>, in which the wavelength λₘ₁ is in a range of more than 395 nm and 500 nm or less, and the wavelength λₘ₂ is in a range of 250 nm or more and 395 nm or less.
<32> The laminate described in <30> or <31>, in which the first photosensitive layer contains a substance absorbing light having the wavelength λₘ₂.
<33> The laminate described in any one of <30> to <32>, in which the second photosensitive layer contains a substance absorbing light having the wavelength λₘ₁.
<34> The laminate described in any one of <30> to <33>, in which the following relations C and D are satisfied for the first photosensitive layer and the second photosensitive layer.
$$3 \leq {\text{S}}_{\text{m12}} / {\text{S}}_{\text{m11}} \qquad \text{Relation C:}$$
$$3 \leq {\text{S}}_{\text{m21}} / {\text{S}}_{\text{m22}} \qquad \text{Relation D:}$$
Sₘ₁₂ represents a spectral sensitivity of the first photosensitive layer to the wavelength λₘ₂, Sₘ₁₁ represents a spectral sensitivity of the first photosensitive layer to the wavelength λₘ₁, Sₘ₂₁ represents a spectral sensitivity of the second photosensitive layer to the wavelength λₘ₁, and Sₘ₂₂ represents a spectral sensitivity of the second photosensitive layer to the wavelength λₘ₂.
<35> The laminate described in any one of <30> to <34>, in which the first photosensitive layer has a transmittance of 70% or less for light having the wavelength λₘ₂.
<36> The laminate described in any one of <30> to <35>, in which the second photosensitive layer has a transmittance of 70% or less for light having the wavelength λₘ₁.
<37> The laminate described in any one of <30> to <36>, in which the laminate includes at least one conductive layer on at least one surface of the substrate.
<38> The laminate described in any one of <30> to <37>, in which the laminate includes at least one conductive layer on at least one surface of the substrate, and on at least a partial region of the conductive layer, a conductive layer having a composition different from a composition of the conductive layer is additionally formed.
<39> The laminate described in any one of <30> to <37>, in which the laminate includes at least one conductive layer on at least one surface of the substrate, and the conductive layer has two or more regions having different compositions within the substrate.
<40> The laminate described in any one of <30> to <39>, in which the laminate includes at least one conductive layer on both surfaces of the substrate.
<41> The laminate described in any one of <37> to <40>, in which at least one of the conductive layers is a layer containing a metal oxide.
<42> The laminate described in any one of <37> to <41>, in which at least one of the conductive layers is a layer containing at least one material selected from the group consisting of metal nanowires and metal nanoparticles.
<43> The laminate described in any one of <30> to <42>, in which the first photosensitive layer is a negative tone photosensitive layer.
<44> The laminate described in any one of <30> to <43>, in which the second photosensitive layer is a negative tone photosensitive layer.
<45> The laminate described in any one of <30> to <42>, in which the first photosensitive layer is a positive tone photosensitive layer.
<46> The laminate described in any one of <30> to <43> and <45>, in which the second photosensitive layer is a positive tone photosensitive layer.
<47> The laminate described in any one of <30> to <46>, in which the wavelength λₘ₂ is in a range of 335 nm or more and 395 nm or less.
<48> The laminate described in any one of <30> to <47>, in which the wavelength λₘ₁ is in a range of 396 nm or more and 456 nm or less.

According to an aspect of the present disclosure, there is provided a pattern forming method capable of suppressing the occurrence of exposure fogging and forming a resin pattern having excellent resolution.

According to another aspect of the present disclosure, there is provided a manufacturing method of a circuit board that uses a pattern forming method capable of suppressing the occurrence of exposure fogging and forming a resin pattern having excellent resolution.

According to a still another aspect of the present disclosure, there is provided a laminate capable of suppressing the occurrence of exposure fogging and making it possible to form a resin pattern having excellent resolution.

### DESCRIPTION OF THE PREFERRED EMBODIMENTS

Hereinafter, embodiments of the present disclosure will be specifically described. The present disclosure is not limited to the following embodiments, and can be embodied with appropriate modifications within the scope of the objects of the present disclosure.

In the present disclosure, a range of numerical values described using “to” means a range including the numerical values listed before and after “to” as the lower limit and the upper limit. Regarding the numerical ranges described in stages in the present disclosure, the upper or lower limit of a numerical range may be replaced with the upper or lower limit of another numerical range described in stages. Furthermore, regarding the numerical ranges described in the present disclosure, the upper or lower limit of a numerical range may be replaced with values described in examples.

In the present disclosure, “(meth)acryloyl” means either or both of acryloyl and methacryloyl, and “(meth)acrylate” means either or both of acrylate and methacrylate.

In the present disclosure, in a case where there is a plurality of substances in a composition that corresponds to each component of the composition, unless otherwise specified, the amount of each component in the composition means the total amount of the plurality of substances present in the composition.

In the present disclosure, the term “step” includes not only an independent step, but also a step that is not clearly distinguished from other steps as long as the step achieves the intended goal.

Regarding the groups (atomic groups) described in the present disclosure, in a case where a group is simply mentioned without being described in terms of whether it is substituted or unsubstituted, such a group includes both the group having no substituent and group having a substituent. For example, “alkyl group” includes not only an alkyl group having no substituent (unsubstituted alkyl group) but also an alkyl group having a substituent (substituted alkyl group).

In the present disclosure, “% by mass” has the same definition as “% by weight”, and “part by mass” has the same definition as “part by weight”.

In the present disclosure, the combination of two or more preferred aspects is a more preferred aspect.

In the present disclosure, some of the chemical structural formulas may be described as a simplified structural formula from which a hydrogen atom is omitted.

In the present disclosure, “solid content” refers to the components of a composition excluding solvents.

In the present disclosure, unless otherwise specified, each of the weight-average molecular weight (Mw) and number-average molecular weight (Mn) is a molecular weight that is measured using a gel permeation chromatography (GPC) analysis device (columns: “TSKgel GMHxL, TSKgel G4000HxL” (manufactured by Tosoh Corporation) and TSKgel G2000HxL (manufactured by Tosoh Corporation), detector: differential refractometer, solvent: tetrahydrofuran (THF)) and expressed in terms of polystyrene used as a standard substance.

In the present disclosure, the ordinal numerals (for example, “the first” and “the second”) are terms used to distinguish constituents and do not limit the number of constituents and the superiority or inferiority of constituents.

### Pattern Forming Method

The pattern forming method according to the present disclosure includes a step of preparing a laminate having a first photosensitive layer, a substrate having a region transparent to an exposure wavelength, and a second photosensitive layer in this order (hereinafter, called “preparation step” in some cases), a step of exposing the first photosensitive layer (hereinafter, called “exposure step (1)” in some cases), a step of exposing the second photosensitive layer (hereinafter, called “exposure step (2)” in some cases), a step of developing the exposed first photosensitive layer to form a first resin pattern (hereinafter, called “developing step (1)” in some cases), and a step of developing the exposed second photosensitive layer to form a second resin pattern (hereinafter, called “developing step (2)” in some cases), in which a dominant wavelength λ₁ of an exposure wavelength in the step of exposing the first photosensitive layer and a dominant wavelength λ₂ of an exposure wavelength in the step of exposing the second photosensitive layer satisfy a relation of λ₁ ≠ λ₂ (hereinafter, called “specific exposure condition” in some cases).

Comprising the above steps, the pattern forming method according to the present disclosure can suppress the occurrence of exposure fogging and form a resin pattern having excellent resolution. The reason why the pattern forming method according to the present disclosure has the above effects is presumed as follows. As described above, for example, in a case where an ultraviolet absorbing material is used to increase the optical density of a photosensitive layer such that the occurrence of exposure fogging is suppressed, the resolution of the obtained resin pattern is likely to deteriorate. On the other hand, the pattern forming method according to the present disclosure includes the preparation step, the exposure step (1), the exposure step (2), the developing step (1), and the developing step (2), and the dominant wavelength λ₁ of the exposure wavelength in the exposure step (1) is different from the dominant wavelength λ₂ of the exposure wavelength in the exposure step (2), which enables the first photosensitive layer and the second photosensitive layer to be exposed selectively or exposed by priority. Therefore, the pattern forming method according to the present disclosure can suppress the occurrence of exposure fogging and can form a resin pattern having excellent resolution.

In the present disclosure, “exposure wavelength” means the wavelength of light that is radiated in a case where a photosensitive layer is exposed, and reaches the photosensitive layer. For example, in a case where a photosensitive layer is exposed through a filter having wavelength selectivity, the wavelength of light not yet passing through the filter does not correspond to the exposure wavelength. “Wavelength selectivity” means the properties of transmitting light in a specific wavelength range. In the present disclosure, the wavelength and intensity of light are measured using a known spectroscope (for example, RPS900-R, manufactured by INTERNATIONAL LIGHT TECHNOLOGIES INC.).

In the present disclosure, “dominant wavelength” refers to the wavelength of light with the highest intensity among the wavelengths (that is, exposure wavelengths) of light reaching a photosensitive layer. For example, in a case where the light reaching a photosensitive layer is exposure light that has wavelengths of 365 nm and 405 nm and exhibits higher intensity at the wavelength of 365 nm than at the wavelength of 405 nm, the dominant wavelength of the exposure light is 365 nm. In the present disclosure, “exposure light” means light used to expose a photosensitive layer.

Each step of the pattern forming method according to the present disclosure will be specifically described below.

### Preparation Step

The pattern forming method according to the present disclosure includes a step of preparing a laminate having a first photosensitive layer, a substrate having a region transparent to an exposure wavelength (hereinafter, simply called “substrate” in some cases), and a second photosensitive layer in this order.

In the present disclosure, “preparing a laminate” means putting the laminate in a usable condition. Unless otherwise specified, “preparing a laminate” includes preparing a pre-manufactured laminate and manufacturing a laminate. That is, the laminate used in the pattern forming method according to the present disclosure may be a pre-manufactured laminate or a laminate manufactured in the preparation step.

In the pattern forming method according to the present disclosure, as the laminate, the laminate according to the present disclosure that will be described later can be suitably used.

### Substrate

The laminate has a substrate having a region transparent to an exposure wavelength. The substrate is disposed between the first photosensitive layer and the second photosensitive layer.

In the present disclosure, “region transparent to an exposure wavelength” means a region having a transmittance of 30% or more for the dominant wavelength among exposure wavelengths. The transmittance is preferably 50% or more, more preferably 60% or more, even more preferably 80% or more, and particularly preferably 90% or more. The upper limit of the transmittance is not limited. The transmittance may be determined, for example, in a range of 100% or less. The transmittance is measured using a known transmittance measuring instrument (for example, V-700 series manufactured by JASCO Corporation).

The region transparent to an exposure wavelength may be disposed on the entire substrate or on a part of the substrate. It is preferable that the region transparent to an exposure wavelength be disposed in a portion corresponding to an exposed portion in the exposure step. The region transparent to an exposure wavelength is preferably disposed on the entire substrate. That is, the substrate is preferably a substrate transparent to an exposure wavelength.

Examples of materials of the substrate include a resin material and an inorganic material.

Examples of the resin material include polyesters (for example, polyethylene terephthalate and polyethylene naphthalate), polyetheretherketones, acrylic resins, cycloolefin polymers, and polycarbonates.

Examples of the inorganic material include glass and quartz.

The substrate is preferably a resin film which is preferably a polyethylene terephthalate film, a polyethylene naphthalate film, or a cycloolefin polymer film.

The thickness of the substrate is not limited. From the viewpoint of transport properties, electrical characteristics, and film-forming properties, the average thickness of the substrate is preferably 10 µm to 100 µm, and more preferably 10 µm to 60 µm The average thickness of the substrate is the average of thicknesses at 10 sites measured by observing a cross section perpendicular to the in-plane direction of the substrate by using a scanning electron microscope (SEM).

### Conductive Layer

It is preferable that the substrate have a conductive layer. Specifically, the laminate preferably has at least one conductive layer on at least one surface of the substrate. More preferably, the laminate has at least one conductive layer on both surfaces of the substrate. The conductive layer preferably has a region transparent to an exposure wavelength.

In the present disclosure, “conductive” means having a volume resistivity of less than 1 × 10⁶ Ωcm. The volume resistivity showing conductivity is preferably less than 1 × 10⁴ Ωcm. The volume resistivity is measured using a known resistivity meter (for example, a resistance measuring instrument EC-80P, manufactured by NAPSON CORPORATION).

From the viewpoint of conductivity, it is preferable that the conductive layer contain a metal. Examples of the metal include copper, silver, tin, palladium, gold, nickel, chromium, platinum, iron, gallium, and indium. The metal may be a single metal or an alloy. Examples of the alloy include copper alloys and silver alloys.

From the viewpoint of conductivity, the conductive layer preferably contains at least one metal selected from the group consisting of copper, silver, tin, and indium.

The transparent conductive layer may contain one metal or two or more metals.

Examples of specific conductive layers include a layer containing a metal oxide, a layer containing metal nanoparticles, and a layer containing metal nanowires. In an embodiment, at least one of the conductive layers included in the laminate is preferably a layer containing a metal oxide. In an embodiment, at least one of the conductive layers included in the laminate is preferably a layer containing at least one material selected from the group consisting of metal nanowires and metal nanoparticles. Examples of the metal oxide include indium tin oxide (ITO), indium zinc oxide (IZO), zinc oxide (ZnO), IGZO (registered trademark; a sort of oxide semiconductor containing indium (In), gallium (Ga), zinc (Zn), and oxygen (O)). Examples of the metal nanoparticles include metal nanoparticles such as silver nanoparticles, copper nanoparticles, gold nanoparticles, and platinum nanoparticles. Examples of the metal nanowires include silver nanowires, copper nanowires, gold nanowires, and platinum nanowires. From the viewpoint of transparency, at least one of the components of the conductive layer is preferably ITO, silver nanoparticles, or silver nanowires.

The thickness of the conductive layer is not limited. From the viewpoint of conductivity and film-forming properties, the average thickness of the conductive layer is preferably 0.001 µm to 1,000 µm, more preferably 0.005 µm to 15 µm, and particularly preferably 0.01 µm to 10 µm The average thickness of the conductive layer is measured by a method based on the method of measuring the average thickness of the substrate described above.

As theThe method of forming the conductive layer, known methods can be used without limitation. Examples of the method of forming the conductive layer include coating, vacuum vapor deposition, sputtering, and plating.

After the conductive layer is formed, another layer may be additionally formed in a partial region or the entire region of the conductive layer. For example, for the purpose of laminating another conductive layer, protecting the conductive layer, controlling the adhesiveness with a photosensitive layer, or controlling electrical characteristics, another layer may be formed on the conductive layer. The aforementioned another layer may be a layer composed of an organic substance, a layer composed of an inorganic substance, a layer in which an inorganic substance is dispersed in an organic matrix, or a layer in which an organic substance is dispersed in an inorganic matrix. Examples of the method of forming the aforementioned another layer include, but are not limited to, forming a conductive layer containing silver nanowires and then forming a protective film composed of an organic substance, forming a conductive layer containing gold nanowires and then forming an adhesive layer, and the like.

In a case where another conductive layer is to be laminated, a layer having a composition based on the above description may be laminated. Examples of the method of laminating another conductive layer include, but are not limited to, a method of forming a conductive layer containing silver nanowires and then forming a layer containing silver nanoparticles on a partial region or the entire region of the conductive layer, a method of forming a conductive layer containing ITO and then forming a layer containing copper on a partial region or the entire region of the conductive layer, and the like.

As means for forming the aforementioned another layer, for example, known methods such as coating, vacuum vapor deposition, sputtering, and lamination can be used.

The conductive layer may have a mix of regions having different compositions in the same plane. Examples of such a conductive layer include, but are not limited to, a conductive layer having a mix of a region having silver nanowires and a region having ITO in the plane, and a conductive layer having a mix of a region having silver nanowires and a region having silver nanoparticles in the plane. Dividing the conductive layer into regions in this way makes it possible to improve, for example, the characteristics of a circuit formed of the conductive layer.

### First Photosensitive Layer

The laminate has a first photosensitive layer. The first photosensitive layer is not particularly limited as long as it is a layer having the properties of changing solubility in a developer by exposure. Examples of the first photosensitive layer include a positive tone photosensitive layer whose solubility in a developer increases by exposure (hereinafter, simply called “positive tone photosensitive layer” in some cases), and a negative tone photosensitive layer whose solubility in a developer decreases by exposure (hereinafter, simply called “negative tone photosensitive layer” in some cases).

In the present disclosure, “solubility in a developer increases by exposure” means that the solubility of an exposed portion in a developer is relatively higher than the solubility of an unexposed portion in the developer.

In the present disclosure, “solubility in a developer decreases by exposure” means that the solubility of an exposed portion in a developer is relatively lower than the solubility of an unexposed portion in the developer.

From the viewpoint of resolution, the first photosensitive layer is preferably a positive tone photosensitive layer whose solubility in a developer increases by exposure. From the viewpoint of strength, heat resistance, and chemical resistance of the resin pattern to be obtained, the first photosensitive layer is preferably a negative tone photosensitive layer whose solubility in a developer decreases by exposure. The positive tone photosensitive layer and the negative tone photosensitive layer will be specifically described below.

### Positive Tone Photosensitive Layer

As the positive tone photosensitive layer, known positive tone photosensitive layers can be used without limitation. It is preferable that the positive tone photosensitive layer contain an acid-decomposable resin, that is, a polymer that has a constitutional unit having an acid group protected with an acid-decomposable group, and a photoacid generator. The positive tone photosensitive layer may also be a positive tone photosensitive layer that contains a naphthoquinonediazide-based compound as a photoreaction initiator and a phenol novolac resin.

The positive tone photosensitive layer is more preferably a chemically amplified positive tone photosensitive layer containing a polymer that has a constitutional unit having an acid group protected with an acid-decomposable group and a photoacid generator.

(Polymer having constitutional unit having acid group protected with acid-decomposable group)

It is preferable that the positive tone photosensitive layer contain a polymer (hereinafter, called “polymer X” in some cases) having a constitutional unit (hereinafter, called “constitutional unit A” in some cases) having an acid group protected with an acid-decomposable group. The positive tone photosensitive layer may contain one polymer X or two or more polymers X.

In the polymer X, the acid group protected with an acid-decomposable group is converted into an acid group through a deprotection reaction, by the action of an acidic substance (for example, an acid) in a catalytic amount generated by exposure. The generation of an acid group in the polymer X increases the solubility of the positive tone photosensitive layer in a developer.

The polymer X is preferably an addition polymerization-type polymer, and more preferably a polymer having a constitutional unit derived from (meth)acrylic acid or an ester thereof.

### Constitutional Unit Having Acid Group Protected With Acid-Decomposable Group

It is preferable that the polymer X have a constitutional unit (constitutional unit A) having an acid group protected with an acid-decomposable group. In a case where the polymer X has the constitutional unit A, the sensitivity of the positive tone photosensitive layer can be improved.

As the acid group, known acid groups can be used without limitation. The acid group is preferably a carboxy group or a phenolic hydroxyl group.

Examples of the acid-decomposable group include a group that is relatively easily decomposed by an acid and a group that is relatively difficult to be decomposed by an acid. Examples of the group that is relatively easily decomposed by an acid include an acetal-type protective group (for example, a 1-alkoxyalkyl group, a tetrahydropyranyl group, and a tetrahydrofuranyl group). Examples of the group that is relatively difficult to be decomposed by an acid include a tertiary alkyl group (for example, a tert-butyl group) and a tertiary alkyloxycarbonyl group (for example, a tert-butyloxycarbonyl group). Among the above, the acid-decomposable group is preferably an acetal-type protective group.

From the viewpoint of suppressing variation in the line width of the resin pattern, the molecular weight of the acid-decomposable group is preferably 300 or less.

From the viewpoint of sensitivity and resolution, the constitutional unit A is preferably a constitutional unit represented by Formula A1, a constitutional unit represented by Formula A2, or a constitutional unit represented by Formula A3, and more preferably a constitutional unit represented by Formula A3. The constitutional unit represented by Formula A3 is a constitutional unit having a carboxy group protected with an acetal-type acid-decomposable group.

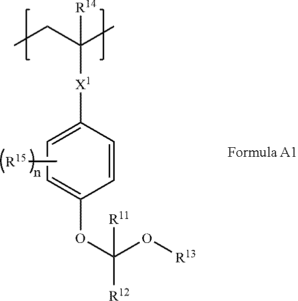

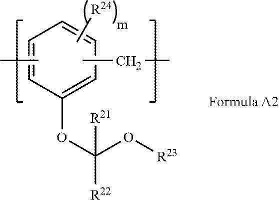

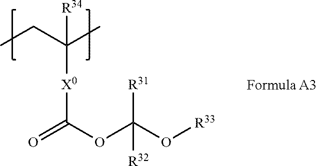

In Formula A1, R¹¹ and R¹² each independently represent a hydrogen atom, an alkyl group, or an aryl group, at least one of R¹¹ or R¹² is an alkyl group or an aryl group, R¹³ represents an alkyl group or an aryl group, R¹¹ or R¹² and R¹³ may be linked to form a cyclic ether, R¹⁴ represents a hydrogen atom or a methyl group, X¹ represents a single bond or a divalent linking group, R¹⁵ represents a substituent, and n represents an integer of 0 to 4.

In Formula A2, R²¹ and R²² each independently represent a hydrogen atom, an alkyl group, or an aryl group, at least one of R²¹ or R²² represents an alkyl group or an aryl group, R²³ represents an alkyl group or an aryl group, R²¹ or R²² and R²³ may be linked to form a cyclic ether, R²⁴ each independently represents a hydroxy group, a halogen atom, an alkyl group, an alkoxy group, an alkenyl group, an aryl group, an aralkyl group, an alkoxycarbonyl group, a hydroxyalkyl group, an arylcarbonyl group, an aryloxycarbonyl group, or a cycloalkyl group, and m represents an integer of 0 to 3.

In Formula A3, R³¹ and R³² each independently represent a hydrogen atom, an alkyl group, or an aryl group, at least one of R³¹ or R³² represents an alkyl group or an aryl group, R³³ represents an alkyl group or an aryl group, R³¹ or R³² and R³³ may be linked to form a cyclic ether, R³⁴ represents a hydrogen atom or a methyl group, and X⁰ represents a single bond or an arylene group.

In Formula A3, in a case where R³¹ or R³² is an alkyl group, an alkyl group having 1 to 10 carbon atoms is preferable.

In Formula A3, in a case where R³¹ or R³² is an aryl group, a phenyl group is preferable.

In Formula A3, R³¹ and R³² preferably each independently represent a hydrogen atom or an alkyl group having 1 to 4 carbon atoms.

In Formula A3, R³³ is preferably an alkyl group having 1 to 10 carbon atoms, and more preferably an alkyl group having 1 to 6 carbon atoms.

In Formula A3, the alkyl group and the aryl group represented by R³¹ to R³³ may have a substituent.

In Formula A3, R³¹ or R³² and R³³ are preferably linked to form a cyclic ether. The number of ring members of the cyclic ether is preferably 5 or 6, and more preferably 5.

In Formula A3, X⁰ is preferably a single bond. The arylene group may have a substituent.

In Formula A3, from the viewpoint of making it possible to further reduce the glass transition temperature (Tg) of the polymer X, R³⁴ is preferably a hydrogen atom.

The content of the constitutional unit represented by Formula A3 in which R³⁴ represents a hydrogen atom is preferably 20% by mass or more with respect to the total mass of constitutional unit A contained in the polymer X. The content of the constitutional unit represented by Formula A3, in which R³⁴ represents a hydrogen atom, in the constitutional unit A can be checked by the peak intensity ratio calculated by the conventional method based on the ¹³C-nuclear magnetic resonance (NMR) spectroscopy.

For preferred aspects of Formula A1 to Formula A3, paragraphs “0044” to “0058” of WO2018/179640A can be referred to.

In Formula A1 to Formula A3, from the viewpoint of sensitivity, the acid-decomposable group is preferably a group having a cyclic structure, more preferably a group having a tetrahydrofuran ring structure or a tetrahydropyran ring structure, even more preferably a group having a tetrahydrofuran ring structure, and particularly preferably a tetrahydrofuranyl group.

The polymer X may have one constitutional unit A or two or more constitutional units A.

The content of the constitutional unit A with respect to the total mass of the polymer X is preferably 10% by mass to 70% by mass, more preferably 15% by mass to 50% by mass, and particularly preferably 20% by mass to 40% by mass. In a case where the content of the constitutional unit A is within the above range, the resolution is further improved. In a case where the polymer X contains two or more constitutional units A, the aforementioned content of the constitutional unit A means the total content of the two or more constitutional units A. The content of the constitutional unit A can be checked by the peak intensity ratio calculated by the conventional method based on ¹³C-NMR spectroscopy.

### Constitutional Unit Having Acid Group

The polymer X may have a constitutional unit having an acid group (hereinafter, called “constitutional unit B” in some cases).

The constitutional unit B is a constitutional unit having an acid that is not protected with an acid-decomposable group, that is, an acid group that does not have a protective group. In a case where the polymer X has the constitutional unit B, the sensitivity during the pattern formation is improved. Furthermore, the photosensitive layer readily dissolves in an alkaline developer in a developing step following exposure, which makes it possible to shorten the development time.

The acid group in the constitutional unit B means a proton dissociating group having a pKa of 12 or less. From the viewpoint of improving sensitivity, the pKa of the acid group is preferably 10 or less, and more preferably 6 or less. Furthermore, the pKa of the acid group is preferably -5 or more.

Examples of the acid group include a carboxy group, a sulfonamide group, a phosphonic acid group, a sulfo group, a phenolic hydroxyl group, and a sulfonylimide group. The acid group is preferably a carboxy group or a phenolic hydroxyl group, and more preferably a carboxy group.

The polymer X may have one constitutional unit B or two or more constitutional units B.

The content of the constitutional unit B with respect to the total mass of the polymer X is preferably 0.01% by mass to 20% by mass, more preferably 0.01% by mass to 10% by mass, and particularly preferably 0.1% by mass to 5% by mass. In a case where the content of the constitutional unit B is within the above range, the resolution is further improved. In a case where the polymer X has two or more constitutional units B, the aforementioned content of the constitutional unit B means the total content of the two or more constitutional units B. The content of the constitutional unit B can be checked by the peak intensity ratio calculated by the conventional method based on ¹³C-NMR spectroscopy.

### Another Constitutional Unit

It is preferable that the polymer X have another constitutional unit (hereinafter, called “constitutional unit C” in some cases) different from the constitutional unit A and constitutional unit B described above. Adjusting at least one of the type or content of the constitutional unit C makes it possible to adjust various characteristics of the polymer X. In a case where the polymer X has the constitutional unit C, it is possible to easily adjust the glass transition temperature, acid value, and hydrophilicity/hydrophobicity of the polymer X.

Examples of monomers forming the constitutional unit C include styrenes, (meth)acrylic acid alkyl esters, (meth)acrylic acid cyclic alkyl esters, (meth)acrylic acid aryl esters, unsaturated dicarboxylic acid diesters, unsaturated bicyclic compounds, maleimide compounds, unsaturated aromatic compounds, conjugated diene-based compounds, unsaturated monocarboxylic acids, unsaturated dicarboxylic acids, and unsaturated dicarboxylic acid anhydrides.

From the viewpoint of adhesiveness with the substrate, the monomer forming the constitutional unit C is preferably a (meth)acrylic acid alkyl ester, and more preferably a (meth)acrylic acid alkyl ester having an alkyl group with 4 to 12 carbon atoms. Examples of the (meth)acrylic acid alkyl ester include methyl (meth)acrylate, ethyl (meth)acrylate, propyl (meth)acrylate, n-butyl (meth)acrylate, and 2-ethylhexyl (meth)acrylate.

Examples of the constitutional unit C include constitutional units derived from styrene, α-methylstyrene, acetoxystyrene, methoxystyrene, ethoxystyrene, chlorostyrene, methyl vinyl benzoate, ethyl vinyl benzoate, methyl (meth)acrylate, ethyl (meth)acrylate, n-propyl (meth)acrylate, isopropyl (meth)acrylate, n-butyl (meth)acrylate, 2-ethylhexyl (meth)acrylate, 2-hydroxyethyl (meth)acrylate, 2-hydroxypropyl (meth)acrylate, benzyl (meth)acrylate, cyclopentyl (meth)acrylate, cyclohexyl (meth)acrylate, isobornyl (meth)acrylate, acrylonitrile, or ethylene glycol monoacetoacetate mono(meth)acrylate. Examples of the constitutional unit C also include constitutional units derived from the compounds described in paragraphs “0021” to “0024” of JP2004-264623A.

From the viewpoint of resolution, it is preferable that the constitutional unit C include a constitutional unit having a basic group. Examples of the basic group include a group having a nitrogen atom. Examples of the group having a nitrogen atom include an aliphatic amino group, an aromatic amino group, and a nitrogen-containing heteroaromatic ring group. The basic group is preferably an aliphatic amino group.

The aliphatic amino group may be any of a primary amino group, a secondary amino group, and a tertiary amino group. From the viewpoint of resolution, the aliphatic amino group is preferably a secondary amino group or a tertiary amino group.

Examples of monomers forming the constitutional unit having a basic group include 1,2,2,6,6-pentamethyl-4-piperidyl methacrylate, 2-(dimethylamino)ethyl methacrylate, 2,2,6,6-tetramethyl-4-piperidyl acrylate, 2,2,6,6-tetramethyl-4-piperidyl methacrylate, 2-(diethylamino)ethyl methacrylate, 2-(dimethylamino)ethyl acrylate, 2-(diethylamino)ethyl acrylate, N-(3-dimethylamino)propyl methacrylate, N-(3-dimethylamino)propyl acrylate, N-(3-diethylamino)propyl methacrylate, N-(3-diethylamino)propyl acrylate, 2-(diisopropylamino)ethyl methacrylate, 2-morpholinoethyl methacrylate, 2-morpholinoethyl acrylate, N-[3-(dimethylamino)propyl]acrylamide, 4-aminostyrene, 4-vinylpyridine, 2-vinylpyridine, 3-vinylpyridine, 1-vinylimidazole, 2-methyl-1-vinylimidazole, 1-allylimidazole, and 1-vinyl-1,2,4-triazole. Among the above, 1,2,2,6,6-pentamethyl-4-piperidyl methacrylate is preferable.

From the viewpoint of improving electrical characteristics, the constitutional unit C is preferably a constitutional unit having an aromatic ring or a constitutional unit having an aliphatic cyclic skeleton. Examples of monomers forming these constitutional units include styrene, α-methylstyrene, dicyclopentanyl (meth)acrylate, cyclopentyl (meth)acrylate, cyclohexyl (meth)acrylate, isobornyl (meth)acrylate, and benzyl (meth)acrylate. Among the above, cyclohexyl (meth)acrylate is preferable.

The polymer X may have one constitutional unit C or two or more constitutional units C.

The content of the constitutional unit C with respect to the total mass of the polymer X is preferably 90% by mass or less, more preferably 85% by mass or less, and particularly preferably 80% by mass or less. The content of the constitutional unit C with respect to the total mass of the polymer X is preferably 10% by mass or more, and more preferably 20% by mass or more. In a case where the content of the constitutional unit C is within the above range, the resolution and the adhesiveness with the substrate are further improved. In a case where the polymer X has two or more constitutional units C, the aforementioned content of the constitutional unit C means the total content of the two or more constitutional units C. The content of the constitutional unit C can be checked by the peak intensity ratio calculated by the conventional method based on ¹³C-NMR spectroscopy.

Preferred examples of the polymer X will be shown below. However, the polymer X is not limited to the following examples. The ratio of each constitutional unit in the polymer X shown below and the weight-average molecular weight are appropriately selected to obtain preferred physical properties.[0079]

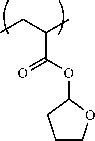

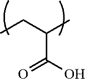

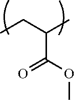

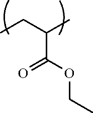

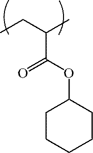

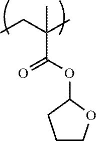

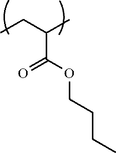

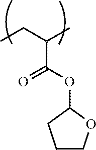

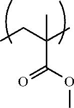

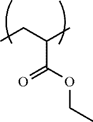

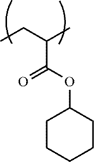

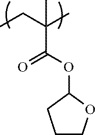

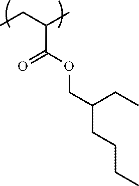

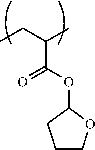

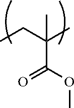

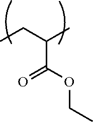

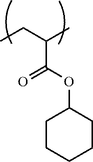

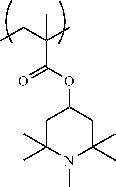

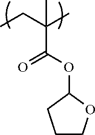

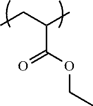

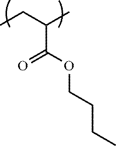

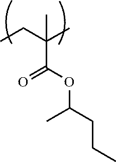

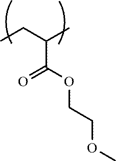

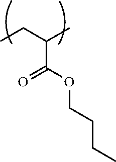

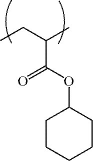

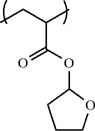

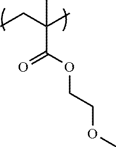

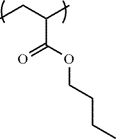

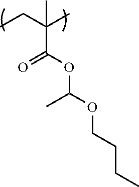

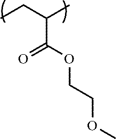

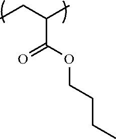

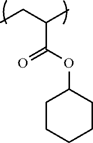

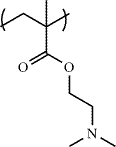

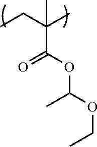

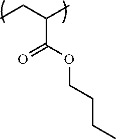

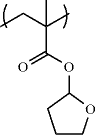

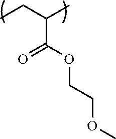

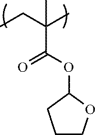

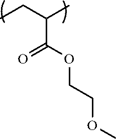

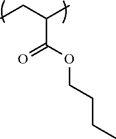

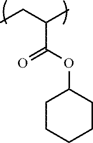

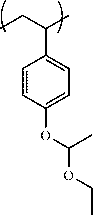

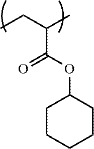

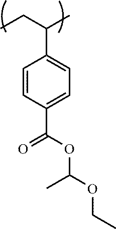

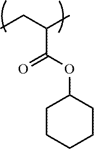

### Glass Transition Temperature

The glass transition temperature (Tg) of the polymer X is preferably 90° C. or less, more preferably 20° C. to 60° C., and particularly preferably 30° C. to 50° C. In a case where the positive tone photosensitive layer is formed using a transfer material that will be described later, adjusting the glass transition temperature of the polymer X to the above range makes it possible to improve the transfer properties of the positive tone photosensitive layer.

Examples of the method of adjusting the Tg of the polymer X to the above range include a method using the FOX equation. With the FOX equation, it is possible to adjust the Tg of the target polymer X based on, for example, the Tg of a homopolymer of each constitutional unit in the target polymer X and the mass fraction of each constitutional unit.

The FOX equation will be described below by using a copolymer having a first constitutional unit and a second constitutional unit as an example.

In a case where Tg1 represents a glass transition temperature of a homopolymer of a first constitutional unit, W1 represents a mass fraction of the first constitutional unit in a copolymer, Tg2 represents a glass transition temperature of a homopolymer of a second constitutional unit, and W2 represents a mass fraction of the second constitutional unit in a copolymer, a glass transition temperature Tg0 (unit: K) of the copolymer having the first constitutional unit and the second constitutional unit can be estimated according to the following equation.

$$\text{1} / \text{Tg0} \text{=} \left(\text{W1} / \text{Tg1}\right) \text{+} \left(\text{W2} / \text{Tg2}\right) \qquad \text{FOX equation:}$$

Adjusting the weight-average molecular weight of the polymer also makes it possible to adjust the Tg of the polymer.

### Acid Value

From the viewpoint of resolution, the acid value of the polymer X is preferably 0 mgKOH/g to 50 mgKOH/g, more preferably 0 mgKOH/g to 20 mgKOH/g, and particularly preferably 0 mgKOH/g to 10 mgKOH/g.

The acid value of a polymer represents the mass of potassium hydroxide required to neutralize acidic components per 1 g of the polymer. A specific measuring method will be described below. First, a measurement sample is dissolved in a mixed solvent containing tetrahydrofuran and water (volume ratio: tetrahydrofuran/water = 9/1). By using a potentiometric titrator (for example, trade name: AT-510, manufactured by KYOTO ELECTRONICS MANUFACTURING CO., LTD.), the obtained solution is titrated to a 0.1 mol/L aqueous sodium hydroxide solution at 25° C. for neutralization. The acid value is calculated by the following equation by using an inflection point of a titration pH curve as the end point of titration.
A = 56.11 × Vs × 0.1 × f/w
A: acid value (mgKOH/g)
Vs: amount of 0.1 mol/L aqueous sodium hydroxide solution used for titration (mL)
f: titer of 0.1 mol/L aqueous sodium hydroxide solution
w: mass (g) of measurement sample (expressed in terms of solid contents)

### Weight-Average Molecular Weight

The weight-average molecular weight (Mw) of the polymer X is preferably 60,000 or less as a polystyrene-equivalent weight-average molecular weight. In a case where the positive tone photosensitive layer is formed using the transfer material that will be described later, adjusting the weight-average molecular weight of the polymer X to 60,000 or less makes it possible to transfer the positive tone photosensitive layer at a low temperature (for example, at a temperature of 130° C. or less).

The weight-average molecular weight of the polymer X is preferably 2,000 to 60,000, and more preferably 3,000 to 50,000.

The ratio (dispersity) of the weight-average molecular weight of the polymer X to the number- average molecular weight of the polymer X is preferably 1.0 to 5.0, and more preferably 1.05 to 3.5.

The weight-average molecular weight of the polymer X is measured by gel permeation chromatography (GPC). As the measuring device, various commercially available devices can be used. The method of measuring the weight-average molecular weight of the polymer X by GPC will be specifically described below.

As a measuring device, HLC (registered trademark)-8220GPC (manufactured by Tosoh Corporation) is used.

One TSKgel (registered trademark) Super HZM-M (4.6 mm ID × 15 cm, manufactured by Tosoh Corporation), one Super HZ4000 (4.6 mm ID × 15 cm, manufactured by Tosoh Corporation), one Super HZ3000 (4.6 mm ID × 15 cm, manufactured by Tosoh Corporation), and one Super HZ2000 (4.6 mm ID×15 cm, manufactured by Tosoh Corporation) are connected in series and used as a column.

Tetrahydrofuran (THF) is used as an eluent.

As the measurement conditions, a sample concentration is set to 0.2% by mass, a flow rate is set to 0.35 mL/min, a sample injection amount is set to 10 µL, and a measurement temperature is set to 40° C.

As a detector, a differential refractive index (RI) detector is used.

The calibration curve is plotted using any of 7 samples of “Standard sample TSK standard, polystyrene” manufactured by Tosoh Corporation: “F-40”, “F-20”, “F-4”, “F-1”, “A-5000”, “A-2500”, and “A-1000”.

### Content

From the viewpoint of high resolution, the content of the polymer X with respect to the total mass of the positive tone photosensitive layer is preferably 50% by mass to 99.9% by mass, and more preferably 70% by mass to 98% by mass.

### Manufacturing Method

As the manufacturing method of the polymer X, known methods can be used without limitation. For example, the polymer X can be manufactured by polymerizing a monomer for forming the constitutional unit A and, as necessary, a monomer for forming the constitutional unit B and a monomer for forming the constitutional unit C in an organic solvent by using a polymerization initiator. The polymer X can also be manufactured by a so-called polymer reaction.

### Other Polymers

The positive tone photosensitive layer may contain, in addition to the polymer X, a polymer that does not have a constitutional unit having an acid group protected with an acid-decomposable group (hereinafter, called “other polymers” in some cases).

Examples of those other polymers include polyhydroxystyrene. Examples of commercially available products of polyhydroxystyrene include SMA 1000P, SMA 2000P, SMA 3000P, SMA 1440F, SMA 17352P, SMA 2625P, and SMA 3840F manufactured by Sartomer, ARUFON UC-3000, ARUFON UC-3510, ARUFON UC-3900, ARUFON UC-3910, ARUFON UC-3920, and ARUFON UC-3080 manufactured by TOAGOSEI CO., LTD., and Joncryl 690, Joncryl 678, Joncryl 67, and Joncryl 586 manufactured by BASF SE.

The positive tone photosensitive layer may contain another polymer, or two or more other polymers.

In a case where the positive tone photosensitive layer contains other polymers, the content of those other polymers with respect to the total mass of the polymer components is preferably 50% by mass or less, more preferably 30% by mass or less, and particularly preferably 20% by mass or less.

In the present disclosure, “polymer components” is a generic term for all polymers contained in the positive tone photosensitive layer. For example, in a case where the positive tone photosensitive layer contains the polymer X and other polymers, the polymer X and those other polymers are collectively called “polymer components”. The compounds corresponding to the cross-linking agent, dispersant, and surfactant that will be described later are not included in the polymer components even those these are polymer compounds.

The content of the polymer components with respect to the total mass of the positive tone photosensitive layer is preferably 50% by mass to 99.9% by mass, and more preferably 70% by mass to 98% by mass.

### Photoacid Generator

It is preferable that the positive tone photosensitive layer contain a photoacid generator as a photosensitive compound. The photoacid generator is a compound that can generate an acid by being irradiated with actinic rays (for example, ultraviolet rays, far ultraviolet rays, X-rays, and electron beams).

The photoacid generator is preferably a compound that generates an acid in response to actinic rays having a wavelength of 300 nm or more and preferably having a wavelength of 300 nm to 450 nm. Furthermore, a photoacid generator that does not directly respond to actinic rays having a wavelength of 300 nm or more can be preferably used in combination with a sensitizer, as long as the photoacid generator is a compound that generates an acid in response to actinic rays having a wavelength of 300 nm or more by being used in combination with a sensitizer.

The photoacid generator is preferably a photoacid generator that generates an acid having a pKa of 4 or less, more preferably a photoacid generator that generates an acid having a pKa of 3 or less, and particularly preferably a photoacid generator that generates an acid having a pKa of 2 or less. The lower limit of the pKa of the acid derived from the photoacid generator is not limited. The pKa of the acid derived from the photoacid generator is preferably -10.0 or more, for example.

Examples of the photoacid generator include an ionic photoacid generator and a nonionic photoacid generator.

Examples of the ionic photoacid generator include an onium salt compound. Examples of the onium salt compound include a diaryliodonium salt compound, a triarylsulfonium salt compound, and a quaternary ammonium salt compound. The ionic photoacid generator is preferably an onium salt compound, and particularly preferably at least one of a triarylsulfonium salt compound or a diaryliodonium salt compound.

As the ionic photoacid generator, the ionic photoacid generators described in paragraphs “0114” to “0133” of JP2014-85643A can also be preferably used.

Examples of the nonionic photoacid generator include a trichloromethyl-s-triazine compound, a diazomethane compound, an imidosulfonate compound, and an oxime sulfonate compound. From the viewpoint of sensitivity, resolution, and adhesiveness with the substrate, the nonionic photoacid generator is preferably an oxime sulfonate compound.

Specific examples of the trichloromethyl-s-triazine compound, the diazomethane compound, and the imidosulfonate compound include the compounds described in paragraphs “0083” to “0088” of JP2011-221494A.

As the oxime sulfonate compound, the compounds described in paragraphs “0084” to “0088” of WO2018/179640A can be suitably used.

From the viewpoint of sensitivity and resolution, the photoacid generator is preferably at least one compound selected from the group consisting of an onium salt compound and an oxime sulfonate compound, and more preferably an oxime sulfonate compound.

Preferred examples of the photoacid generator include photoacid generators having the following structures.

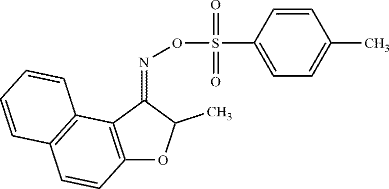 [SMILES: Cc1ccc(S(=O)(=O)O/N=C2/c3c(ccc4ccccc34)OC2C)cc1]

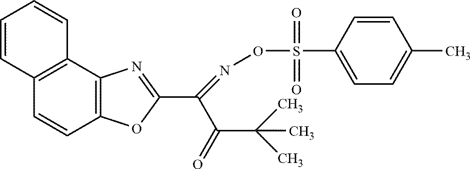 [SMILES: Cc1ccc(S(=O)(=O)O/N=C(\C(=O)C(C)(C)C)c2nc3c(ccc4ccccc43)o2)cc1]

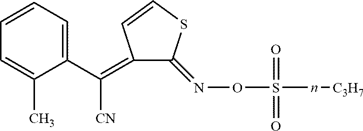

Examples of the photoacid generator having absorption at a wavelength of 405 nm include ADEKA ARKLS (registered trademark) SP-601 (manufactured by ADEKA CORPORATION).

The positive tone photosensitive layer may contain one photoacid generator or two or more photoacid generators.

From the viewpoint of sensitivity and resolution, the content of the photoacid generator with respect to the total mass of the positive tone photosensitive layer is preferably 0.1% by mass to 10% by mass, and more preferably 0.5% by mass to 5% by mass.

### Other Additives

The positive tone photosensitive layer may contain known additives in addition to the components described above. Examples of the additives include a sensitizer, a basic compound, a heterocyclic compound, an alkoxysilane compound, and a surfactant.

### Plasticizer

The positive tone photosensitive layer may contain a plasticizer for the purpose of improving plasticity.

From the viewpoint of imparting plasticity, it is preferable that the plasticizer have an alkyleneoxy group in the molecule. It is preferable that the alkyleneoxy group contained in the plasticizer have the following structure.

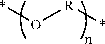

In the above formula, R represents an alkylene group having 2 to 8 carbon atoms, n represents an integer of 1 to 50, and * represents a bonding site with another atom.

In a case where the plasticity of the positive tone photosensitive layer containing the alkyleneoxy group-containing compound having the above structure (hereinafter, called “compound X”), the polymer X, and the photoacid generator is not improved compared to a positive tone photosensitive layer that does not contain the compound X, the compound X does not correspond to the plasticizer in the present disclosure. Generally, the optionally used surfactant is not used in an amount capable of imparting plasticity to the positive tone photosensitive layer. Therefore, the surfactant does not correspond to the plasticizer in the present disclosure.

Examples of the plasticizer include a compound having the following structure. However, the plasticizer is not limited to the following compound.

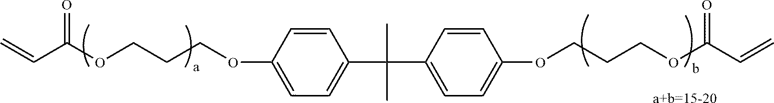

It is preferable that the weight-average molecular weight of the plasticizer be smaller than the weight-average molecular weight of the polymer X. From the viewpoint of imparting plasticity, the weight-average molecular weight of the plasticizer is preferably 500 or more and less than 10,000, more preferably 700 or more and less than 5,000, and particularly preferably 800 or more and less than 4,000.

The positive tone photosensitive layer may contain one plasticizer or two or more plasticizers.

From the viewpoint of adhesiveness with the substrate, the content of the plasticizer with respect to the total mass of the positive tone photosensitive layer is preferably 1% by mass to 50% by mass, and more preferably 2% by mass to 20% by mass.

### Sensitizer

It is preferable that the positive tone photosensitive layer contain a sensitizer.

The sensitizer is electronically excited by absorbing actinic rays. The contact between the electronically excited sensitizer and the photoacid generator brings about actions such as electron migration, energy transfer, and heating. By the actions described above, the photoacid generator generates an acid. Therefore, in a case where the positive tone photosensitive layer contains a sensitizer, the exposure sensitivity can be improved.

The sensitizer is preferably at least one compound selected from the group consisting of an anthracene derivative, an acridone derivative, a thioxanthone derivative, a coumarin derivative, a base styryl derivative, and a distyrylbenzene derivative, and more preferably an anthracene derivative.

The anthracene derivative is preferably 9,10-dibutoxyanthracene, 9,10-dichloroanthracene, 2-ethyl-9,10-dimethoxyanthracene, 9-hydroxymethylanthracene, 9-bromoanthracene, 9-chloroanthracene, 9, 10-dibromoanthracene, 2-ethylanthracene, or 9,10-dimethoxyanthracene.

Examples of the sensitizer include the compounds described in paragraphs “0139” to “0141” of WO2015/093271A.

The positive tone photosensitive layer may contain one sensitizer or two or more sensitizers.

The content of the sensitizer with respect to the total mass of the positive tone photosensitive layer is preferably 0% by mass to 10% by mass, and more preferably 0.1% by mass to 10% by mass.

### Basic Compound

It is preferable that the positive tone photosensitive layer contain a basic compound.

Examples of the basic compound include an aliphatic amine, an aromatic amine, a heterocyclic amine, a quaternary ammonium hydroxide, and a quaternary ammonium salt of carboxylic acid. Specific examples of the basic compound include the compounds described in paragraphs “0204” to “0207” of JP2011-221494A, the contents of which are incorporated into the present specification by reference.

Examples of the aliphatic amine include trimethylamine, diethylamine, triethylamine, di-n-propylamine, tri-n-propylamine, di-n-pentylamine, tri-n-pentylamine, diethanolamine, triethanolamine, dicyclohexylamine, and dicyclohexylmethylamine.

Examples of the aromatic amine include aniline, benzylamine, N,N-dimethylaniline, and diphenylamine.

Examples of the heterocyclic amine include pyridine, 2-methylpyridine, 4-methylpyridine, 2-ethylpyridine, 4-ethylpyridine, 2-phenylpyridine, 4-phenylpyridine, N-methyl-4-phenylpyridine, 4-dimethylaminopyridine, imidazole, benzimidazole, 4-methylimidazole, 2-phenylbenzimidazole, 2,4,5-triphenylimidazole, nicotine, nicotinic acid, nicotinamide, quinoline, 8-oxyquinoline, pyrazine, pyrazole, pyridazine, purine, pyrrolidine, piperidine, piperazine, morpholine, 4-methylmorpholine, 1,5-diazabicyclo[4.3.0]-5-nonene, and 1,8-diazabicyclo[5.3.0]-7-undecene.

Examples of the quaternary ammonium hydroxide include tetramethylammonium hydroxide, tetraethylammonium hydroxide, tetra-n-butylammonium hydroxide, tetra-n-hexylammonium hydroxide, and the like.

Examples of the quaternary ammonium salt of carboxylic acid include tetramethylammonium acetate, tetramethylammonium benzoate, tetra-n-butylammonium acetate, and tetra-n-butylammonium benzoate.

From the viewpoint of rustproofing properties of the conductive layer and linearity of the conductive pattern, the basic compound is preferably a benzotriazole compound.

As the benzotriazole compound, known benzotriazole compounds can be used without limitation as long as the benzotriazole compound is a compound having a benzotriazole skeleton. Examples of the benzotriazole compound include 1,2,3-benzotriazole, 1-[N,N-bis(2-ethylhexyl)aminomethyl]benzotriazole, 5-carboxybenzotriazole, 1-(hydroxymethyl)-1H-benzotriazole, 1-acetyl-1H-benzotriazole, 1-aminobenzotriazole, 9-(1H-benzotriazol-1-ylmethyl)-9H-carbazole, 1-chloro-1H-benzotriazole, 1-(2-pyridinyl)benzotriazole, 1-hydroxybenzotriazole, 1-methylbenzotriazole, 1-ethylbenzotriazole, 1-(1′-hydroxyethyl)benzotriazole, 1-(2′-hydroxyethyl)benzotriazole, 1-propylbenzotriazole, 1-(1′-hydroxypropyl)benzotriazole, 1-(2′-hydroxypropyl)benzotriazole, 1-(3′-hydroxypropyl)benzotriazole, 4-hydroxy-1H-benzotriazole, 5-methyl-1H-benzotriazole, methylbenzotriazole-5-carboxylate, ethylbenzotriazole-5-carboxylate, t-butyl-benzotriazole-5-carboxylate, cyclopentylethyl-benzotriazole-5-carboxylate, 1H-benzotriazole-1-acetonitrile, 1H-benzotriazole-1-carboxaldehyde, 2-methyl-2H-benzotriazole, and 2-ethyl-2H-benzotriazole.

The positive tone photosensitive layer may contain one basic compound or two or more basic compounds.

The content of the basic compound with respect to the total mass of the positive tone photosensitive layer is preferably 0.001% by mass to 5% by mass, and more preferably 0.005% by mass to 3% by mass.

### Heterocyclic Compound

The positive tone photosensitive layer may contain a heterocyclic compound.

Examples of the heterocyclic compound include a compound having an epoxy group or an oxetanyl group in the molecule, a heterocyclic compound having an alkoxymethyl group, an oxygen-containing heterocyclic compound (for example, a cyclic ether and a cyclic ester (for example, lactone)), and a nitrogen-containing heterocyclic compound (for example, a cyclic amine and oxazoline). The heterocyclic compound may be a heterocyclic compound containing elements (for example, silicon, sulfur, and phosphorus) having electrons in the d-orbital.

Examples of the compound having an epoxy group in the molecule include a bisphenol A-type epoxy resin, a bisphenol F-type epoxy resin, a phenol novolac-type epoxy resin, a cresol novolac-type epoxy resin, and an aliphatic epoxy resin.

The compound having an epoxy group in the molecule is preferably a bisphenol A-type epoxy resin, a bisphenol F-type epoxy resin, a phenol novolac-type epoxy resin, or an aliphatic epoxy resin, and more preferably an aliphatic epoxy resin.

The compound having an epoxy group in the molecule is available as a commercial product. Examples of commercially available products of the compound having an epoxy group in the molecule include JER828, JER1007, JER157S70, and JER157S65 manufactured by Mitsubishi Chemical Corporation., and the commercially available products described in paragraph “0189” of JP2011-221494A.

Examples of commercially available products other than the above include ADEKA RESIN EP-4000S, EP-4003S, EP-4010S, and EP-4011S manufactured by ADEKA CORPORATION, NC-2000, NC-3000, NC-7300, XD-1000, EPPN-501, and EPPN-502 manufactured by Nippon Kayaku Co., Ltd., DENACOL EX-611, EX-612, EX-614, EX-614B, EX-622, EX-512, EX-521, EX-411, EX-421, EX-313, EX-314, EX-321, EX-211, EX-212, EX-810, EX-811, EX-850, EX-851, EX-821, EX-830, EX-832, EX-841, EX-911, EX-941, EX-920, EX-931, EX-212L, EX-214L, EX-216L, EX-321L, EX-850L, DLC-201, DLC-203, DLC-204, DLC-205, DLC-206, DLC-301, DLC-402, EX-111, EX-121, EX-141, EX-145, EX-146, EX-147, EX-171, and EX-192 manufactured by Nagase ChemteX Corporation., YH-300, YH-301, YH-302, YH-315, YH-324, and YH-325 manufactured by NIPPON STEEL Chemical & Material Co., Ltd., and CELLOXIDE 2021P, 2081, 2000, 3000, EHPE3150, EPOLEAD GT400, and Serbinase B0134 and B0177 manufactured by DAICEL Corporation.

Examples of the compound having an oxetanyl group in the molecule include ARON OXETANE OXT-201, OXT-211, OXT-212, OXT-213, OXT-121, OXT-221, OX-SQ, and PNOX manufactured by TOAGOSEI CO., LTD.

It is preferable that the compound having an oxetanyl group may be used alone or used together with the compound having an epoxy group.

Among the above, as the heterocyclic compound, from the viewpoint of etching resistance and line width stability, the compound having an epoxy group is preferable.

The positive tone photosensitive layer may contain one heterocyclic compound or two or more heterocyclic compounds.

From the viewpoint of adhesiveness with the substrate and etching resistance, the content of the heterocyclic compound with respect to the total mass of the positive tone photosensitive layer is preferably 0.01% by mass to 50% by mass, more preferably 0.1% by mass to 10% by mass, and particularly preferably 1% by mass to 5% by mass.

### Alkoxysilane Compound

The positive tone photosensitive layer may contain an alkoxysilane compound.

Examples of the alkoxysilane compound include γ-aminopropyltrimethoxysilane, γ-aminopropyltriethoxysilane, γ-glycidoxypropyltrialkoxysilane, γ-glycidoxypropylalkyldialkoxysilane, γ-methacryloxypropyltrialkoxysilane, γ-methacryloxypropylalkyldialkoxysilane, γ-chloropropyltrialkoxysilane, γ-mercaptopropyltrialkoxysilane, β-(3,4-epoxycyclohexyl)ethyltrialkoxysilane, and vinyltrialkoxysilane.

Among the above, as the alkoxysilane compound, a trialkoxysilane compound is preferable, γ-glycidoxypropyltrialkoxysilane or γ-methacryloxypropyltrialkoxysilane is more preferable, γ-glycidoxypropyltrialkoxysilane is even more preferable, and 3-glycidoxypropyltrimethoxysilane is particularly preferable.

The positive tone photosensitive layer may contain one alkoxysilane compound or two or more alkoxysilane compounds.

From the viewpoint of adhesiveness with the substrate and etching resistance, the content of the alkoxysilane compound with respect to the total mass of the positive tone photosensitive layer is preferably 0.1% by mass to 50% by mass, more preferably 0.5% by mass to 40% by mass, and particularly preferably 1.0% by mass to 30% by mass.

### Surfactant

From the viewpoint of uniformity of film thickness, it is preferable that the positive tone photosensitive layer contain a surfactant.

Examples of the surfactant include an anionic surfactant, a cationic surfactant, a nonionic surfactant, and an amphoteric surfactant. The surfactant is preferably a nonionic surfactant.

Examples of the nonionic surfactant include polyoxyethylene higher alkyl ethers, polyoxyethylene higher alkylphenyl ethers, higher fatty acid diesters of polyoxyethylene glycol, a silicone-based surfactant, and a fluorine-based surfactant.

Examples of commercially available products of the nonionic surfactant include KP (manufactured by Shin-Etsu Chemical Co., Ltd.), POLYFLOW (manufactured by KYOEISHA CHEMICAL CO., LTD.), EFTOP (manufactured by JEMCO Corporation.), MEGAFACE (registered trademark) (manufactured by DIC Corporation), FLUORAD (manufactured by Sumitomo 3M Limited), ASAHIGUARD (registered trademark) (manufactured by AGC Inc.), SURFLON (registered trademark) (manufactured by AGC SEIMI CHEMICAL CO., LTD.), PolyFox (manufactured by OMNOVA Solutions Inc.), and SH-8400 (manufactured by Dow Corning Toray Co., Ltd.).

Examples of the nonionic surfactant include glycerol, trimethylolpropane, trimethylolethane, and ethoxylate and propoxylate of these (for example, glycerol propoxylate, glycerol ethoxylate, and the like), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid ester, PLURONIC L10, L31, L61, L62, 10R5, 17R2,and 25R2 (all of these are manufactured by BASF SE), TETRONIC 304, 701, 704, 901, 904, and 150R1 (all of these are manufactured by BASF SE), SOLSPERSE 20000 (all of these are manufactured by Lubrizol Japan Limited.), NCW-101, NCW-1001, and NCW-1002 (all of these are manufactured by FUJIFILM Wako Pure Chemical Corporation), PIONIN D-6112, D-6112-W, and D-6315 (all of these are manufactured by TAKEMOTO OIL & FAT Co., Ltd.), OLFINE E1010 and SURFYNOL 104, 400, and 440 (all of these are manufactured by Nissin Chemical Industry Co., Ltd.), and the like.

The surfactant is preferably a copolymer that contains a constitutional unit SA and a constitutional unit SB represented by Formula I-1 and has a polystyrene-equivalent weight-average molecular weight (Mw) of 1,000 or more and 10,000 or less measured by gel permeation chromatography using tetrahydrofuran (THF) as a solvent.

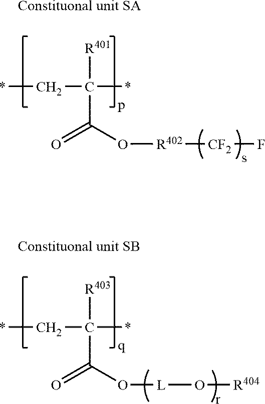

In Formula I-1, R⁴⁰¹ and R⁴⁰³ each independently represent a hydrogen atom or a methyl group, R⁴⁰² represents a linear alkylene group having 1 or more and 4 or less carbon atoms, R⁴⁰⁴ represents a hydrogen atom or an alkyl group having 1 or more and 4 or less carbon atoms, L represents an alkylene group having 3 or more and 6 or less carbon atoms, p and q each represent mass percentage showing a polymerization ratio, p represents a numerical value of 10% by mass or more and 80% by mass or less, q represents a numerical value of 20% by mass or more and 90% by mass or less, r represents an integer of 1 or more and 18 or less, s represents an integer of 1 or more and 10 or less, and * represents a bonding site with another structure.

L is preferably a branched alkylene group represented by Formula I-2. In Formula I-2, R⁴⁰⁵ represents an alkyl group having 1 or more and 4 or less carbon atoms. From the viewpoint of compatibility, R⁴⁰⁵ is preferably an alkyl group having 1 or more and 3 or less carbon atoms, and more preferably an alkyl group having 2 or 3 carbon atoms. The sum of p and q (p + q) is preferably p + q = 100, that is, 100% by mass.

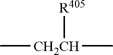

The weight-average molecular weight (Mw) of the copolymer containing the constitutional unit SA and the constitutional unit SB represented by Formula I-1 is preferably 1,500 or more and 5,000 or less.

Examples of commercially available fluorine-based surfactants include MEGAFACE F-171, F-172, F-173, F-176, F-177, F-141, F-142, F-143, F-144., F-437, F-475, F-477, F-479, F-482, F-551-A, F-552, F-554, F-555-A, F-556, F-557, F -558, F-559, F-560, F-561, F-565, F-563, F-568, F-575, F-780, EXP, MFS-330, MFS-578, MFS-579, MFS-586, MFS-587, R-41, R-41-LM, R-01, R-40, R-40-LM, RS-43, TF-1956, RS-90, R-94, RS-72-K, and DS-21 (all of these are manufactured by DIC Corporation), FLUORAD FC430, FC431, and FC171 (all of these are manufactured by Sumitomo 3M Limited), SURFLON S-382, SC-101, SC-103, SC-104, SC-105, SC-1068, SC-381, SC-383, S-393, and KH-40 (all of these are manufactured by AGC Inc.), PolyFox PF636, PF656, PF6320, PF6520, and PF7002 (all of these are manufactured by OMNOVA Solutions Inc.), and FTERGENT 710FL, 710FM, 610FM, 601AD, 601ADH2, 602A, 215M, 245F, 251, 212M, 250, 209F, 222F, 208G, 710LA, 710FS, 730LM, 650AC, 681, and 683 (all of these are manufactured by NEOS COMPANY LIMITED), and the like.

As the fluorine-based surfactant, an acrylic compound is also suitably used which has a molecular structure having a fluorine atom-containing functional group and goes through the volatilization of fluorine atoms by the cleavage of the portion of the fluorine atom-containing functional group in a case where the compound is heated. Examples of such a fluorine-based surfactant include MEGAFACE DS series manufactured by DIC Corporation (The Chemical Daily Co., Ltd. (Feb. 22, 2016), Nikkei Business Daily (Feb. 23, 2016)), for example, MEGAFACE DS-21.

As the fluorine-based surfactant, it is also preferable to use a polymer of a fluorine atom-containing vinyl ether compound having a fluorinated alkyl group or a fluorinated alkylene ether group and a hydrophilic vinyl ether compound.

As the fluorine-based surfactant, a block polymer can also be used.

As the fluorine-based surfactant, a fluorine-containing polymer compound can also be preferably used which contains a constitutional unit that is derived from a (meth)acrylate compound having a fluorine atom and a constitutional unit that is derived from a (meth)acrylate compound having two or more (preferably five or more) alkyleneoxy groups (preferably ethyleneoxy groups or propyleneoxy groups).

Furthermore, as the fluorine-based surfactant, a fluorine-containing polymer having an ethylenically unsaturated bond-containing group on a side chain can also be used. Examples thereof include MEGAFACE RS-101, RS-102, RS-718K, and RS-72-K (manufactured by DIC Corporation), and the like.

As the fluorine-based surfactant, from the viewpoint of improving environmental compatibility, a surfactant is preferable which is derived from alternative materials of compounds having a linear perfluoroalkyl group having 7 or more carbon atoms, such as perfluorooctanoic acid (PFOA) and perfluorooctane sulfonic acid (PFOS).

Examples of the silicone-based surfactant include a linear polymer consisting of a siloxane bond and a modified polysiloxane polymer having an organic group introduced into a side chain or a terminal.

Specific examples of the silicone-based surfactant include DOWSIL 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of these are manufactured by Dow Corning Toray Co., Ltd.), X-22-4952, X-22-4272, X-22-6266, KF-351A, K354L, KF-355A, KF-945, KF-640, KF-642, KF-643, X-22-6191, X-22-4515, KF-6004, KP-341, KF-6001, and KF-6002 (all of these are manufactured by Shin-Etsu Silicone), F-4440, TSF-4300, TSF-4445, TSF-4460, and TSF-4452 (all of these are manufactured by Momentive Performance Materials Inc.), BYK-307, BYK-323, and BYK-330 (all of these are manufactured by BYK-Chemie GmbH), and the like.

As the surfactant, it is also possible to use the surfactants described in paragraph “0017” of JP4502784B and paragraphs “0060” to “0071” of JP2009-237362A.

The positive tone photosensitive layer may contain one surfactant or two or more surfactants.

The content of the surfactant with respect to the total mass of the positive tone photosensitive layer is preferably 10% by mass or less, more preferably 0.001% by mass to 10% by mass, and particularly preferably 0.01% by mass to 3% by mass.

The plasticizer, sensitizer, basic compound, heterocyclic compound, alkoxysilane compound, and surfactant are also described in paragraphs “0097” to “0127” of WO2018/179640A. The contents of these paragraphs are incorporated into the present specification by reference.

### Other Components

The positive tone photosensitive layer may contain components other than the above additives (hereinafter, called “other components” in some cases). Examples of those other components include metal oxide particles, an antioxidant, a dispersant, an acid proliferation agent, a development accelerator, conductive fibers, a colorant, a thermal radical polymerization initiator, a thermal acid generator, an ultraviolet absorber, a thickener, a crosslinking agent, and an organic or inorganic deposition preventing agent. Preferred aspects of those other components are described in paragraphs “0165” to “0184” of JP2014-85643A, the contents of which are incorporated into the present specification by reference.

The positive tone photosensitive layer may contain a solvent. For example, in a case where a composition containing a solvent is used to form the positive tone photosensitive layer, sometimes the solvent remains in the positive tone photosensitive layer.

Examples of the solvent include the solvents described in paragraphs “0174” to “0178” of JP2011-221494A and the solvents described in paragraphs “0092” to “0094” of WO2018/179640A. As a solvent, a cyclic ether solvent such as tetrahydrofuran may also be used.

The positive tone photosensitive layer may contain one solvent or two or more solvents.

The content of the solvent with respect to the total mass of the positive tone photosensitive layer is preferably 2% by mass or less, more preferably 1% by mass or less, and particularly preferably 0.5% by mass or less.

### Negative Tone Photosensitive Layer

As the negative tone photosensitive layer, known negative tone photosensitive layers can be used without limitation. From the viewpoint of pattern forming properties, it is preferable that the negative tone photosensitive layer contain a polymer having an acid group, a polymerizable compound, and a photopolymerization initiator. As the negative tone photosensitive layer, for example, the photosensitive resin layer described in JP2016-224162A may also be used.

### Polymer Having Acid Group

It is preferable that the negative tone photosensitive layer contain a polymer having an acid group (hereinafter, called “polymer Y” in some cases).

Examples of the acid group include a carboxy group, a sulfo group, a phosphoric acid group, and a phosphonic acid group. The acid group is preferably a carboxy group.

From the viewpoint of alkali developability, the polymer Y is preferably an alkali-soluble resin having an acid value of 60 mgKOH/g or more, and more preferably a carboxy group-containing acrylic resin having an acid value of 60 mgKOH/g or more.

Examples of the carboxy group-containing acrylic resin having an acid value of 60 mgKOH/g or more include a carboxy group-containing acrylic resin having an acid value of 60 mgKOH/g or more among the polymers described in paragraph “0025” of JP2011-95716A, a carboxy group-containing acrylic resin having an acid value of 60 mgKOH/g or more among the polymers described in paragraphs “0033” to “0052” of JP2010-237589A, a carboxy group-containing acrylic resin having an acid value of 60 mgKOH/g or more among the binder polymers described in paragraphs “0053” to “0068” of JP2016-224162A, and the like. “Acrylic resin” refers to a resin having at least one of a constitutional unit derived from a (meth)acrylic acid or a constitutional unit derived from a (meth)acrylic acid ester. In the acrylic resin, the content of the constitutional unit derived from a (meth)acrylic acid and the constitutional unit derived from a (meth)acrylic acid ester with respect to the total mass of the acrylic resin is preferably 30% by mass to 100% by mass, and more preferably 50% by mass to 100% by mass.

In the polymer Y, the content of the constitutional unit having an acid group with respect to the total mass of the polymer Y is preferably 5% by mass to 50% by mass, more preferably 10% by mass to 40% by mass, and particularly preferably 12% by mass to 30% by mass.

The polymer Y may have a reactive group. As the reactive group, a polymerizable group is preferable. Examples of the polymerizable group include an ethylenically unsaturated group, a polycondensable group (for example, a hydroxy group and a carboxy group), and a polyaddition reactive group (for example, an epoxy group and an isocyanate group).

From the viewpoint of alkali developability, the acid value of the polymer Y is preferably 60 mgKOH/g to 200 mgKOH/g, more preferably 100 mgKOH/g to 200 mgKOH/g, and particularly preferably 150 mgKOH/g to 200 mgKOH/g.

The weight-average molecular weight of the polymer Y is preferably 1,000 or more, more preferably 10,000 or more, and particularly preferably 20,000 to 100,000.

The polymer Y may have a constitutional unit derived from a non-acidic monomer. Examples of the non-acidic monomer include a (meth)acrylic acid ester, an ester compound of vinyl alcohol, (meth)acrylonitrile, and an aromatic vinyl compound.

Examples of the (meth)acrylic acid ester include methyl (meth)acrylate, ethyl (meth)acrylate, n-propyl (meth)acrylate, isopropyl (meth)acrylate, n-butyl (meth)acrylate, isobutyl (meth)acrylate, tert-butyl (meth)acrylate, 2-hydroxyethyl (meth)acrylate, 2-hydroxypropyl (meth)acrylate, 2-ethylhexyl (meth)acrylate, and benzyl (meth)acrylate.

Examples of the ester compound of vinyl alcohol include vinyl acetate.

Examples of the aromatic vinyl compound include styrene and a styrene derivative.

The non-acidic monomer is preferably methyl (meth)acrylate, n-butyl (meth)acrylate, styrene, a styrene derivative, or benzyl (meth)acrylate. From the viewpoint of resolution, adhesiveness with the substrate, etching resistance, and reduction of aggregates during development, the non-acidic monomer is more preferably styrene, a styrene derivative, or benzyl (meth)acrylate.

The polymer Y may have any one of a linear structure, a branched structure, and an alicyclic structure on a side chain. Using the monomer containing a group having a branched structure on a side chain or the monomer containing a group having an alicyclic structure on a side chain makes it possible to introduce the branched structure or alicyclic structure into the side chain of the polymer A. The group having an alicyclic structure may be monocyclic or polycyclic.

Specific examples of the monomer containing a group having a branched structure on a side chain include isopropyl (meth)acrylate, isobutyl (meth)acrylate, sec-butyl (meth)acrylate, tert-butyl (meth)acrylate, isoamyl (meth)acrylate, tert-amyl (meth)acrylate, sec-amyl (meth)acrylate, 2-octyl (meth)acrylate, 3-octyl (meth)acrylate, tert-octyl (meth)acrylate, and the like. Among these, isopropyl (meth)acrylate, isobutyl (meth)acrylate, and tert-butyl methacrylate are preferable, and isopropyl methacrylate and tert-butyl methacrylate are more preferable.

Specific examples of the monomer containing a group having an alicyclic structure on a side chain include a monomer having a monocyclic aliphatic hydrocarbon group and a monomer having a polycyclic aliphatic hydrocarbon group. Examples thereof also include (meth)acrylate having an alicyclic hydrocarbon group with 5 to 20 carbon atoms. More specific examples thereof include (meth)acrylic acid (bicyclo[2.2.1]heptyl-2), (meth)acrylic acid-1-adamantyl, (meth)acrylic acid-2-adamantyl, (meth)acrylic acid-3-methyl-1-adamantyl, (meth)acrylic acid-3,5-dimethyl-1-adamantyl, (meth)acrylic acid-3-ethyladamantyl, (meth)acrylic acid-3-methyl-5-ethyl-1-adamantyl, (meth)acrylic acid-3,5,8-triethyl-1-adamantyl, (meth)acrylic acid-3,5-dimethyl-8-ethyl-1-adamantyl, 2-methyl-2-adamantyl (meth)acrylate, 2-ethyl-2-adamantyl (meth)acrylate, 3-hydroxy-1-adamantyl (meth)acrylate, octahydro-4,7-methanoinden-5-yl (meth)acrylate, octahydro-4,7-methanoinden-1-yl methyl (meth)acrylate, (meth)acrylic acid-1-menthyl, tricyclodecane (meth)acrylate, (meth)acrylic acid-3-hydroxy-2,6,6-trimethyl-bicyclo[3.1.1]heptyl, (meth)acrylic acid-3,7,7-trimethyl-4-hydroxy-bicyclo[4.1.0]heptyl, (nor)bornyl (meth)acrylate, isobornyl (meth)acrylate, fenchyl (meth)acrylate, (meth)acrylic acid-2,2,5-trimethylcyclohexyl, cyclohexyl (meth)acrylate, and the like. Among these (meth)acrylic acid esters, cyclohexyl (meth)acrylate, (nor)bornyl (meth)acrylate, isobornyl (meth)acrylate, (meth)acrylic acid-1-adamantyl (meth)acrylate, (meth)acrylic acid-2-adamantyl, fenchyl (meth)acrylate, 1-menthyl (meth)acrylate, or tricyclodecane (meth)acrylate are preferable, and cyclohexyl (meth)acrylate, (nor)bornyl (meth)acrylate, isobornyl (meth)acrylate, (meth)acrylic acid-2-adamantyl (meth)acrylate, or tricyclodecane (meth)acrylate are more preferable.

The negative tone photosensitive layer may contain one polymer Y or two or more of polymers Y.

From the viewpoint of photosensitivity, the content of the polymer Y with respect to the total mass of the negative tone photosensitive layer is preferably 10% by mass to 90% by mass, more preferably 20% by mass to 80% by mass, and even more preferably 30% by mass to 70% by mass.

### Polymerizable Compound

It is preferable that the negative tone photosensitive layer contain a polymerizable compound.

As the polymerizable compound, known polymerizable compounds can be used without limitation. The polymerizable compound is preferably an ethylenically unsaturated compound. The ethylenically unsaturated compound is a compound having one or more ethylenically unsaturated groups. The ethylenically unsaturated compound contributes to the photosensitivity (that is, photocuring properties) of the negative tone photosensitive layer and the strength of the cured film.

The ethylenically unsaturated group is preferably a (meth)acryloyl group.

The ethylenically unsaturated compound is preferably a (meth)acrylate compound.

Examples of the ethylenically unsaturated compound include a caprolactone-modified (meth)acrylate compound [for example, KAYARAD (registered trademark) DPCA-20 manufactured by Nippon Kayaku Co., Ltd. and A-9300-1CL manufactured by SHIN-NAKAMURA CHEMICAL CO., LTD.], an alkylene oxide-modified (meth)acrylate compound [for example, KAYARAD RP-1040 manufactured by Nippon Kayaku Co., Ltd., ATM-35E and A-9300 manufactured by Shin-Nakamura Chemical Co., Ltd., and EBECRYL (registered trademark) 135 manufactured by DAICEL-ALLNEX LTD.], ethoxylated glycerin triacrylate [for example, A-GLY-9E manufactured by SHIN-NAKAMURA CHEMICAL CO., LTD.], ARONIX (registered trademark) TO-2349 (manufactured by TOAGOSEI CO., LTD.), ARONIX M-520 (manufactured by TOAGOSEI CO., LTD.), ARONIX M-510 (manufactured by TOAGOSEI CO., LTD.), a urethane (meth)acrylate compound [for example, 8UX-015A (manufactured by TAISEI FINE CHEMICAL CO., LTD.), UA-32P (manufactured by Shin-Nakamura Chemical Co., Ltd.), and UA-1100H (manufactured by Shin-Nakamura Chemical Co., Ltd.)].

As the ethylenically unsaturated compound, the polymerizable compounds having an acid group described in paragraphs “0025” to “0030” of JP2004-239942A may also be used.

It is preferable that the negative tone photosensitive layer contain, as an ethylenically unsaturated compound, a compound having two or more ethylenically unsaturated groups. Hereinafter, an ethylenically unsaturated compound having X pieces of ethylenically unsaturated group will be called “X-functional ethylenically unsaturated compound” in some cases.

Examples of a difunctional ethylenically unsaturated compound include tricyclodecane dimethanol diacrylate (A-DCP, manufactured by SHIN-NAKAMURA CHEMICAL CO, LTD.), tricyclodecane dimethanol dimethacrylate (DCP, manufactured by SHIN-NAKAMURA CHEMICAL CO, LTD.), 1,9-nonanediol diacrylate (A-NOD-N, manufactured by SHIN-NAKAMURA CHEMICAL CO, LTD.), and 1,6-hexanediol diacrylate (A-HD-N, manufactured by SHIN-NAKAMURA CHEMICAL CO, LTD.).

As a difunctional ethylenically unsaturated compound, a difunctional ethylenically unsaturated compound having a bisphenol structure is also suitably used.

Examples of the difunctional ethylenically unsaturated compound having a bisphenol structure include the compounds described in paragraphs “0072” to “0080” of JP2016-224162A. Examples of the difunctional ethylenically unsaturated compound having a bisphenol structure also include alkylene oxide-modified bisphenol A di(meth)acrylate.

Examples of the alkylene oxide-modified bisphenol A di(meth)acrylate include ethylene glycol dimethacrylate obtained by adding an average of 5 mol of ethylene oxide to both ends of bisphenol A, ethylene glycol dimethacrylate obtained by adding an average of 2 mol of ethylene oxide to both ends of bisphenol A, ethylene glycol dimethacrylate obtained by adding an average of 5 mol of ethylene oxide added to both ends of bisphenol A, alkylene glycol dimethacrylate obtained by adding an average of 6 mol of ethylene oxide and an average of 2 mol of propylene oxide to both ends of bisphenol A, and alkylene glycol dimethacrylate obtained by adding an average of 15 mol of ethylene oxide and an average of 2 mol of propylene oxide to both ends of bisphenol A.

Specific examples of the alkylene oxide-modified bisphenol A di(meth)acrylate include 2,2-bis(4-(methacryloxydiethoxy)phenyl)propane and 2,2-bis(4-(methacryloxyethoxypropoxy)phenyl)propane.

Examples of commercially available products of the alkylene oxide-modified bisphenol A di(meth)acrylate include BPE-500 (manufactured by SHIN-NAKAMURA CHEMICAL CO, LTD.).

Examples of an ethylenically unsaturated compound having 3 or more ethylenically unsaturated groups include dipentaerythritol (tri/tetra/penta/hexa)(meth)acrylate, pentaerythritol (tri/tetra)(meth)acrylate, trimethylolpropane tri(meth)acrylates, ditrimethylolpropane tetra(meth)acrylate, isocyanuric acid (meth)acrylate, and glycerin tri(meth)acrylate.

“(Tri/tetra/penta/hexa)(meth)acrylate” is a concept including tri(meth)acrylate, tetra(meth)acrylate, penta(meth)acrylate, and hexa(meth)acrylate. “(Tri/tetra)(meth)acrylate” is a concept including tri(meth)acrylate and tetra(meth)acrylate.

The ethylenically unsaturated compound having 3 or more ethylenically unsaturated groups is preferably tetramethacrylate obtained by adding an average of 9 mol of ethylene oxide to a terminal of the hydroxyl group of pentaerythritol, tetramethacrylate obtained by adding an average of 12 mol of ethylene oxide to a terminal of a hydroxyl group of pentaerythritol, tetramethacrylate obtained by adding an average of 15 mol of ethylene oxide to an end of a hydroxyl group of pentaerythritol, tetramethacrylate obtained by adding an average of 20 mol of ethylene oxide to an end of a hydroxyl group of pentaerythritol, tetramethacrylate obtained by adding an average of 28 mol of ethylene oxide to an end of a hydroxyl group of pentaerythritol, or tetramethacrylate obtained by adding an average of 35 mol of ethylene oxide to an end of a hydroxyl group of pentaerythritol.

The molecular weight of the polymerizable compound is preferably 200 to 3,000, more preferably 280 to 2,200, and particularly preferably 300 to 2,200. In a case where the polymerizable compound is a compound (for example, a polymer) having a molecular weight distribution, the weight-average molecular weight (Mw) of the polymerizable compound is preferably 200 to 3,000, more preferably 280 to 2,200, and particularly preferably 300 to 2,200.

The negative tone photosensitive layer may contain one polymerizable compound or two or more polymerizable compounds.

The content of the polymerizable compound with respect to the total mass of the negative tone photosensitive layer is preferably 10% by mass to 70% by mass, more preferably 20% by mass to 60% by mass, and particularly preferably 20% by mass to 50% by mass.

### Photopolymerization Initiator

It is preferable that the negative tone photosensitive layer contain a photopolymerization initiator. The photopolymerization initiator initiates the polymerization of a polymerizable compound by receiving actinic rays (for example, ultraviolet rays and visible rays). The photopolymerization initiator is a sort of photoreaction initiator.

Examples of photopolymerization initiators include a photopolymerization initiator having an oxime ester structure, a photopolymerization initiator having an α-aminoalkylphenone structure, a photopolymerization initiator having an α-hydroxyalkylphenone structure, a photopolymerization initiator having an acylphosphine oxide structures, a photopolymerization initiator having a N-phenylglycine structure, and the like. The photopolymerization initiator is preferably at least one photopolymerization initiator selected from the group consisting of a photopolymerization initiator having an oxime ester structure, a photopolymerization initiator having an α-aminoalkylphenone structure, a photopolymerization initiator having an α-hydroxyalkylphenone structure, and a photopolymerization initiator having an N-phenylglycine structure.

The photopolymerization initiator is also preferably at least one compound selected from the group consisting of, for example, a 2,4,5-triarylimidazole dimer and a derivative thereof. In the 2,4,5-triarylimidazole dimer and a derivative thereof, two 2,4,5-triarylimidazole structures may be the same as or different from each other.

Preferred examples of the derivative of the 2,4,5-triarylimidazole dimer include a 2-(o-chlorophenyl)-4,5-diphenylimidazole dimer, 2-(o-chlorophenyl)-4,5-di(methoxyphenyl)imidazole dimer, a 2-(o-fluorophenyl)-4,5-diphenylimidazole dimer, a 2-(o-methoxyphenyl)-4,5-diphenylimidazole dimer, and a 2-(p-methoxyphenyl)-4,5-diphenylimidazole dimer.

As the photopolymerization initiator, for example, the photopolymerization initiators described in paragraphs “0031” to “0042” of JP2011-95716A and paragraphs “0064” to “0081” of JP2015-14783A may also be used.

Examples of commercially available products of the photopolymerization initiator include 1-[4-(phenylthio)phenyl]-1,2-octanedione-2-(O-benzoyloxime) (trade name: IRGACURE (registered trademark) OXE-01), manufactured by BASF Japan Ltd.), 1-[9-ethyl-6-(2-methylbenzoyl)-9H-carbazol-3-yl]ethanone-1-(O-acetyloxime) (trade name: IRGACURE OXE-02, manufactured by BASF Japan Ltd.), IRGACURE OXE-03 (manufactured by BASF Japan Ltd.), IRGACURE OXE-04 (manufactured by BASF Japan Ltd.), 2-(dimethylamino)-2-[(4-methylphenyl)methyl]-1-[4-(4-morpholinyl)phenyl]-1-butanone (trade name: Omnirad 379EG, manufactured by IGM Resins B.V.), 2-methyl-1-(4-methylthiophenyl)-2-morpholinopropan-1-one (trade name: Omnirad 907, manufactured by IGM Resins B.V.), 2-hydroxy-1-{4-[4-(2-hydroxy-2-methylpropionyl)benzyl]phenyl}-2-methylpropan-1-one (trade name: Omnirad 127, manufactured by IGM Resins B.V.), 2-benzyl-2-dimethylamino-1-(4-morpholinophenyl)butanone-1 (trade name: Omnirad 369, manufactured by IGM Resins B.V.), 2-hydroxy-2-methyl-1-phenylpropan-1-one (trade name: Omnirad 1173, manufactured by IGM Resins B.V.), 1-hydroxycyclohexylphenyl ketone (trade name : Omnirad 184, manufactured by IGM Resins B.V.), 2,2-dimethoxy-1,2-diphenylethan-1-one (trade name: Omnirad 651, manufactured by IGM Resins B.V.), 2,4,6-trimethylbenzoyl-diphenylphosphine oxide (trade name: Omnirad TPO H, manufactured by IGM Resins B.V.), bis(2,4,6-trimethylbenzoyl)phenyl phosphine oxide (trade name: Omnirad 819, manufactured by IGM Resins B.V.), an oxime ester-based photopolymerization initiator (trade name: Lunar 6, manufactured by DKSH Japan, Ltd.), 2,2′-bis(2-chlorophenyl)-4,4′,5,5′-tetraphenylbisimidazole (another name: 2-(2-chlorophenyl)-4,5-diphenylimidazole dimer) (trade name: B-CIM, manufactured by Hampford Research Inc.), and a 2-(o-chlorophenyl)-4, 5-diphenylimidazole dimer (trade name: BCTB, manufactured by Tokyo Chemical Industry Co., Ltd.).

Examples of commercially available products of the photopolymerization initiator also include ADEKA ARKLS NCI-930, ADEKA ARKLS NCI-730, and ADEKA ARKLS N-1919T manufactured by ADEKA CORPORATION.

The negative tone photosensitive layer may contain one photopolymerization initiator or two or more photopolymerization initiators.

The content of the photopolymerization initiator with respect to the total mass of the negative tone photosensitive layer is preferably 0.1% by mass or more, more preferably 0.5% by mass or more, and particularly preferably 1.0% by mass or more. The content of the photopolymerization initiator with respect to the total mass of the negative tone photosensitive layer is preferably 10% by mass or less, and more preferably 5% by mass or less.

### Other Additives

The negative tone photosensitive layer may contain known additives in addition to the components described above. Examples of the additives include a polymerization inhibitor, a plasticizer, a sensitizer, a hydrogen donor, a heterocyclic compound, and an ultraviolet (UV) absorber.

### Polymerization Inhibitor

The negative tone photosensitive layer may contain a polymerization inhibitor.

Examples of the polymerization inhibitor include the thermal polymerization inhibitors described in paragraph “0018” of JP4502784B. The polymerization inhibitor is preferably phenothiazine, phenoxazine, hydroquinone, chloranil, sodium phenolindophenol, m-aminophenol, or 4-methoxyphenol.

The negative tone photosensitive layer may contain one polymerization inhibitor or two or more polymerization inhibitors.

The content of the polymerization inhibitor with respect to the total mass of the negative tone photosensitive layer is preferably 0.01% by mass to 3% by mass, more preferably 0.01% by mass to 1% by mass, and particularly preferably 0.01% by mass to 0.8% by mass.

### Plasticizer

Examples of the plasticizer include the plasticizers described above regarding the positive tone photosensitive layer, and preferred plasticizers are the same as described above.

The negative tone photosensitive layer may contain one plasticizer or two or more plasticizers.

From the viewpoint of adhesiveness with the substrate, the content of the plasticizer with respect to the total mass of the negative tone photosensitive layer is preferably 1% by mass to 50% by mass, and more preferably 2% by mass to 20% by mass.

### Sensitizer

The negative tone photosensitive layer may contain a sensitizer.

Examples of the sensitizer include a dialkylaminobenzophenone compound, a pyrazoline compound, an anthracene compound, a coumarin compound, a cyanine compound, a xanthone compound, a thioxanthone compound, an oxazole compound, a benzoxazole compound, a thiazole compound, a benzothiazole compound, a triazole compound (for example, 1,2,4-triazole), a stilbene compound, a triazine compound, a thiophene compound, a naphthalimide compound, a triarylamine compound, a pyrazoline compound, and an aminoacridine compound.

A dye or a pigment can be used as the sensitizer. Examples of the dye or pigment include fuchsine, phthalocyanine green, coumarin 6, coumarin 7, coumarin 102, DOC iodide, indomonocarbocyanine sodium, an auramine base, chalcoxide green S, paramagenta, crystal violet, methyl orange, Nile blue 2B, Victoria Blue, Malachite Green (manufactured by Hodogaya Chemical Co., Ltd.), AIZEN (registered trademark) MALACHITE GREEN, manufactured by Hodogaya Chemical Co., Ltd.), Basic Blue 20, and Diamond Green (manufactured by Hodogaya Chemical Co., Ltd., AIZEN (registered trademark) DIAMOND GREEN GH).

As the dye, a color-developing dye can be used. The color-developing dye is a compound having a function of developing color by light irradiation. Examples of the color-developing dye include a leuco dye and a fluoran dye. The color-developing dye is preferably a leuco dye.

The negative tone photosensitive layer may contain one sensitizer or two or more sensitizers.

From the viewpoint of improving sensitivity to a light source and improving a curing rate by the balance between a polymerization rate and chain transfer, the content of the sensitizer with respect to the total mass of the negative tone photosensitive layer is preferably 0.01% by mass to 5% by mass, and more preferably 0.05% by mass to 1% by mass.

### Hydrogen Donor

The negative tone photosensitive layer may contain a hydrogen donor. The hydrogen donor can donate hydrogen to the photopolymerization initiator.

Examples of the hydrogen donors include bis[4-(dimethylamino)phenyl]methane, bis[4-(diethylamino)phenyl]methane, a thiol compound, and leucocrystal violet.

The negative tone photosensitive layer may contain one hydrogen donor or two or more hydrogen donors.

The content of the hydrogen donor with respect to the total mass of the negative tone photosensitive layer is preferably 0.01% by mass to 10% by mass, more preferably 0.05% by mass to 5% by mass, and particularly preferably 0.1% by mass to 2% by mass.

### Heterocyclic Compound

Examples of the heterocyclic compound include the heterocyclic compound described above regarding the positive tone photosensitive layer, and preferred heterocyclic compounds are the same as described above.

The negative tone photosensitive layer may contain one heterocyclic compound or two or more heterocyclic compounds.

From the viewpoint of adhesiveness with the substrate and etching resistance, the content of the heterocyclic compound with respect to the total mass of the negative tone photosensitive layer is preferably 0.01% by mass to 50% by mass, more preferably 0.1% by mass to 10% by mass, and particularly preferably 1% by mass to 5% by mass.

### Ultraviolet (UV) Absorber

The negative tone photosensitive layer may contain a UV absorber within the scope that does not depart from the gist of the present disclosure. A UV absorber can reduce the transmittance of the negative tone photosensitive layer to the exposure wavelength.

Examples of the UV absorber include a benzophenone-based UV absorber, a benzotriazole-based UV absorber, a benzoate-based UV absorber, a salicylate-based UV absorber, a triazine-based UV absorber, and a cyanoacrylate-based UV absorber. The UV absorber is preferably at least one UV absorber selected from the group consisting of a benzotriazole-based UV absorber and a triazine-based UV absorber.

Examples of benzotriazole-based UV absorber include 2-(2H-benzotriazol-2-yl)-p-cresol, 2-(2H-benzotriazol-2-yl)-4-6-bis(1-methyl-1-phenylethyl)phenol, 2-[5-chloro(2H)-benzotriazol-2-yl]-4-methyl-6-(tert-butyl)phenol, 2-(2H-benzotriazol-yl)-4,6-di-tert-pentylphenol, and 2-(2H-benzotriazol-2-yl)-4-(1,1,3,3-tetramethylbutyl)phenol. The benzotriazole-based UV absorber may be a mixture, modified substance, polymerized substance, or derivative of the above compounds.

Examples of the triazine-based UV absorber include 2-(4,6-diphenyl-1,3,5-triazin-2-yl)-5-[(hexyl)oxy]-phenol, 2-[4-[(2-hydroxy-3-dodecyloxypropyl)oxy] -2-hydroxyphenyl] -4,6-bis(2,4-dimethylphenyl)-1, 3,5-triazine, 2-[4-[(2-hydroxy-3-tridecyloxypropyl)oxy]-2-hydroxyphenyl]-4,6-bis(2,4-dimethylphenyl)-1, 3,5-triazine, and 2,4-bis(2,4-dimethylphenyl)-6-(2-hydroxy-4-iso-octyloxyphenyl)-s-triazine. The triazine-based UV absorber may be a mixture, modified substance, polymerized substance, or derivative of the above compounds.

The negative tone photosensitive layer may contain one UV absorber or two or more UV absorbers.

From the viewpoint of suppressing the occurrence exposure fogging and resolution, the content of the UV absorber with respect to the total mass of the negative tone photosensitive layer is preferably 0.1% by mass to 5% by mass, more preferably 0.1% by mass to 3% by mass, and particularly preferably 0.1% by mass to 2% by mass.

### Other Components

The negative tone photosensitive layer may components other than the above additives (hereinafter, called “other components” in some cases). Examples of those other components include metal oxide particles, an antioxidant, a dispersant, an acid proliferation agent, a development accelerator, conductive fibers, a colorant, a thermal radical polymerization initiator, a thermal acid generator, an ultraviolet absorber, a thickener, a crosslinking agent, and an organic or inorganic deposition preventing agent. Preferred aspects of those other components are described in paragraphs “0165” to “0184” of JP2014-85643A, and the contents of the publication are incorporated into the present specification by reference.

The negative tone photosensitive layer may contain a solvent. For example, in a case where a composition containing a solvent is used to form the negative tone photosensitive layer, sometimes the solvent remains in the negative tone photosensitive layer. Examples of the solvent include the solvents described above regarding the positive tone photosensitive layer.

The negative tone photosensitive layer may contain one solvent or two or more solvents.

The content of the solvent with respect to the total mass of the negative tone photosensitive layer is preferably 2% by mass or less, more preferably 1% by mass or less, and particularly preferably 0.5% by mass or less.

The negative tone photosensitive layer may contain a resin other than the polymer Y. Preferred examples of the resin include a polyhydroxystyrene resin, a polyimide resin, a polybenzoxazole resin, and a polysiloxane resin. The negative tone photosensitive layer may contain one resin or two or more resins other than the polymer Y.

### Impurities

It is preferable that the first photosensitive layer do not contain impurities, such as metal components and residual monomer components, as far as possible.

### Thickness

The thickness of the first photosensitive layer is not limited. From the viewpoint of uniformity of film thickness, the average thickness of the first photosensitive layer is preferably 0.5 µm or more, and more preferably 1 µm or more. From the viewpoint of resolution, the average thickness of the first photosensitive layer is preferably 20 µm or less, more preferably 10 µm or less, and particularly preferably 5 µm or less. The average thickness of the first photosensitive layer is measured by a method based on the method of measuring the average thickness of the substrate described above.

### Second Photosensitive Layer

The laminate has a second photosensitive layer. The second photosensitive layer is not particularly limited as long as it is a layer having the properties of changing solubility in a developer by exposure. Examples of the second photosensitive layer include a positive tone photosensitive layer whose solubility in a developer increases by exposure and a negative tone photosensitive layer whose solubility in a developer decreases by exposure.

From the viewpoint of resolution, the second photosensitive layer is preferably a positive tone photosensitive layer whose solubility in a developer increases by exposure. Examples of the positive tone photosensitive layer include the positive tone photosensitive layers described above in the section of “First photosensitive layer”, and preferred positive tone photosensitive layers are the same as described above.

From the viewpoint of strength, heat resistance, and chemical resistance of the resin pattern to be obtained, the second photosensitive layer is preferably a negative tone photosensitive layer whose solubility in a developer decreases by exposure. Examples of the negative tone photosensitive layer include the negative tone photosensitive layers described above in the section of “First photosensitive layer”, and preferred negative tone photosensitive layers are the same as described above.

### Impurities

It is preferable that the second photosensitive layer do not contain impurities, such as metal components and residual monomer components, as far as possible.

### Thickness

The thickness of the second photosensitive layer is not limited. From the viewpoint of uniformity of film thickness, the average thickness of the second photosensitive layer is preferably 0.5 µm or more, and more preferably 1 µm or more. From the viewpoint of resolution, the average thickness of the second photosensitive layer is preferably 20 µm or less, more preferably 10 µm or less, and particularly preferably 5 µm or less. The average thickness of the second photosensitive layer is measured by a method based on the method of measuring the average thickness of the substrate described above.

Examples of combinations of the type of first photosensitive layer and the type of second photosensitive layer include the following ones.
(1) The first photosensitive layer is a negative tone photosensitive layer, and the second photosensitive layer is a negative tone photosensitive layer.
(2) The first photosensitive layer is a positive tone photosensitive layer, and the second photosensitive layer is a positive tone photosensitive layer.
(3) The first photosensitive layer is a negative tone photosensitive layer, and the second photosensitive layer is a positive tone photosensitive layer.
(4) The first photosensitive layer is a positive tone photosensitive layer, and the second photosensitive layer is a negative tone photosensitive layer.

### Sensitivity of Photosensitive Layer and Photosensitive Compound

It is preferable that the first photosensitive layer and the second photosensitive layer each have a specific exposure sensitivity. In a case where the first and second photosensitive layers each have a specific exposure sensitivity, the occurrence of exposure fogging can be effectively suppressed.

Specifically, in a case where the sensitivity of the first photosensitive layer and the second photosensitive layer satisfies the following relations 1 and 2, the occurrence of exposure fogging can be effectively suppressed.

$$1.1 \leq {\text{E}}_{1 \text{r}} / {\text{E}}_{2} \qquad \text{Relation 1:}$$

$$1.1 \leq {\text{E}}_{2 \text{r}} / {\text{E}}_{1} \qquad \text{Relation 2:}$$

E₁ᵣ represents a maximum exposure amount at which the first photosensitive layer does not react in a case where the first photosensitive layer is exposed to light having the dominant wavelength λ₂ from a side of the second photosensitive layer of the laminate, E₂ represents an exposure amount in a case where the second photosensitive layer is exposed to light having the dominant wavelength λ₂ in the step of exposing the second photosensitive layer, E₂ᵣ represents a maximum exposure amount at which the second photosensitive layer does not react in a case where the second photosensitive layer is exposed to light having the dominant wavelength λ₁ from a side of the first photosensitive layer of the laminate, and E₁ represents an exposure amount in a case where the first photosensitive layer is exposed to light having the dominant wavelength λ₁ in the step of exposing the first photosensitive layer. The units of the exposure amounts described above are the same as each other. The units of the exposure amounts described above are, for example, mJ/cm².

The above sensitivity conditions will be specifically described. In the process of exposing the first photosensitive layer and the second photosensitive layer facing each other across the substrate interposed therebetween (that is, the exposure step (1) and the exposure step (2)), the first photosensitive layer is exposed to exposure light having the dominant wavelength λ₁, and the second photosensitive layer is exposed to exposure light having the dominant wavelength λ₂. Furthermore, in the above process, the first photosensitive layer is also exposed from the substrate side to the exposure light having the dominant wavelength λ₂ transmitted through the second photosensitive layer and the substrate, and the second photosensitive layer is also exposed from the substrate side to the exposure light having the dominant wavelength λ₁ transmitted through the first photosensitive layer and the substrate.

Therefore, the first photosensitive layer and the second photosensitive layer are required not to react with the exposure light transmitted from the substrate side, that is, not to cause exposure fogging. In a case where the photosensitive layers react with the exposure light transmitted through the substrate, for example, an unintended exposure pattern is formed, which adversely affects the final quality of wiring lines. In order to avoid exposure fogging, in the case of first photosensitive layer, the maximum exposure amount E₁ᵣ at which the first photosensitive layer does not react in a case where the first photosensitive layer is exposed from the side of the second photosensitive layer may be higher than the exposure amount E₂ of the second photosensitive layer. The same is true for the second photosensitive layer.

Each of the value of E₁ᵣ/E₂ and the value of E₂ᵣ/E₁ is preferably 1.1 or more, more preferably 1.15 or more, and particularly preferably 1.2 or more. Setting E₁ᵣ/E₂ and E₂ᵣ/E₁ to these ratios makes it possible to perform stable patterning without causing exposure fogging even though the exposure amount slightly changes in the process. The upper limit of each of E₁ᵣ/E₂ and E₂ᵣ/E₁ is not particularly limited, and can be set to any value as long as the photosensitive layers have proper performance.

Adjusting the light absorption coefficient of the photosensitive layers with respect to the dominant wavelength λ₁ and the dominant wavelength λ₂ makes it possible to set E₁ᵣ/E₂ and E₂ᵣ/E₁ to the above ratios. More specifically, appropriately selecting compounds, such as a photoreaction initiator, a sensitizer and a chain transfer agent, relating to a photoreaction used in each of the photosensitive layers makes it possible to obtain a photosensitive layer having the performance described above.

For example, in a case where the first photosensitive layer is exposed to light having a dominant wavelength of 405 nm and the second photosensitive layer is exposed to light having a dominant wavelength of 365 nm, reducing the light absorption coefficient of the first photosensitive layer with respect to the wavelength of 365 nm makes it possible to prevent the exposure fogging from easily occurring due to the exposure light having a wavelength of 365 nm transmitted through the second photosensitive layer and the substrate. Furthermore, for example, as a technical means for suppressing the occurrence of exposure fogging in the first photosensitive layer, it is possible to use a method of introducing a compound that may absorb light having a wavelength of 365 nm into the second photosensitive layer such that the amount of light transmitted through the second photosensitive layer and the substrate is controlled. On the other hand, for example, by reducing the light absorption coefficient of the second photosensitive layer with respect to a wavelength of 405 nm, it is possible to suppress the occurrence of exposure fogging in the second photosensitive layer as in the first photosensitive layer.

It is also preferable that the sensitivity of each of the first photosensitive layer and the second photosensitive layer satisfy the following relations 3 and 4.

$$3 \leq {\text{S}}_{12} / {\text{S}}_{11} \qquad \text{Relation 3:}$$

$$3 \leq {\text{S}}_{21} / {\text{S}}_{22} \qquad \text{Relation 4:}$$

S₁₂ represents a spectral sensitivity of the first photosensitive layer to the dominant wavelength λ₂, S₁₁ represents a spectral sensitivity of the first photosensitive layer to the dominant wavelength λ₁, S₂₁ represents a spectral sensitivity of the second photosensitive layer to the dominant wavelength λ₁, and S₂₂ represents a spectral sensitivity of the second photosensitive layer to the dominant wavelength λ₂. The units of the spectral sensitivities described above are the same as each other. The units of the spectral sensitivities described above are, for example, mJ/cm².

The spectral sensitivity refers to the minimum exposure amount necessary for a photosensitive layer to react in a case where the photosensitive layer is exposed to light having a specific wavelength. The smaller the value of the spectral sensitivity (that is, the minimum exposure amount necessary for the photosensitive layer to react) in the present disclosure, the higher the sensitivity of the photosensitive layer. Generally, the photosensitive layer has different light absorption coefficients for different wavelengths, and the photoreaction initiator and the sensitizer have different quantum yields for different wavelengths. Accordingly, usually, the sensitivity of the photosensitive layer also varies with wavelengths. In order to suppress exposure fogging, for example, it is desirable that the first photosensitive layer have a high spectral sensitivity (S₁₂), that is, low sensitivity, with respect to the dominant wavelength λ₂. In a case where the ratios S₁₂/S₁₁ and S₂₁/S₂₂ are above a certain level, the photosensitive layer is unlikely to react with the exposure light transmitted from the substrate side, which makes it possible to obtain excellent patterning properties.

The value of each of S₁₂/S₁₁ and S₂₁/S₂₂ is preferably 3 or more, more preferably 4 or more, and particularly preferably 5 or more. The upper limit of the value of each of S₁₂/S₁₁ and S₂₁/S₂₂ is not particularly limited, and can be set to arbitrary value as long as the photosensitive layer has proper performance. The photosensitive layer having such performance can be obtained by means of adjusting the light absorption coefficient of the photosensitive layer for each of the dominant wavelengths λ₁ and λ₂.

For measuring the spectral sensitivity, the photosensitive layer is irradiated with exposure light having a specific wavelength through a step wedge tablet and then developed. In the case of negative tone photosensitive layer, the minimum exposure amount at which the exposed portion remains can be adopted as a spectral sensitivity. In contrast, in the case of positive tone photosensitive layer, the minimum exposure amount at which the exposed portion is removed can be adopted as a spectral sensitivity.

It is preferable that the first photosensitive layer and the second photosensitive layer contain different photosensitive compounds. In a case where the first photosensitive layer and the second photosensitive layer contain different photosensitive compounds, the occurrence of exposure fogging can be further suppressed.

In the present disclosure, “different photosensitive compounds” means photosensitive compounds having different molar absorption coefficients at an exposure wavelength. For example, it is preferable that the photosensitive compound contained in one of the first photosensitive layer and the second photosensitive layer have a higher molar absorption coefficient at a wavelength of 365 nm than at a wavelength of 405 nm, and the photosensitive compound contained in the other photosensitive layer have a higher molar absorption coefficient at a wavelength of 405 nm than at a wavelength of 365 nm.

Preferred ranges of the molar absorption coefficient in “having a higher molar absorption coefficient at a wavelength of 365 nm than at a wavelength of 405 nm” will be shown below. In a case where the molar absorption coefficient at a wavelength of 365 nm is 100%, the molar absorption coefficient at a wavelength of 405 nm is preferably 80% or less, more preferably 50% or less, even more preferably 20% or less, particularly preferably 10% or less, and most preferably 5% or less. The lower limit of the molar absorption coefficient at a wavelength of 405 nm is not limited. In a case where the molar absorption coefficient at a wavelength of wavelength of 365 nm is 100%, the molar absorption coefficient at a wavelength of 405 nm may be determined, for example, in a range of 0% or more.

Preferred ranges of the molar absorption coefficient in “having a higher molar absorption coefficient at a wavelength of 405 nm than at a wavelength of 365 nm” will be shown below. In a case where the molar absorption coefficient at a wavelength of 405 nm is 100%, the molar absorption coefficient at a wavelength of 365 nm is preferably 80% or less, more preferably 50% or less, even more preferably 20% or less, particularly preferably 10% or less, and most preferably 5% or less. The lower limit of the molar absorption coefficient at a wavelength of 365 nm is not limited. In a case where the molar absorption coefficient at a wavelength of wavelength of 405 nm is 100%, the molar absorption coefficient at a wavelength of 365 nm may be determined, for example, in a range of 0% or more.

For example, between the first photosensitive layer and the second photosensitive layer, a photosensitive layer exposed at an exposure wavelength having higher intensity at a wavelength of 365 nm than at a wavelength of 405 nm preferably contains a photosensitive compound having a higher molar absorption coefficient at a wavelength of 365 nm than at a wavelength of 405 nm, and a photosensitive layer exposed at an exposure wavelength having higher intensity at a wavelength of 405 nm than at a wavelength of 365 nm preferably contains a photosensitive compound having a higher molar absorption coefficient at a wavelength of 405 nm than at a wavelength of 365 nm. In a case where the first photosensitive layer and the second photosensitive layer contain the photosensitive compounds described above, the occurrence of exposure fogging can be further suppressed.

The photosensitive compound is not limited as long as the compound has properties of reacting with light. Examples of the photosensitive compound include a photoacid generator, a photoreaction initiator, and a sensitizer. The photosensitive compound is preferably a photoacid generator or a photopolymerization initiator. Examples of the photoacid generator include the photoacid generators described above in the section of “Positive tone photosensitive layer”, and preferred photoacid generators are also the same as described above. Examples of the photopolymerization initiator include the photopolymerization initiators described above in the section of “Negative tone photosensitive layer”, and preferred photopolymerization initiators are also the same as described above.

### Light Absorption Characteristics

It is preferable that the first photosensitive layer have properties of absorbing light having the dominant wavelength λ₂. In the step of exposing the second photosensitive layer (that is, the exposure step (2)), for example, the exposure light transmitted through the second photosensitive layer, the substrate, and the first photosensitive layer in this order is sometimes reflected by a member such as a filter having wavelength selectivity and reaches the second photosensitive layer again. In a case where the second photosensitive layer is exposed again to the reflected exposure light, the resolution is likely to deteriorate. On the other hand, the first photosensitive layer having the properties of absorbing light having the dominant wavelength λ₂ can absorb light having the dominant wavelength λ₂ that is transmitted through the second photosensitive layer and the substrate and light having the dominant wavelength λ₂ that is reflected by a member such as a filter having wavelength selectivity. Therefore, the deterioration of resolution resulting from the re-exposure of the second photosensitive layer is suppressed.

It is preferable that the second photosensitive layer have properties of absorbing light having the dominant wavelength λ₁. In the step of exposing the first photosensitive layer (that is, the exposure step (1)), for example, the exposure light transmitted through the filter photosensitive layer, the substrate, and the second photosensitive layer in this order is sometimes reflected by a member such as a filter having wavelength selectivity and reaches the first photosensitive layer again. In a case where the first photosensitive layer is exposed again to the reflected exposure light, the resolution is likely to deteriorate. On the other hand, the second photosensitive layer having the properties of absorbing light having the dominant wavelength λ₁ can absorb light having the dominant wavelength λ₁ that is transmitted through the first photosensitive layer and the substrate and light having the dominant wavelength λ₁ that is reflected by a member such as a filter having wavelength selectivity. Therefore, the deterioration of resolution resulting from the re-exposure of the first photosensitive layer is suppressed.

From the viewpoint of suppressing deterioration of resolution resulting from re-exposure, in a certain embodiment, the first photosensitive layer preferably contains a substance absorbing light having the dominant wavelength λ₂, or the second photosensitive layer preferably contains a substance absorbing light having the dominant wavelength λ₁. The above embodiment includes the following (1) to (3). Among the following (1) to (3), (3) is preferable.
(1) The first photosensitive layer contains a substance absorbing light having the dominant wavelength λ₂.
(2) The second photosensitive layer contains a substance absorbing light having the dominant wavelength λ₁.
(3) The first photosensitive layer contains a substance absorbing light having the dominant wavelength λ₂, and the second photosensitive layer contains a substance absorbing light having the dominant wavelength λ₁.

From the viewpoint of suppressing the deterioration of resolution resulting from re-exposure, the layer having the properties of absorbing a specific dominant wavelength may be a layer other than the first photosensitive layer and the second photosensitive layer. In one embodiment, the laminate preferably has at least one layer selected from the group consisting of a layer that is disposed between the substrate and the first photosensitive layer and contains a substance absorbing light having the dominant wavelength λ₂, a layer that is disposed on the substrate via the first photosensitive layer and contains a substance absorbing light having the dominant wavelength λ₂, a layer that is disposed between the substrate and the second photosensitive layer and contains a substance absorbing light having the dominant wavelength λ₁, and a layer that is disposed on the substrate via the second photosensitive layer and contains a substance absorbing light having the dominant wavelength λ₁. Examples of the layer containing a substance absorbing light having the dominant wavelength λ₁ or the dominant wavelength λ₂ include layers described in the following “Other layers”. The layer containing the substance absorbing light having the dominant wavelength λ₁ or the dominant wavelength λ₂ is preferably a thermoplastic resin layer or an interlayer, and more preferably a thermoplastic resin layer. The thermoplastic resin layer and the interlayer will be described later.

Examples of the substance absorbing light having the dominant wavelength λ₁ or the dominant wavelength λ₂ include a dye and a pigment. Examples of the substance absorbing light having the dominant wavelength λ₁ or the dominant wavelength λ₂ include a near-ultraviolet absorber. Examples of the substance absorbing light having the dominant wavelength λ₁ or the dominant wavelength λ₂ also include inorganic particles.

Either the substance absorbing light having the dominant wavelength λ₂ or the substance absorbing the light having the dominant wavelength λ₁ is preferably a substance having absorption in a wavelength range of 400 nm or more. According to the spectral distribution of a light source such as a high-pressure mercury lamp, in practice, the exposure wavelength is selected by taking 400 nm as the boundary, for example. For example, the exposure wavelength in either the exposure step (1) or the exposure step (2) may be selected in a wavelength range of 400 nm or more. In the application of the exposure wavelength described above, either the substance absorbing light having the dominant wavelength λ₂ or the substance absorbing the light having the dominant wavelength λ₁ is preferably a substance having absorption in a wavelength range of 400 nm or more.

Examples of the substance having absorption in a wavelength range of 400 nm or more include a dye having absorption in a wavelength range of 400 nm or more and a pigment having absorption in a wavelength range of 400 nm or more. Examples of the dye having absorption in a wavelength range of 400 nm or more include Solvent Yellow 4, Solvent Yellow 14, Solvent Yellow 56, Methyl Yellow, Solvent Green 3, Acid Yellow 3, Acid Yellow 23, Acid Yellow 36, Acid Yellow 73, Basic Yellow 1, Basic Yellow 2, Basic Yellow 7, Acid Green 1, Acid Green 3, Acid Green 27, Acid Green 50, Acid Green A, and Basic Green 1. Examples of the pigment having absorption in a wavelength range of 400 nm or more include Pigment Yellow 1, Pigment Yellow 14, Pigment Yellow 34, Pigment Yellow 93, Pigment Yellow 138, Pigment Yellow 150, Pigment Green 7, Pigment Green 36, and Pigment Green 50, and Pigment Green 58. Examples of the substance having absorption in a wavelength range of 400 nm or more also include a near-ultraviolet absorber having absorption in a wavelength range of 400 nm or more and inorganic particles having absorption in a wavelength range of 400 nm or more.

The substance having absorption in a wavelength range of 400 nm or more is preferably a substance having a maximum absorption wavelength λₘₐₓ in a wavelength range of 400 nm or more.

Preferred aspects of the substance absorbing light having the dominant wavelength λ₁ or the dominant wavelength λ₂ may be selected according to the following (1) to (4). Selecting a substance having light absorption characteristics suited for the target dominant wavelength makes it possible to suppress the deterioration of resolution resulting from re-exposure.
(1) In a case where the dominant wavelength λ₁ is 400 nm or more, the substance absorbing light having the dominant wavelength λ₁ has absorption in a wavelength range of 400 nm or more.
(2) In a case where the dominant wavelength λ₁ is less than 400 nm, the substance absorbing light having the dominant wavelength λ₁ has absorption in a wavelength range less than 400 nm.
(3) In a case where the dominant wavelength λ₂ is 400 nm or more, the substance absorbing light having the dominant wavelength λ₂ has absorption in a wavelength range of 400 nm or more.
(4) In a case where the dominant wavelength λ₂ is less than 400 nm, the substance absorbing light having the dominant wavelength λ₂ has absorption in a wavelength range less than 400 nm.

The content of the substance absorbing light having the dominant wavelength λ₁ or the dominant wavelength λ₂ is preferably 30% by mass or less with respect to the total mass of the layer containing such a substance. Minimizing the content of the substance absorbing light having the dominant wavelength λ₁ or the dominant wavelength λ₂ makes it possible to suppress deterioration of the original function of the layer containing such a substance. The lower limit of the content of the substance absorbing light having the dominant wavelength λ₁ or the dominant wavelength λ₂ may be determined based on the amount of light obtained in a case where the reflected exposure light reaches the photosensitive layer again (hereinafter, in this paragraph, the amount of light will be called “amount of reflected light”). It is preferable to adjust the content of the substance absorbing light having the dominant wavelength λ₁ or the dominant wavelength λ₂, such that the ratio of the amount of reflected light to the amount of exposure light incident on the target photosensitive layer is 50% or less (preferably 20% or less and more preferably 10% or less). The amount of reflected light is calculated, for example, based on the absorbance and reflectivity of the photosensitive layer, the absorbance and reflectivity of the substrate, the absorbance and reflectivity of a photo mask, and the absorbance of the substance absorbing light having the dominant wavelength λ₁ or the dominant wavelength λ₂.

### Other Layers

The laminate may have layers other than the layers described above (hereinafter, called “other layers” in some cases). Examples of those other layers include a temporary support and a protective film.

The temporary support will be described below. As will be described later, the temporary support is a member used, for example, in a case where the photosensitive layer is formed using a transfer material. In a case where the laminate has a temporary support, generally, the temporary support may be disposed on at least one surface of the laminate. Specifically, the temporary support may be disposed on the outermost layer on a side of the substrate where the first photosensitive layer is disposed. The temporary support may be disposed on the outermost layer on a side of the substrate where the second photosensitive layer is disposed.

Examples of the temporary support include a glass substrate, a resin film, and paper. From the viewpoint of strength and flexibility, the temporary support is preferably a resin film. Examples of the resin film include a polyethylene terephthalate film, a cellulose triacetate film, a polystyrene film, and a polycarbonate film. The temporary support is preferably a polyethylene terephthalate film, and more preferably a biaxially stretched polyethylene terephthalate film.

As the temporary support, it is possible to use a film that is flexible and is not significantly deformed, shrinks, or is stretched under pressure or under pressure with heating. Examples of such a film include a polyethylene terephthalate film (for example, a biaxially stretched polyethylene terephthalate film), a cellulose triacetate film, a polystyrene film, a polyimide film, and a polycarbonate film. Among these, as the temporary support, a biaxially stretched polyethylene terephthalate film is particularly preferable. Furthermore, it is preferable that the film used as the temporary support do not have deformation, such as wrinkles, scratches, and the like.

It is preferable that the temporary support have high transparency, because such a temporary support makes it possible to perform pattern exposure through the temporary support. The transmittance of the temporary support at 365 nm is preferably 60% or more, and more preferably 70% or more.

From the viewpoint of pattern forming properties during pattern exposure through the temporary support and transparency of the temporary support, it is preferable that the haze of the temporary support be low. Specifically, the haze of the temporary support is preferably 2% or less, more preferably 0.5% or less, and particularly preferably 0.3% or less.

From the viewpoint of pattern forming properties during pattern exposure through the temporary support and transparency of the temporary support, it is preferable that the number of fine particles, foreign substances, and defects contained in the temporary support be small. The number of fine particles having a diameter of 1 µm or more, foreign substances, and defects is preferably 50/10 mm² or less, more preferably 10/10 mm² or less, even more preferably 3/10 mm² or less, and particularly preferably 0/10 mm².

The thickness of the temporary support is not particularly limited, but is preferably 5 µm to 200 µm From the viewpoint of ease of handling and general-purpose properties, the thickness of the temporary support is more preferably 10 µm to 150 µm, and even more preferably 10 µm to 50 µm.

Preferred aspects of the temporary support are described, for example, in paragraphs “0017” and “0018” of JP2014-85643A, paragraphs “0019” to “0026” of JP2016-27363A, paragraphs “0041” to “0057” of WO2012/081680A, and paragraphs “0029” to “0040” of WO2018/179370A, and the contents of these publications are incorporated into the present specification.

In a case where the laminate has a protective film, generally, the protective film may be disposed on at least one surface of the laminate. Specifically, the protective film may be disposed on the outermost layer on a side of the substrate where the first photosensitive layer is disposed. The protective film may also be disposed on the outermost layer on a side of the substrate where the second photosensitive layer is disposed.

The protective film will be described below. Examples of the protective film include a resin film and paper. From the viewpoint of strength and flexibility, the protective film is preferably a resin film. Examples of the resin film include a polyethylene film, a polypropylene film, a polyethylene terephthalate film, a cellulose triacetate film, a polystyrene film, and a polycarbonate film. The resin film is preferably a polyethylene film, a polypropylene film, or a polyethylene terephthalate film.

It is preferable that the protective film have light transmittance. In a case where the protective film having light transmittance, exposure can be performed through the protective film.

The thickness of the protective film is not limited. The average thickness of the protective film may be determined, for example, in a range of 1 µm to 2 mm. The average thickness of the protective film is measured by a method based on the method of measuring the average thickness of the substrate described above.

Examples of other layers also include a thermoplastic resin layer and an interlayer.

The thermoplastic resin layer will be described below. The thermoplastic resin layer contains resins. Some or all of the resins are preferably a thermoplastic resin. The thermoplastic resin layer preferably contains a thermoplastic resin.

The thermoplastic resin is preferably an alkali-soluble resin. Examples of the alkali-soluble resin include an acrylic resin, a polystyrene resin, a styrene-acrylic copolymer, a polyurethane resin, polyvinyl alcohol, polyvinyl formal, a polyamide resin, a polyester resin, an epoxy resin, a polyacetal resin, a polyhydroxystyrene resin, a polyimide resin, a polybenzoxazole resin, a polysiloxane resin, polyethyleneimine, polyallylamine, and polyalkylene glycol.

From the viewpoint of developability and adhesiveness with the adjacent layer, the alkali-soluble resin is preferably an acrylic resin. The acrylic resin means a resin having at least one constitutional unit selected from the group consisting of a constitutional unit derived from a (meth)acrylic acid, a constitutional unit derived from a (meth)acrylic acid ester, and a constitutional unit derived from a (meth)acrylic acid amide. In the acrylic resin, the total content of the constitutional unit derived from a (meth)acrylic acid, the constitutional unit derived from a (meth)acrylic acid ester, and the constitutional unit derived from a (meth)acrylic acid amide is preferably 50% by mass or more with respect to the total mass of the acrylic resin. Particularly, the total content of the constitutional unit derived from a (meth)acrylic acid and the constitutional unit derived from a (meth)acrylic acid ester with respect to the total mass of the acrylic resin is preferably 30% by mass to 100% by mass, and more preferably 50% by mass to 100% by mass.

The alkali-soluble resin is preferably a polymer having an acid group. Examples of the acid group include a carboxy group, a sulfo group, a phosphoric acid group, and a phosphonic acid group. Among these, a carboxy group is preferable.

From the viewpoint of developability, the alkali-soluble resin is preferably an alkali-soluble resin having an acid value of 40 mgKOH/g or more, and more preferably a carboxy group-containing acrylic resin having an acid value of 40 mgKOH/g or more. The acid value of the alkali-soluble resin is preferably 300 mgKOH/g or less, more preferably 250 mgKOH/g or less, even more preferably 200 mgKOH/g or less, and particularly preferably 160 mgKOH/g or less.

Examples of the carboxy group-containing acrylic resin having an acid value of 60 mgKOH/g or more include an alkali-soluble resin which is a carboxy group-containing acrylic resin having an acid value of 60 mgKOH/g or more among the polymers described in paragraph “0025” of JP2011-095716A, a carboxy group-containing acrylic resin having an acid value of 60 mgKOH/g or more among the polymers described in paragraphs “0033” to “0052” of JP2010-237589A, and a carboxy group-containing acrylic resin having an acid value of 60 mgKOH/g or more among the binder polymers described in paragraphs “0053” to “0068” of JP2016-224162A. In the carboxy group-containing acrylic resin, the copolymerization ratio of the constitutional unit having a carboxy group with respect to the total mass of the acrylic resin is preferably 5% by mass to 50% by mass, more preferably 10% by mass to 40% by mass, and particularly preferably 12% by mass to 30% by mass. As the alkali-soluble resin, from the viewpoint of developability and adhesiveness with the adjacent layer, an acrylic resin having a constitutional unit derived from a (meth)acrylic acid is particularly preferable.

The alkali-soluble resin may have a reactive group. Examples of the reactive group include an addition polymerizable group. Examples of the reactive group include an ethylenically unsaturated group, a polycondensable group (for example, a hydroxy group and a carboxy group), and a polyaddition reactive group (for example, an epoxy group and a (blocked) isocyanate group).

The weight-average molecular weight (Mw) of the alkali-soluble resin is preferably 1,000 or more, more preferably 10,000 to 100,000, and particularly preferably 20,000 to 50,000.

One alkali-soluble resin or two or more alkali-soluble resins may be used.

From the viewpoint of developability and adhesiveness with the adjacent layer, the content of the alkali-soluble resin with respect to the total mass of the thermoplastic resin layer is preferably 10% by mass to 99% by mass, more preferably 20% by mass to 90% by mass, even more preferably 40% by mass to 80% by mass, and particularly preferably 50% by mass to 75% by mass.

It is preferable that the thermoplastic resin layer contain a colorant (hereinafter, called “colorant B” in some cases) that has a maximum absorption wavelength of 450 nm or more in a wavelength range of 400 nm to 780 nm in a case where the colorant develops color and goes through a change of the maximum absorption wavelength by an acid, base, or radicals. From the viewpoint of visibility of an exposed portion and an unexposed portion and resolution, the colorant B is preferably a colorant that goes through a change of the maximum absorption wavelength by an acid or radicals, and more preferably a colorant that goes through a change of the maximum absorption wavelength by an acid. From the viewpoint of visibility of an exposed portion and an unexposed portion and resolution, the thermoplastic resin layer preferably contains both the colorant that goes through a change of the maximum absorption wavelength by an acid as the colorant B and the compound that generates an acid by light.

One colorant B or two or more colorants B may be used.

From the viewpoint of visibility of an exposed portion and an unexposed portion, the content of the colorant B with respect to the total mass of the thermoplastic resin layer is preferably 0.2% by mass or more, more preferably 0.2% by mass to 6% by mass, even more preferably 0.2% by mass to 5% by mass, and particularly preferably 0.25% by mass to 3.0% by mass.

The content of the colorant B means the content of the colorant determined in a case where the entirety of the colorant B contained in the thermoplastic resin layer is caused to develop color. A method of quantifying the content of the colorant B will be described below by using a colorant that develops color by radicals as an example. A solution is prepared by dissolving 0.001 g of a colorant in 100 mL of methyl ethyl ketone. Furthermore, a solution is prepared by dissolving 0.01 g of a colorant in 100 mL of methyl ethyl ketone. A photoradical polymerization initiator Irgacure OXE01 (trade name, BASF Japan Ltd.) is added to each of the obtained solutions, and the solutions are irradiated with light of 365 nm, such that radicals are generated and the entire colorant develops color. Thereafter, in the atmosphere, the absorbance of each of the solutions at a liquid temperature of 25° C. is measured using a spectrophotometer (UV3100, manufactured by Shimadzu Corporation), and a calibration curve is created. Then, the absorbance of a solution containing a colorant caused to develop color entirely is measured by the same method as the above method, except that 0.1 g of the thermoplastic resin layer is dissolved in methyl ethyl ketone instead of the colorant. From the obtained absorbance of the solution containing the thermoplastic resin layer, the amount of the colorant contained in the thermoplastic resin layer is calculated based on the calibration curve.

The thermoplastic resin layer may contain a compound that generates an acid, a base, or radicals by light (hereinafter, called “compound C” in some cases). As the compound C, a compound is preferable which generates an acid, a base, or radicals by receiving actinic rays such as ultraviolet rays and visible rays. As the compound C, known photoacid generators, photobase generators, and photoradical polymerization initiators (photoradical generators) can be used.

From the viewpoint of resolution, the thermoplastic resin layer may contain a photoacid generator. Examples of the photoacid generator include a photocationic polymerization initiator.

From the viewpoint of sensitivity and resolution, the photoacid generator preferably includes at least one compound selected from the group consisting of an onium salt compound and an oxime sulfonate compound. From the viewpoint of sensitivity, resolution, and adhesiveness, the photoacid generator more preferably includes an oxime sulfonate compound. As the photoacid generator, photoacid generators having the following structures are also preferable.

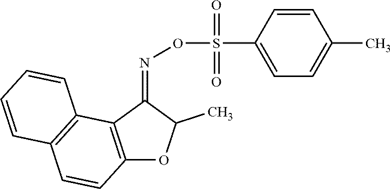 [SMILES: Cc1ccc(S(=O)(=O)O/N=C2/c3c(ccc4ccccc34)OC2C)cc1]

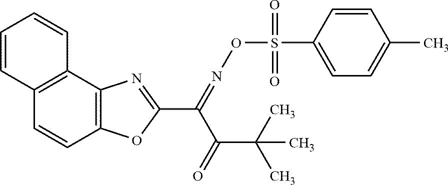 [SMILES: Cc1ccc(S(=O)(=O)ON=C(C(=O)C(C)(C)C)c2nc3c(ccc4ccccc43)o2)cc1]

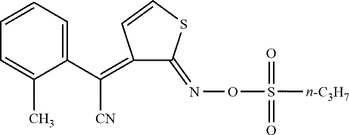

The thermoplastic resin layer may contain a photoradical polymerization initiator. Examples of the photoradical polymerization initiator include a photoradical polymerization initiator among the photopolymerization initiators that may be contained in the aforementioned negative tone photosensitive layer.

The thermoplastic resin layer may contain a photobase generator. Examples of the photobase generator include 2-nitrobenzylcyclohexylcarbamate, triphenylmethanol, O-carbamoylhydroxylamide, O-carbamoyloxime, [[(2,6-dinitrobenzyl)oxy]carbonyl]cyclohexylamine, bis[[(2-nitrobenzyl)oxy]carbonyl]hexane 1,6-diamine, 4-(methylthiobenzoyl)-1-methyl-1-morpholinoethane, (4-morpholinobenzoyl)-1-benzyl-1-dimethylaminopropane, N-(2-nitrobenzyloxycarbonyl)pyrrolidine, hexaamminecobalt (III) tris(triphenylmethylborate), 2-benzyl-2-dimethylamino-1-(4-morpholinophenyl)butanone, 2,6-dimethyl-3,5-diacetyl-4-(2-nitrophenyl)-1,4-dihydropyridine, and 2,6-dimethyl-3,5-diacetyl-4-(2,4-dinitrophenyl)-1,4-dihydropyridine.

One compound C or two or more compounds C may be used.

From the viewpoint of visibility of an exposed portion and an unexposed portion and resolution, the content of the compound C with respect to the total mass of the thermoplastic resin layer is preferably 0.1% by mass to 10% by mass, and more preferably 0.5% by mass to 5% by mass.

From the viewpoint of resolution, adhesiveness with the adjacent layer, and developability, it is preferable that the thermoplastic resin layer contain a plasticizer. It is preferable that the molecular weight (weight-average molecular weight in a case where the plasticizer is an oligomer or polymer and has a molecular weight distribution) of the plasticizer is smaller than the molecular weight of the alkali-soluble resin. The molecular weight (weight-average molecular weight) of the plasticizer is preferably 200 to 2,000. The plasticizer is not particularly limited as long as it is a compound that exhibits plasticity by being compatible with the alkali-soluble resin. From the viewpoint of imparting plasticity, the plasticizer is preferably a compound having an alkyleneoxy group in the molecule, and more preferably a polyalkylene glycol compound. The alkyleneoxy group contained in the plasticizer more preferably has a polyethyleneoxy structure or a polypropyleneoxy structure.

From the viewpoint of resolution and storage stability, the plasticizer preferably includes a (meth)acrylate compound. From the viewpoint of compatibility, resolution, and adhesiveness with the adjacent layer, the alkali-soluble resin is more preferably an acrylic resin and the plasticizer more preferably includes a (meth)acrylate compound. Examples of the (meth)acrylate compound used as the plasticizer include the (meth)acrylate compounds described above the polymerizable compound contained in the negative tone photosensitive layer.

In a case where the thermoplastic resin layer contains a (meth)acrylate compound as a plasticizer, from the viewpoint of adhesiveness between the thermoplastic resin layer and the adjacent layer, it is preferable that the (meth)acrylate compound be not polymerized in an exposed portion after exposure. From the viewpoint of resolution of the thermoplastic resin layer, adhesiveness with the adjacent layer, and developability, the (meth)acrylate compound used as a plasticizer is preferably a polyfunctional (meth)acrylate compound having two or more (meth)acryloyl groups in one molecule. In addition, as the (meth)acrylate compound used as a plasticizer, a (meth)acrylate compound having an acid group or a urethane (meth)acrylate compound is also preferable.

One plasticizer or two or more plasticizers may be used.

From the viewpoint of resolution of the thermoplastic resin layer, adhesiveness with the adjacent layer, and developability, the content of the plasticizer with respect to the total mass of the thermoplastic resin layer is preferably is 1% by mass to 70% by mass, more preferably 10% by mass to 60% by mass, and particularly preferably 20% by mass to 50% by mass.

The thermoplastic resin layer may contain a sensitizer. The sensitizer is not particularly limited, and examples thereof include sensitizers that may be contained in the negative tone photosensitive layer described above.

One sensitizer or two or more sensitizers may be used.

The content of the sensitizer can be appropriately selected according to the purpose. From the viewpoint of improving sensitivity to a light source and visibility of an exposed and an unexposed portion, the content of the sensitizer with respect to the total mass of the thermoplastic resin layer is preferably 0.01% by mass to 5% by mass, and more preferably 0.05% by mass to 1% by mass.

As necessary, the thermoplastic resin layer may contain known additives, such as a surfactant, in addition to the above components. The thermoplastic resin layer is described in paragraphs “0189” to “0193” of JP2014-085643A, and the contents of the publication are incorporated into the present specification.

From the viewpoint of adhesiveness with the adjacent layer, the thickness of the thermoplastic resin layer is preferably 1 µm or more, and more preferably 2 µm or more. From the viewpoint of resolution and developability, the thickness of the thermoplastic resin layer is preferably 20 µm or less, more preferably 10 µm or less, and particularly preferably 8 µm or less.

Hereinafter, the interlayer will be described. As the interlayer, for example, a water-soluble resin layer containing a water-soluble resin is used. As the interlayer, for example, the oxygen barrier layer functioning as an oxygen barrier described as “separation layer” in JP1993-072724A (JP-H05-072724A) is also used. In a case where the interlayer is an oxygen barrier layer, the sensitivity during exposure is improved, the time load on the exposure machine is reduced, and productivity is improved. The oxygen barrier layer used as the interlayer may be appropriately selected from known layers. The oxygen barrier layer is preferably a layer that exhibits low oxygen permeability and is dispersed or dissolved in water or an alkaline aqueous solution (for example, 1% by mass aqueous solution of sodium carbonate at 22° C.).

The interlayer is preferably disposed between the photosensitive layer and the thermoplastic resin layer.

The water-soluble resin layer, which is a sort of interlayer, contains resins. Some or all of the resins are a water-soluble resin. Examples of resins that can be used as a water-soluble resin include a polyvinyl alcohol-based resin, a polyvinylpyrrolidone-based resin, a cellulose-based resin, an acrylamide-based resin, a polyethylene oxide-based resin, gelatin, a vinyl ether-based resin, and a polyamide-based resin. Examples of the water-soluble resin also include a (meth)acrylic acid/vinyl compound copolymer. As the (meth)acrylic acid/vinyl compound copolymer, a (meth)acrylic acid/allyl (meth)acrylate copolymer is preferable, and a methacrylic acid/allyl methacrylate copolymer is more preferable. In a case where the water-soluble resin is a (meth)acrylic acid/vinyl compound copolymer, the compositional ratio (mol %) of each component is, for example, preferably 90/10 to 20/80, and more preferably 80/20 to 30/70.

The weight-average molecular weight of the water-soluble resin is preferably 5,000 or more, more preferably 7,000 or more, and particularly preferably 10,000 or more. Furthermore, the weight-average molecular weight of the water-soluble resin is preferably 200,000 or less, more preferably 100,000 or less, and particularly preferably 50,000 or less. The dispersity (Mw/Mn) of the water-soluble resin is preferably 1 to 10, and more preferably 1 to 5.

In view of further improving the ability of the water-soluble resin layer to suppress interlayer mixing, the resin in the water-soluble resin layer is preferably a resin different from both the resin contained in the layer disposed on one surface side of the water-soluble resin layer and the resin contained in the layer disposed on the other surface side of the water-soluble resin layer.

In view of further improving the oxygen barrier properties and the ability to suppress interlayer mixing, the water-soluble resin preferably contains polyvinyl alcohol, and more preferably contains both the polyvinyl alcohol and polyvinylpyrrolidone.

One water-soluble resin or two or more water-soluble resins may be used.

In view of further improving the oxygen barrier properties and the ability to suppress interlayer mixing, the content of the water-soluble resin with respect to the total mass of the water-soluble resin layer is preferably 50% by mass or more, more preferably 70% by mass or more, even more preferably 80% by mass or more, and particularly preferably 90% by mass or more. The upper limit of the content of the water-soluble resin is not limited. The content of the water-soluble resin with respect to the total mass of the water-soluble resin layer is preferably 99.9% by mass or less, and more preferably 99.8% by mass or less.

As necessary, the interlayer may contain known additives such as a surfactant. Examples of the surfactant include the surfactants described above in the section of “Positive tone photosensitive layer”.

The thickness of the interlayer is preferably 0.1 µm to 5 µm, and more preferably 0.5 µm to 3 µm In a case where the thickness of the interlayer is within the above range, the oxygen barrier properties do not deteriorate, and the ability to suppress interlayer mixing is excellent. In addition, it is possible to suppress an increase in the time taken for removing the interlayer during development.

### Manufacturing Method of Laminate

As the manufacturing method of the laminate, known methods can be used without limitation. Examples thereof include a method of forming the first photosensitive layer on one surface of the substrate and then forming the second photosensitive layer on the other surface of the substrate. The first photosensitive layer and the second photosensitive layer may be formed simultaneously or separately. Hereinafter, the first photosensitive layer and the second photosensitive layer will be collectively called “photosensitive layer” in some cases. The term “photosensitive layer” includes either or both of the first photosensitive layer and the second photosensitive layer.

As the method of forming the photosensitive layer, known methods can be used without limitation. Examples of the method of forming the photosensitive layer include a coating method and a method using a transfer material.

The methods of forming the first photosensitive layer and the second photosensitive layer may be the same as or different from each other. For example, the first photosensitive layer and the second photosensitive layer may be formed by a coating method or a method using a transfer material. Alternatively, one of the first photosensitive layer and the second photosensitive layer may be formed by a coating method, and the other may be formed using a transfer material.

### Coating Method

As the coating method, known methods can be used without limitation. For example, by coating the substrate with a composition for forming a photosensitive layer, it is possible to form the photosensitive layer. As necessary, the composition for forming a photosensitive layer with which the substrate is coated may be dried by a known method.

Examples of the method of preparing the composition for forming a photosensitive layer include a method of mixing raw materials of a target photosensitive layer with a solvent at an arbitrary ratio. As the mixing method, known methods can be used without limitation. The composition for forming a photosensitive layer may be filtered using a filter having a pore diameter of 0.2 µm or the like.

Examples of the solvent include ethylene glycol monoalkyl ethers, ethylene glycol dialkyl ethers, ethylene glycol monoalkyl ether acetates, propylene glycol monoalkyl ethers, propylene glycol dialkyl ethers, propylene glycol monoalkyl ether acetates, diethylene glycol dialkyl ethers, diethylene glycol monoalkyl ether acetates, dipropylene glycol monoalkyl ethers, dipropylene glycol dialkyl ethers, dipropylene glycol monoalkyl ether acetates, esters, ketones, amides, and lactones. Examples of the solvent also include the solvents described in paragraphs “0174” to “0178” of JP2011-221494A and the solvents described in paragraphs “0092” to “0094” of WO2018/179640A, and the contents of these publications are incorporated into the present specification by reference.

As necessary, benzyl ethyl ether, dihexyl ether, ethylene glycol monophenyl ether acetate, diethylene glycol monomethyl ether, diethylene glycol monoethyl ether, isophorone, caproic acid, caprylic acid, 1-octanol, 1-nonanol, benzyl alcohol, anisole, benzyl acetate, ethyl benzoate, diethyl oxalate, diethyl maleate, ethylene carbonate, or propylene carbonate may be added to the aforementioned solvent.

As the solvent, a solvent having a boiling point of 130° C. or higher and lower than 160° C., a solvent having a boiling point of 160° C. or higher, or a mixture of these is preferable.

Examples of the solvent having a boiling point of 130° C. or higher and lower than 160° C. include propylene glycol monomethyl ether acetate (boiling point 146° C.), propylene glycol monoethyl ether acetate (boiling point 158° C.), propylene glycol methyl-n-butyl ether (boiling point 155° C.), and propylene glycol methyl-n-propyl ether (boiling point 131° C.).

Examples of the solvent having a boiling point of 160° C. or higher include ethyl 3-ethoxypropionate (boiling point of 170° C.), diethylene glycol methyl ethyl ether (boiling point of 176° C.), propylene glycol monomethyl ether propionate (boiling point of 160° C.), dipropylene glycol methyl ether acetate (boiling point 213° C.), 3-methoxybutyl ether acetate (boiling point 171° C.), diethylene glycol diethyl ether (boiling point 189° C.), diethylene glycol dimethyl ether (boiling point 162° C.), propylene glycol diacetate (boiling point 190° C.), diethylene glycol monoethyl ether acetate (boiling point 220° C.), dipropylene glycol dimethyl ether (boiling point 175° C.), and 1,3-butylene glycol diacetate (boiling point 232° C.).

The Composition for forming a photosensitive layer may contain one solvent or two or more solvents. In the composition for forming a photosensitive layer, it is preferable that two or more solvents be used in combination. In a case where two or more solvents are used in combination, for example, it is preferable to use a combination of propylene glycol monoalkyl ether acetates and dialkyl ethers, a combination of diacetates and diethylene glycol dialkyl ethers, or a combination of esters and butylene glycol alkyl ether acetates.

The content of the solvent with respect to 100 parts by mass of total solid content in the composition for forming a photosensitive layer is preferably 50 parts by mass to 1,900 parts by mass, and more preferably 100 parts by mass to 900 parts by mass.

Examples of methods of coating with the composition for forming a photosensitive layer include slit coating, spin coating, curtain coating, and ink jet coating. The method of coating with the composition for forming a photosensitive layer is preferably slit coating.

### Transfer Step

Examples of the method using a transfer material include a method of bonding a substrate and a transfer material together. For example, bonding together a substrate and a transfer material having the temporary support and the first photosensitive layer makes it possible to transfer the first photosensitive layer to the substrate.

It is preferable to performing bonding of the substrate and the transfer material while applying pressure and heat by using a roll or the like. The pressure may be determined, for example, in a range of linear pressure of 1,000 N/m to 10,000 N/m. The temperature may be determined, for example, in a range of 40° C. to 130° C. In a case where at least any one of the pressure or heat is lower than the above range, there is a possibility that air which can be entrapped during lamination will not be sufficiently pushed out from between the substrate and the photosensitive layer. In a case where the pressure is higher than the above range, the photosensitive layer is likely to be deformed. In a case where the temperature is higher than the above range, the photosensitive layer is likely to be decomposed or altered due to heat and to have an undesirable shape.

For the bonding of the substrate and the transfer material, for example, it is possible to use a laminator, a vacuum laminator, and an auto cut laminator that can further increase productivity. The bonding of the substrate and the transfer material can also be performed by roll-to-roll depending on the material of the substrate.

The transfer of the first photosensitive layer to the substrate and the transfer of the second photosensitive layer to the substrate may be performed simultaneously or separately.

The transfer material can be formed by, for example, forming a photosensitive layer by means of coating the temporary support with the composition for forming a photosensitive layer. As necessary, the composition for forming a photosensitive layer with which the temporary support is coated may be dried by a known method. Examples of the temporary support include the temporary supports described in the section of “Other layers” described above, and preferred temporary supports are the same as described above.

In a case where the transfer material has the temporary support and the photosensitive layer, a protective film may be disposed on the surface of the photosensitive layer opposite to the surface on which the temporary support is disposed. Examples of the protective film include the protective films described in the section of “other layers” described above, and preferred protective films are the same as described above.

### Exposure Step (1)

The pattern forming method according to the present disclosure includes a step of exposing the first photosensitive layer (exposure step (1)). In the exposure step (1), the exposed first photosensitive layer (that is, the exposed portion) goes through a change of the solubility in a developer. For example, in a case where the first photosensitive layer is a positive tone photosensitive layer, the solubility of the exposed portion in a developer is higher than the solubility of an unexposed portion in a developer. For example, in a case where the first photosensitive layer is a negative tone photosensitive layer, the solubility of the exposed portion in a developer is lower than the solubility of an unexposed portion in a developer.

Examples of the method of exposing the first photosensitive layer include a method using a photo mask. For example, by disposing a photo mask between the first photosensitive layer and a light source, it is possible to expose the first photosensitive layer through the photo mask in a patterned manner. Performing pattern exposure on the first photosensitive layer makes it possible to form an exposed portion and an unexposed portion in the first photosensitive layer.

In the exposure step (1), it is preferable that the first photosensitive layer and the photo mask are brought into contact with each other for exposure. The method of bringing the first photosensitive layer and the photo mask into contact with each other for exposure (also called “contact exposure”) can improve resolution.

In the exposure step (1), in addition to the contact exposure described above, a proximity exposure method, a lens-based or mirror-based projection exposure method, or a direct exposure method using an exposure laser or the like can be appropriately selected and used. In the case of lens-based projection exposure method, according to the required resolving power and focal depth, it is possible to use an exposure machine having an appropriate numerical aperture (NA) of a lens. In the case of direct exposure method, drawing may be performed directly on the photosensitive layer, or shrinking projection exposure may be performed on the photosensitive layer via a lens. The exposure may be performed not only in the atmosphere, but also in an environment with a reduced pressure or in a vacuum. Furthermore, the exposure may be performed in a state where a liquid such as water is interposed between a light source and the photosensitive layer.

In a case where a protective film is disposed on the first photosensitive layer, the first photosensitive layer may be exposed through the protective film. In a case where exposing the first photosensitive layer by contact exposure, from the viewpoint of preventing the contamination of the photo mask and preventing the foreign substances having adhered to the photo mask from affecting exposure, the first photosensitive layer is preferably exposed through the protective film. In a case where the first photosensitive layer is exposed through the protective film, it is preferable to perform the developing step (1), which will be described later, after removing the protective film.

The protective film used in a case where the first photosensitive layer is exposed through the protective film is preferably a film capable of transmitting light radiated during exposure. As the protective film, for example, among the protective films described above in the section of “Other layers”, the protective film capable of transmitting the light radiated during exposure may be used.

In a case where the first photosensitive layer is exposed through the protective film, the protective film may be disposed on the first photosensitive layer at least before the exposure step (1).

In a case where a temporary support is disposed on the first photosensitive layer, the first photosensitive layer may be exposed through the temporary support or may be exposed after the temporary support is removed from the first photosensitive layer. In a case where exposing the first photosensitive layer by contact exposure, from the viewpoint of preventing the contamination of the photo mask and preventing the foreign substances having adhered to the photo mask from affecting exposure, the first photosensitive layer is preferably exposed through the temporary support. In a case where the first photosensitive layer is exposed through the temporary support, it is preferable to perform the developing step (1), which will be described later, after removing the temporary support.

The temporary support used in a case where the first photosensitive layer is exposed through the temporary support is preferably a film capable of transmitting light radiated during exposure. As the temporary support, for example, among the temporary supports described above in the section of “Other layers”, the temporary support capable of transmitting the light radiated during exposure may be used.

The light source for exposure is not limited as long as it can radiate light in a wavelength range (for example, 365 nm or 405 nm) capable of changing the solubility of the first photosensitive layer in a developer. Examples of the light source for exposure include an ultra-high-pressure mercury lamp, a high-pressure mercury lamp, a metal halide lamp, and a light emitting diode (LED).

As described above, the dominant wavelength λ₁ of the exposure wavelength in the exposure step (1) may be different from the dominant wavelength λ₂ of the exposure wavelength in the exposure step (2). The exposure wavelength and dominant wavelength λ₁ in the exposure step (1) may be determined, for example, in a wavelength range of 10 nm to 450 nm. The dominant wavelength λ₁ is, for example, preferably in a range of 300 nm to 400 nm or 370 nm to 450 nm, and more preferably in a range of 300 nm to 380 nm or 390 nm to 450 nm.

It is preferable that the exposure wavelength in the exposure step (1) do not include a wavelength of 365 nm. In the present disclosure, “not include a wavelength of 365 nm” means that in a case where the maximum value of intensity (that is, the intensity of the dominant wavelength, the same shall be applied hereinafter) in the entire exposure wavelength range is 100%, the intensity at a wavelength of 365 nm is 30% or less. In a case where the maximum value of the intensity in the entire exposure wavelength range is 100%, the intensity at a wavelength of 365 nm is preferably 20% or less, more preferably 10% or less, even more preferably 5% or less, particularly preferably 3% or less, and most preferably 1% or less. The lower limit of the intensity at a wavelength of 365 nm is not limited. In a case where the maximum value of the intensity in the entire exposure wavelength range is 100%, the intensity at a wavelength of 365 nm may be determined, for example, in a range of 0% or more.

In a case where the exposure wavelength in the exposure step (1) does not include a wavelength of 365 nm, the exposure wavelength in the exposure step (1) preferably includes a dominant wavelength in a wavelength range of 370 nm to 450 nm, and the intensity at a wavelength of 365 nm is preferably 30% or less in a case where the intensity of the dominant wavelength is 100%; the exposure wavelength in the exposure step (1) more preferably includes a dominant wavelength in a wavelength range of 380 nm to 430 nm, and the intensity at a wavelength of 365 nm is more preferably 30% or less in a case where the intensity of the dominant wavelength is 100%; and the exposure wavelength in the exposure step (1) particularly preferably includes a dominant wavelength in a wavelength range of 390 nm to 420 nm, and the intensity at a wavelength of 365 nm is particularly preferably 30% or less in a case where the intensity of the dominant wavelength is 100%. In a case where the intensity of the dominant wavelength is 100%, the intensity at a wavelength of 365 nm is preferably 20% or less, more preferably 10% or less, even more preferably 5% or less, particularly preferably 3% or less, and most preferably 1% or less. The lower limit of the intensity at a wavelength of 365 nm is not limited. In a case where the intensity in the dominant wavelength is 100%, the intensity at a wavelength of 365 nm may be determined, for example, in a range of 0% or more.

It is also preferable that the exposure wavelength in the exposure step (1) do not include a wavelength of 405 nm. In the present disclosure, “not include a wavelength of 405 nm” means that the intensity at a wavelength of 405 nm is 30% or less in a case where the maximum value of the intensity in the entire exposure wavelength range is 100%. In a case where the maximum value of the intensity in the entire exposure wavelength range is 100%, the intensity at a wavelength of 405 nm is preferably 20% or less, more preferably 10% or less, even more preferably 5% or less, particularly preferably 3% or less, and most preferably 1% or less. The lower limit of the intensity at a wavelength of 405 nm is not limited. In a case where the maximum value of the intensity in the entire exposure wavelength range is 100%, the intensity at a wavelength of 405 nm may be determined, for example, in a range of 0% or more.

In a case where the exposure wavelength in the exposure step (1) does not include a wavelength of 405 nm, the exposure wavelength in the exposure step (1) preferably includes a dominant wavelength in a wavelength range of 300 nm to 400 nm, and the intensity at a wavelength of 405 nm is preferably 30% or less in a case where the intensity of the dominant wavelength is 100%; the exposure wavelength in the exposure step (1) more preferably includes a dominant wavelength in a wavelength range of 300 nm to 380 nm, and the intensity at a wavelength of 405 nm is more preferably 30% or less in a case where the intensity of the dominant wavelength is 100%; and the exposure wavelength in the exposure step (1) particularly preferably includes a dominant wavelength in a wavelength range of 350 nm to 380 nm, and the intensity at a wavelength of 405 nm is particularly preferably 30% or less in a case where the intensity of the dominant wavelength is 100%. In a case where the intensity of the dominant wavelength is 100%, the intensity at a wavelength of 405 nm is preferably 20% or less, more preferably 10% or less, even more preferably 5% or less, particularly preferably 3% or less, and most preferably 1% or less. The lower limit of the intensity at a wavelength of 405 nm is not limited. In a case where the intensity in the dominant wavelength is 100%, the intensity at a wavelength of 405 nm may be determined, for example, in a range of 0% or more.

In one embodiment, the exposure wavelength in the exposure step (1) is preferably an exposure wavelength that exhibits higher intensity at a wavelength of 365 nm than at a wavelength of 405 nm (hereinafter, described as “condition (1-1)” in this paragraph) or an exposure wavelength that exhibits higher intensity at a wavelength of 405 nm than at a wavelength of 365 nm (hereinafter, described as “condition (1-2)” in this paragraph). In a case where the intensity at a wavelength of 365 nm is 100% in the condition (1-1), the intensity at a wavelength of 405 nm is preferably 80% or less, more preferably 50% or less, even more preferably 20% or less, particularly preferably 10% or less, and most preferably 5% or less. The lower limit of the intensity at a wavelength of 405 nm in the condition (1-1) is not limited. In a case where the intensity at a wavelength of 365 nm is 100% in condition (1-1), the intensity at a wavelength of 405 nm may be determined, for example, in a range of 0% or more. On the other hand, in a case where the intensity at a wavelength of 405 nm is 100% in the condition (1-2), the intensity at a wavelength of 365 nm is preferably 80% or less, more preferably 50% or less, even more preferably 20% or less, particularly preferably 10% or less, and most preferably 5% or less. The lower limit of the intensity at a wavelength of 365 nm in the condition (1-2) is not limited. In a case where the intensity at a wavelength of 405 nm is 100% in the condition (1-2), the intensity at a wavelength of 365 nm may be determined, for example, in a range of 0% or more.

Examples of the method of adjusting the exposure wavelength in the exposure step (1) include a method using a filter having wavelength selectivity and a method using a light source capable of radiating light having a specific wavelength. For example, by exposing the first photosensitive layer through a filter having wavelength selectivity, it is possible to adjust the wavelength of light to reach the first photosensitive layer to be in a specific range.

The exposure amount is preferably 5 mJ/cm² to 1,000 mJ/cm², more preferably 10 mJ/cm² to 500 mJ/cm², and particularly preferably 10 mJ/cm² to 200 mJ/cm². The exposure amount is determined based on the illuminance of the light source and the exposure time. Furthermore, the exposure amount may be measured using a actinometer.

In the exposure step (1), the first photosensitive layer may be exposed without using a photo mask. In a case where the first photosensitive layer is exposed without using a photo mask (hereinafter, called “maskless exposure” in some cases), for example, the first photosensitive layer can be exposed using a direct drawing apparatus. The direct drawing apparatus can directly draw an image by using active energy rays. Examples of the light source in the maskless exposure include a laser (for example, a semiconductor laser, a gas laser, and a solid-state laser) and a mercury short arc lamp (for example, an ultra-high-pressure mercury lamp) that can radiate light having a wavelength of 350 nm to 410 nm. The dominant wavelength λ₁ of the exposure wavelength in the maskless exposure is not limited as long as it is different from the dominant wavelength λ₂ of the exposure wavelength in the exposure step (2). A preferred range of the exposure wavelengths is as described above. The exposure amount is determined based on the illuminance of the light source and the moving speed of the laminate. The drawing pattern can be controlled by a computer.

In the exposure step (1), the first photosensitive layer may be exposed from a side of the substrate on which the first photosensitive layer is disposed or from a side of the substrate on which the second photosensitive layer is disposed. From the viewpoint of suppressing exposure fogging, in the exposure step (1), it is preferable that the first photosensitive layer be exposed from a side of the substrate on which the first photosensitive layer is disposed.

### Exposure Step (2)

The pattern forming method according to the present disclosure includes a step of exposing the second photosensitive layer (exposure step (2)). In the exposure step (2), the solubility of the exposed second photosensitive layer (exposed portion) in a developer changes. For example, in a case where the second photosensitive layer is a positive tone photosensitive layer, the solubility of the exposed portion of the second photosensitive layer in a developer is higher than the solubility of an unexposed portion of the second photosensitive layer in a developer. For example, in a case where the second photosensitive layer is a negative tone photosensitive layer, the solubility of the exposed portion of the second photosensitive layer in a developer is lower than the solubility of an unexposed portion of the second photosensitive layer in a developer.

Examples of the method of exposing the second photosensitive layer include a method using a photo mask. For example, by disposing a photo mask between the second photosensitive layer and a light source, it is possible to expose the second photosensitive layer through the photo mask in a patterned manner. Performing pattern exposure on the second photosensitive layer makes it possible to form an exposed portion and an unexposed portion in the second photosensitive layer.

In the exposure step (2), it is preferable that the laminate and the photo mask are brought into contact with each other for exposure. The method of bringing the laminate and the photo mask into contact with each other for exposure (also called “contact exposure”) can improve resolution.

In a case where a protective film is disposed on the second photosensitive layer, the second photosensitive layer may be exposed through the protective film. In a case where exposing the second photosensitive layer by contact exposure, from the viewpoint of preventing the contamination of the photo mask and preventing the foreign substances having adhered to the photo mask from affecting exposure, the second photosensitive layer is preferably exposed through the protective film. In a case where the second photosensitive layer is exposed through the protective film, it is preferable to perform the developing step (2), which will be described later, after removing the protective film.

The protective film used in a case where the second photosensitive layer is exposed through the protective film is not limited as long as the protective film is a film capable of transmitting light radiated during exposure. As the protective film, for example, among the protective films described above in the section of “Other layers”, the protective film capable of transmitting the light radiated during exposure may be used.

In a case where a temporary support is disposed on the second photosensitive layer, the second photosensitive layer may be exposed through the temporary support or may be exposed after the temporary support is removed from the second photosensitive layer. In a case where the second photosensitive layer is exposed by contact exposure, from the viewpoint of preventing the contamination of the photo mask and preventing the foreign substances having adhered to the photo mask from affecting exposure, the second photosensitive layer is preferably exposed through the temporary support. In a case where the second photosensitive layer is exposed through the temporary support, it is preferable to perform the developing step (2), which will be described later, after removing the temporary support.

The temporary support used in a case where the second photosensitive layer is exposed through the temporary support is preferably a film capable of transmitting light radiated during exposure. As the temporary support, for example, among the temporary supports described above in the section of “Other layers”, the temporary support capable of transmitting the light radiated during exposure may be used.

The light source for exposure is not limited as long as it can radiate light in a wavelength range (for example, 365 nm or 405 nm) capable of changing the solubility of the second photosensitive layer in a developer. Examples of the light source for exposure include an ultra-high-pressure mercury lamp, a high-pressure mercury lamp, a metal halide lamp, and a light emitting diode (LED).

As described above, the dominant wavelength λ₂ of the exposure wavelength in the exposure step (2) may be different from the dominant wavelength λ₁ of the exposure wavelength in the exposure step (1). The exposure wavelength and dominant wavelength λ₂ in the exposure step (2) may be determined, for example, in a wavelength range of 10 nm to 410 nm. The dominant wavelength λ₂ is, for example, preferably in a range of 300 nm to 400 nm or 370 nm to 450 nm. The dominant wavelength λ₂ is more preferably in a range of 300 nm to 380 nm or 390 nm to 450 nm. For example, in a case where the dominant wavelength λ₁ in the exposure step (1) is in a range of 300 nm to 400 nm (preferably 300 nm to 380 nm), the dominant wavelength λ₂ in the exposure step (2) is preferably in a range of 370 nm to 450 nm (preferably 390 nm to 450 nm). For example, in a case where the dominant wavelength λ₁ in the exposure step (1) is in a range of 370 nm to 450 nm (preferably 390 nm to 450 nm), the dominant wavelength λ₂ in the exposure step (2) is preferably in a range of 300 nm to 400 nm (preferably 300 nm to 380 nm).

In a case where the exposure wavelength in the exposure step (1) does not include a wavelength of 365 nm, it is preferable that the exposure wavelength in the exposure step (2) do not include a wavelength of 405 nm. Adopting the aforementioned wavelengths in the exposure step (1) and the exposure step (2) makes it possible to more selectively exposure a specific photosensitive layer. In a case where the maximum value of the intensity in the entire exposure wavelength range is 100%, the intensity at a wavelength of 405 nm is preferably 20% or less, more preferably 10% or less, even more preferably 5% or less, particularly preferably 3% or less, and most preferably 1% or less. The lower limit of the intensity at a wavelength of 405 nm is not limited. In a case where the maximum value of the intensity in the entire exposure wavelength range is 100%, the intensity at a wavelength of 405 nm may be determined, for example, in a range of 0% or more.

In a case where the exposure wavelength in the exposure step (2) does not include a wavelength of 405 nm, the exposure wavelength in the exposure step (2) preferably includes a dominant wavelength in a wavelength range of 300 nm to 400 nm, and the intensity at a wavelength of 405 nm is preferably 30% or less in a case where the intensity of the dominant wavelength is 100%; the exposure wavelength in the exposure step (2) more preferably includes a dominant wavelength in a wavelength range of 300 nm to 380 nm, and the intensity at a wavelength of 405 nm is more preferably 30% or less in a case where the intensity of the dominant wavelength is 100%; and the exposure wavelength in the exposure step (2) particularly preferably includes a dominant wavelength in a wavelength range of 350 nm to 380 nm, and the intensity at a wavelength of 405 nm is particularly preferably 30% or less in a case where the intensity of the dominant wavelength is 100%. In a case where the intensity of the dominant wavelength is 100%, the intensity at a wavelength of 405 nm is preferably 20% or less, more preferably 10% or less, even more preferably 5% or less, particularly preferably 3% or less, and most preferably 1% or less. The lower limit of the intensity at a wavelength of 405 nm is not limited. In a case where the intensity in the dominant wavelength is 100%, the intensity at a wavelength of 405 nm may be determined, for example, in a range of 0% or more.

In a case where the exposure wavelength in the exposure step (1) does not include a wavelength of 405 nm, it is preferable that the exposure wavelength in the exposure step (2) do not include a wavelength of 365 nm. Adopting the aforementioned wavelengths in the exposure step (1) and the exposure step (2) makes it possible to more selectively exposure a specific photosensitive layer. In a case where the maximum value of the intensity in the entire exposure wavelength range is 100%, the intensity at a wavelength of 365 nm is preferably 20% or less, more preferably 10% or less, even more preferably 5% or less, particularly preferably 3% or less, and most preferably 1% or less. The lower limit of the intensity at a wavelength of 365 nm is not limited. In a case where the maximum value of the intensity in the entire exposure wavelength range is 100%, the intensity at a wavelength of 365 nm may be determined, for example, in a range of 0% or more.

In a case where the exposure wavelength in the exposure step (2) does not include a wavelength of 365 nm, the exposure wavelength in the exposure step (2) preferably includes a dominant wavelength in a wavelength range of 370 nm to 450 nm, and the intensity at a wavelength of 365 nm is preferably 30% or less in a case where the intensity of the dominant wavelength is 100%; the exposure wavelength in the exposure step (2) more preferably includes a dominant wavelength in a wavelength range of 380 nm to 430 nm, and the intensity at a wavelength of 365 nm is more preferably 30% or less in a case where the intensity of the dominant wavelength is 100%; and the exposure wavelength in the exposure step (2) particularly preferably includes a dominant wavelength in a wavelength range of 390 nm to 420 nm, and the intensity at a wavelength of 365 nm is particularly preferably 30% or less in a case where the intensity of the dominant wavelength is 100%. In a case where the intensity of the dominant wavelength is 100%, the intensity at a wavelength of 365 nm is preferably 20% or less, more preferably 10% or less, even more preferably 5% or less, particularly preferably 3% or less, and most preferably 1% or less. The lower limit of the intensity at a wavelength of 365 nm is not limited. In a case where the intensity in the dominant wavelength is 100%, the intensity at a wavelength of 365 nm may be determined, for example, in a range of 0% or more.

In a case where the exposure wavelength in the exposure step (1) is “wavelength that exhibits higher intensity at a wavelength of 365 nm than at a wavelength of 405 nm”, the exposure wavelength in the exposure step (2) is preferably an exposure wavelength that exhibits higher intensity at a wavelength of 405 nm than at a wavelength of 365 nm (hereinafter, described as “condition (2-1)” in this paragraph). Preferred aspects of the condition (2-1) are the same as the preferred aspects of the condition (1-2) described above in the section of “Exposure step (1)”. On the other hand, in a case where the exposure wavelength in the exposure step (1) is “wavelength that exhibits higher intensity at a wavelength of 405 nm than at a wavelength of 365 nm”, the exposure wavelength in the exposure step (2) is preferably an exposure wavelength that exhibits higher intensity at a wavelength of 365 nm than at a wavelength of 405 nm (hereinafter, described as “condition (2-2)” in this paragraph). Preferred aspects of the condition (2-1) are the same as the preferred aspects of the condition (1-1) described above in the section of “Exposure step (1)”.

Examples of the method of adjusting the exposure wavelength in the exposure step (2) include a method using a filter having wavelength selectivity and a method using a light source capable of radiating light having a specific wavelength. For example, by exposing the second photosensitive layer through a filter having wavelength selectivity, it is possible to adjust the wavelength of light to reach the second photosensitive layer to be in a specific range.

The exposure amount is preferably 5 mJ/cm² to 1,000 mJ/cm², more preferably 10 mJ/cm² to 500 mJ/cm², and particularly preferably 10 mJ/cm² to 200 mJ/cm². The exposure amount is determined based on the illuminance of the light source and the exposure time. Furthermore, the exposure amount may be measured using a actinometer.

Particularly, it is preferable that the dominant wavelength λ₁ and the dominant wavelength λ₂ have the following aspects.

From the viewpoint of suppressing exposure fogging, the dominant wavelength λ₁ is preferably in a range of more than 395 nm and 500 nm or less, and more preferably in a range of 396 nm or more and 456 nm or less.

From the viewpoint of suppressing exposure fogging, the dominant wavelength λ₂ is preferably in a range of 250 nm or more and 395 nm or less, and more preferably in a range of 335 nm or more and 395 nm or less.

Furthermore, from the viewpoint of suppressing exposure fogging, the dominant wavelength λ₁ is even more preferably in a range of more than 395 nm and 500 nm or less and the dominant wavelength λ₂ is even more preferably in a range of 250 nm or more and 395 nm or less, and the dominant wavelength λ₁ is particularly preferably in a range of more than 396 nm and 456 nm or less and the dominant wavelength λ₂ is particularly preferably in a range of 335 nm or more and 395 nm or less.

In the pattern forming method according to the present disclosure, the exposure amount in the exposure step (1) and the exposure amount in the exposure step (2) may be the same as or different from each other.

In the exposure step (2), the second photosensitive layer may be exposed without using a photo mask. In a case where the first photosensitive layer is exposed without using a photo mask (hereinafter, called “maskless exposure” in some cases), for example, the first photosensitive layer can be exposed using a direct drawing apparatus. The direct drawing apparatus can directly draw an image by using active energy rays. Examples of the light source in the maskless exposure include a laser (for example, a semiconductor laser, a gas laser, and a solid-state laser) and a mercury short arc lamp (for example, an ultra-high-pressure mercury lamp) that can radiate light having a wavelength of 350 nm to 410 nm. The dominant wavelength λ₂ of the exposure wavelength in the maskless exposure is not limited as long as it is different from the dominant wavelength λ₂ of the exposure wavelength in the exposure step (1). A preferred range of the exposure wavelengths is as described above. The exposure amount is determined based on the illuminance of the light source and the moving speed of the laminate. The drawing pattern can be controlled by a computer.

In the exposure step (2), the second photosensitive layer may be exposed from a side of the substrate on which the second photosensitive layer is disposed or from a side of the substrate on which the first photosensitive layer is disposed. The radiation direction of light in the exposure step (1) and the radiation direction of light in the exposure step (2) may be the same as or different from each other. From the viewpoint of suppressing exposure fogging, in the exposure step (2), it is preferable that the second photosensitive layer be exposed from a side of the substrate on which the second photosensitive layer is disposed.

In one embodiment, it is preferable that a member that absorbs the dominant wavelength λ₂ be placed disposed between the first photosensitive layer and the light source for exposing the first photosensitive layer, or that a member that absorbs the dominant wavelength λ₁ be disposed between the second photosensitive layer and the light source for exposing the second photosensitive layer. According to the above embodiment, as described above in the section of “Light absorption characteristics”, it is possible to suppress the deterioration of resolution resulting from re-exposure. That is, the member that is disposed between the first photosensitive layer and the light source for exposing the first photosensitive layer and absorbs the dominant wavelength λ₂ can absorb light having the dominant wavelength λ₂ that is transmitted through the second photosensitive layer and the substrate and light having the dominant wavelength λ₂ that is reflected by a member such as a filter having wavelength selectivity. Therefore, the deterioration of resolution resulting from the re-exposure of the second photosensitive layer is suppressed. On the other hand, the member that is disposed between the second photosensitive layer and the light source for exposing the second photosensitive layer and absorbs the dominant wavelength λ₁ can absorb light having the dominant wavelength λ₁ that is transmitted through the first photosensitive layer and the substrate and light having the dominant wavelength λ₁ that is reflected by a member such as a filter having wavelength selectivity. Therefore, the deterioration of resolution resulting from the re-exposure of the first photosensitive layer is suppressed. The above embodiment includes the following (1) to (3). Among the following (1) to (3), (3) is preferable.
(1) A member that absorbs the dominant wavelength λ₂ is disposed between the first photosensitive layer and a light source for exposing the first photosensitive layer.
(2) A member that absorbs the dominant wavelength λ₁ is disposed between the second photosensitive layer and a light source for exposing the second photosensitive layer.
(3) A member that absorbs the dominant wavelength λ₂ is disposed between the first photosensitive layer and a light source for exposing the first photosensitive layer, and a member that absorbs the dominant wavelength λ₁ is disposed between the second photosensitive layer and a light source for exposing the second photosensitive layer.

The member that absorbs the dominant wavelength λ₁ preferably contains a substance that absorbs the dominant wavelength λ₁. The member that absorbs the dominant wavelength λ₂ preferably contains a substance that absorbs the dominant wavelength λ₂. Examples of the substances absorbing light having the dominant wavelength λ₁ or the dominant wavelength λ₂ include the substances absorbing light having the dominant wavelength λ₁ or the dominant wavelength λ₂ described above in the section of “Light absorption characteristics”. Preferred aspects of the substances absorbing light having the dominant wavelength λ₁ or the dominant wavelength λ₂ are the same as the preferred aspects of the substances absorbing light having the dominant wavelength λ₁ or the dominant wavelength λ₂ described above in the section of “Light absorption characteristics”. Either the member absorbing light having the dominant wavelength λ₂ or the member absorbing the light having the dominant wavelength λ₁ is preferably a member containing a substance having absorption in a wavelength range of 400 nm or more. Examples of the substances having absorption in a wavelength range of 400 nm or more include the substances having absorption in a wavelength region of 400 nm or more described above in the section of “Light absorption characteristics”. Preferred aspects of the substances having absorption in a wavelength range of 400 nm or more are the same as the preferred aspects of the substances having absorption in a wavelength region of 400 nm or more described above in the section of “Light absorption characteristics”.

The content of the substance that absorbs the dominant wavelength λ₁ or the dominant wavelength λ₂ is determined, for example, within a range that does not affect the exposure sensitivity. The lower limit of the content of the substance that absorbs the dominant wavelength λ₁ or the dominant wavelength λ₂ is determined, for example, within the range described above in the section of “Light absorption characteristics”.

In the pattern forming method according to the present disclosure, the exposure step (1) and the exposure step (2) may be performed simultaneously. Furthermore, the exposure step (1) and the exposure step (2) may be performed separately. The exposure step (2) may be performed before the exposure step (1). In addition, the exposure step (2) may be performed after the exposure step (1). From the viewpoint of productivity, it is preferable that the exposure step (1) and the exposure step (2) be performed simultaneously.

In the present disclosure, “the step of exposing the first photosensitive layer (exposure step (1)) and the step of exposing the second photosensitive layer (exposure step (2)) are performed simultaneously” includes not only a case where the first photosensitive layer and the second photosensitive layer are perfectly simultaneously exposed, but also a case where the duration of exposure of the first photosensitive layer and the duration of exposure of the second photosensitive layer overlap each other.

In the present disclosure, “the step of exposing the first photosensitive layer (exposure step (1)) and the step of exposing the second photosensitive layer (exposure step (2)) are performed separately” means that the first photosensitive layer and the second photosensitive layer are independently exposed within a range in which the duration of exposure of the first photosensitive layer and the duration of exposure of the second photosensitive layer do not overlap each other.

### Developing Step (1)

The pattern forming method according to the present disclosure includes a step of developing the exposed first photosensitive layer to form a first resin pattern (developing step (1)). In the developing step (1), for example, by removing a portion from the exposed first photosensitive layer, the portion having relatively high solubility in a developer, it is possible to form the first resin pattern.

In the present disclosure, “exposed first photosensitive layer” means the first photosensitive layer that has undergone the exposure step (1), and is not limited to the exposed portion of the first photosensitive layer.

As the developing method, known methods can be used without limitation. For example, the first photosensitive layer can be developed using a developer.

As the developer, known developers can be used without limitation. Examples of the developer include the developers described in JP1993-72724A (JP-H05-72724A). Examples of preferred developers include the developers described in paragraph “0194” of WO2015/093271A.

The developer is preferably an alkaline aqueous solution-based developer containing a compound having a pKa of 7 to 13. In the alkaline aqueous solution-based developer, the concentration of the compound having a pKa of 7 to 13 is preferably 0.05 mol/L to 5 mol/L.

The developer may contain, as components other than the aforementioned component, an organic solvent miscible with water and a surfactant, for example.

The temperature of the developer is preferably 20° C. to 40° C.

As the developing method, known methods can be used without limitation. Examples of the developing method include puddle development, shower development, shower and spin development, and dip development.

As an example of the developing method, shower development will be described. For example, in a case where the first photosensitive layer is a negative tone photosensitive layer, by spraying the developer onto the exposed first photosensitive layer by using a shower, it is possible to remove an unexposed portion of the first photosensitive layer. Further, after development, it is preferable to remove development residues while spraying a detergent or the like with a shower and rubbing the first photosensitive layer with a brush or the like.

The developing step (1) may include a step of performing a heat treatment (also called “post-baking”) on the first resin pattern.

The heat treatment is performed preferably in an environment of 8.1 kPa to 121.6 kPa, more preferably in an environment of 8.1 kPa to 114.6 kPa, and particularly preferably in an environment of 8.1 kPa to 101.3 kPa.

The temperature of the heat treatment is preferably 20° C. to 250° C., more preferably 30° C. to 170° C., and even more preferably 50° C. to 150° C.

The time of the heat treatment time is preferably 1 minute to 30 minutes, more preferably 2 minutes to 10 minutes, and particularly preferably 2 minutes to 4 minutes.

The heat treatment may be performed in the air or in a nitrogen purged environment.

### Developing Step (2)

The pattern forming method according to the present disclosure includes a step of developing the exposed second photosensitive layer to form a second resin pattern (developing step (2)). In the developing step (2), for example, by removing a portion from the exposed second photosensitive layer, the portion having relatively high solubility in a developer, it is possible to form the second resin pattern.

In the present disclosure, “exposed second photosensitive layer” means the second photosensitive layer that has undergone the exposure step (2), and is not limited to the exposed portion of the second photosensitive layer.

As the developing method, known methods can be used without limitation. For example, the second photosensitive layer can be developed using a developer.

As the developer, known developers can be used without limitation. Examples of the developer include the developers described in JP1993-72724A (JP-H05-72724A). Examples of preferred developers include the developers described in paragraph “0194” of WO2015/093271A.

The developer is preferably an alkaline aqueous solution-based developer containing a compound having a pKa of 7 to 13. In the alkaline aqueous solution-based developer, the concentration of the compound having a pKa of 7 to 13 is preferably 0.05 mol/L to 5 mol/L.

The developer may contain, as components other than the aforementioned component, an organic solvent miscible with water and a surfactant, for example.

The temperature of the developer is preferably 20° C. to 40° C.

As the developing method, known methods can be used without limitation. Examples of the developing method include puddle development, shower development, shower and spin development, and dip development.

As an example of the developing method, shower development will be described. For example, in a case where the second photosensitive layer is a negative tone photosensitive layer, by spraying the developer onto the exposed second photosensitive layer by using a shower, it is possible to remove an unexposed portion of the second photosensitive layer. Further, after development, it is preferable to remove development residues while spraying a detergent or the like with a shower and rubbing the first photosensitive layer with a brush or the like.

The developing step (2) may include a step of performing a heat treatment (also called “post-baking”) on the second resin pattern.

The heat treatment is performed preferably in an environment of 8.1 kPa to 121.6 kPa, more preferably in an environment of 8.1 kPa to 114.6 kPa, and particularly preferably in an environment of 8.1 kPa to 101.3 kPa.

The temperature of the heat treatment is preferably 20° C. to 250° C., more preferably 30° C. to 170° C., and even more preferably 50° C. to 150° C.

The time of the heat treatment time is preferably 1 minute to 30 minutes, more preferably 2 minutes to 10 minutes, and particularly preferably 2 minutes to 4 minutes.

The heat treatment may be performed in the air or in a nitrogen purged environment.

In the pattern forming method according to the present disclosure, the developing step (1) and the developing step (2) may be performed simultaneously. Furthermore, the developing step (1) and the developing step (2) may be performed separately. The developing step (2) may be performed before the developing step (1). In addition, the developing step (2) may be performed after the developing step (1). From the viewpoint of productivity, it is preferable that the developing step (1) and the developing step (2) be performed simultaneously.

In the present disclosure, “the step of developing the exposed first photosensitive layer to form a first resin pattern (developing step (1)) and the step of developing the exposed second photosensitive layer to form a second resin pattern (developing step (2)) are performed simultaneously” includes not only a case where the first photosensitive layer and the second photosensitive layer are perfectly simultaneously developed, but also a case where the duration of development of the first photosensitive layer and the duration of development of the second photosensitive layer overlap each other.

In the present disclosure, “the step of developing the exposed first photosensitive layer to form a first resin pattern (developing step (1)) and the step of developing the exposed second photosensitive layer to form a second resin pattern (developing step (2)) are performed separately” means that the first photosensitive layer and the second photosensitive layer are independently developed within a range in which the duration of development of the first photosensitive layer and the duration of development of the second photosensitive layer do not overlap each other.

In an embodiment, it is preferable that the exposure step (1) and the exposure step (2) be performed simultaneously, and the developing step (1) and the developing step (2) be performed simultaneously. In a case where the exposure step (1) and the exposure step (2) are performed simultaneously, and the developing step (1) and the developing step (2) are performed simultaneously, the photosensitive layers having undergone exposure can stay in the same environment for the same period of time until the development starts. Therefore, it is easy to stabilize the product quality, the process length can be shortened, and the process costs can be reduced. On the other hand, in an embodiment, it is preferable that the exposure step (1) and the exposure step (2) be performed separately, or the developing step (1) and the developing step (2) be performed separately. For example, in a case where the first photosensitive layer and the second photosensitive layer having undergone exposure react significantly different rates, or in a case where different exposure light sources need to be arranged away from the photosensitive layers, it is preferable that the exposure step (1) and the exposure step (2) be performed separately. In addition, for example, in a case where the developer used for developing the first photosensitive layer is different from the developer used for developing the second photosensitive layer, it is preferable that the developing step (1) and the developing step (2) be performed separately.

### Etching Step

In a case where a conductive layer is disposed on at least one surface of the substrate, it is preferable that the pattern forming method according to the present disclosure include a step of etching the conductive layer by using at least one of the first resin pattern or the second resin pattern (hereinafter, called “etching step” in some cases). In a case where the pattern forming method according to the present disclosure includes the etching step, a conductive pattern can be formed on at least one surface of the substrate. For example, in a case where the conductive layer is etched using the first resin pattern as a mask, the conductive layer covered with the first resin pattern remains on the substrate as a conductive pattern. On the other hand, the conductive layer not being covered with the first resin pattern is removed.

Examples of the etching dry etching and wet etching. The etching is preferably wet etching because wet etching does not require a vacuum process, and the process of wet etching is simple. Examples of the etching include the methods described in paragraphs “0048” to “0054” of JP2010-152155A.

Examples of the etchant used in wet etching include an acidic etchant and an alkaline etchant.

Examples of the acidic etchant include an aqueous solution containing acidic components (for example, hydrochloric acid, sulfuric acid, nitric acid, hydrofluoric acid, and phosphoric acid), and an aqueous solution containing acidic components and salts (for example, ferric chloride, ammonium fluoride, ferric nitrate, and potassium permanganate). The acidic etchant may contain one acidic component or two or more acidic components. The acidic etchant may contain one salt or two or more salts.

Examples of the alkaline etchant include an aqueous solution containing alkaline components [for example, sodium hydroxide, potassium hydroxide, ammonia, an organic amine, and a salt of an organic amine (for example, tetramethylammonium hydroxide)], and an aqueous solution containing alkaline components and a salt (for example, potassium permanganate). The alkaline etchant may contain one alkaline component or two or more alkaline components. The alkaline etchant may contain one salt or two or more salts.

From the viewpoint of controlling etching rate, the etchant may contain a rust inhibitor. Examples of the rust inhibitor include a nitrogen-containing compound. Examples of the nitrogen-containing compound include a triazole-based compound, an imidazole-based compound, and a tetrazole-based compound.

From the viewpoint of controlling etching rate, the etchant may contain a surfactant, an organic solvent, a chelating agent, an antioxidant, a pH adjuster, and the like.

The temperature of the etchant is preferably 45° C. or less.

In the pattern forming method according to the present disclosure, it is preferable that each of the first resin pattern used as a mask and the second resin pattern used as a mask exhibit excellent resistance to an etchant at 60° C. or less. In a case where the first resin pattern and the second resin pattern have the above resistance, it is possible to prevent the first resin pattern and the second resin pattern from being removed in the etching step. As a result, in the conductive layer, the portions where the first resin pattern and the second resin pattern do not exist are selectively etched.

In a case where the conductive layer is disposed on both surfaces of the substrate, the conductive layer disposed on one surface of the substrate may be etched, and then the conductive layer disposed on the other surface of the substrate may be etched. Alternatively, the conductive layers disposed on both surfaces of the substrate may be etched simultaneously. In a case where the conductive layer is disposed on both surfaces of the substrate, from the viewpoint of productivity, it is preferable to simultaneously etch the conductive layers disposed both surfaces of the substrate.

### Washing Step and Drying Step

From the viewpoint of preventing contamination of the process line, as necessary, the pattern forming method according to the present disclosure may include a washing step and a drying step after the etching step.

In the washing step, for example, the substrate can be washed with pure water at room temperature (for example, 25° C.). The washing time can be appropriately set, for example, in the range of 10 seconds to 300 seconds.

In the drying step, for example, the substrate can be dried using air blow. The air blow pressure is preferably 0.1 kg/cm² to 5 kg/cm².

### Whole Surface Exposure Step

The pattern forming method according to the present disclosure may include a step of exposing the whole surface of at least one of the first resin pattern or the second resin pattern to light (hereinafter, called “whole surface exposure step” in some cases). The whole surface exposure step is preferably performed before the removal step that will be described later. In a case where the pattern forming method according to the present disclosure includes the whole surface exposure step, it is possible to improve the removability of the resin pattern in the removal step that will be described later, and to further improve the reactivity of the pattern remaining after development. For example, in a case where the whole surface of a resin pattern formed using the positive tone photosensitive layer is exposed, the removability in the removal step that will be described later is further improved. For example, in a case where a resin pattern formed using a negative tone photosensitive layer is exposed, the resin pattern is further cured, which improves the resistance of the resin pattern to the process.

In the whole surface exposure step, at least one of the first resin pattern or the second resin pattern may be exposed. For example, in a case where the where the whole surface of the first resin pattern is exposed, the portion where the first resin pattern is not disposed may or may not be exposed. In addition, in a case where the where the whole surface of the second resin pattern is exposed, the portion where the second resin pattern is not disposed may or may not be exposed.

In the whole surface exposure step, from the viewpoint of simplicity, it is preferable that the whole surface of the substrate be exposed.

As the light source for exposure, known light sources can be used without limitation. Examples of the light source for exposure include an ultra-high-pressure mercury lamp, a high-pressure mercury lamp, a metal halide lamp, and a light emitting diode (LED).

From the viewpoint of removability, the exposure wavelength preferably includes a wavelength of 365 nm or a wavelength of 405 nm.

From the viewpoint of removability, the exposure amount is preferably 5 mJ/cm² to 1,000 mJ/cm², more preferably 10 mJ/cm² to 800 mJ/cm², and particularly preferably 100 mJ/cm² to 500 mJ/cm².

From the viewpoint of removability, the exposure amount is preferably equal to or greater than the exposure amount in at least one of the exposure step (1) or the exposure step (2), and more preferably greater than the exposure amount in at least one of the exposure step (1) or the exposure step (2).

The exposure illuminance is preferably 5 mW/cm² to 25,000 mW/cm², more preferably 20 mW/cm² to 20,000 mW/cm², and particularly preferably 30 mW/cm² to 15,000 mW/cm². Increasing the illuminance shortens the time required to expose the whole surface.

### Heating Step

The pattern forming method according to the present disclosure may include a step of heating at least one of the first resin pattern or the second resin pattern (hereinafter, called “heating step” in some cases) that is performed at least in the middle of the whole surface exposure step or before the whole surface exposure step and the removal step that will be described later. In a case where the pattern forming method according to the present disclosure includes the heating step, it is possible to easily remove the first resin pattern and the second resin pattern. For example, in a resin pattern formed using the positive tone photosensitive layer, the reaction rate of the photoacid generator and the reaction rate of the generated acid and the positive tone photosensitive composition can be improved, which makes it possible to improve removal performance.

As the heating device, known heating devices can be used without limitation. Examples of the heating device include an infrared heater, a hot blower, and a convection oven.

From the viewpoint of removability, the heating temperature is preferably 30° C. to 100° C., more preferably 30° C. to 80° C., and particularly preferably 30° C. to 60° C.

From the viewpoint of removability, the heating time is preferably 1 second to 600 seconds, more preferably 1 second to 120 seconds, and particularly preferably 5 seconds to 60 seconds. “Heating time” means the time calculated from when the surface temperature of the substrate has reached the set temperature, and does not include the time elapsing while temperature is rising.

The heating atmosphere is preferably air (relative humidity: 10% RH to 90% RH). The heating atmosphere may be an inert gas (for example, nitrogen and argon).

The pressure is preferably normal pressure.

In a case where a large amount of water adheres to the substrate, from the viewpoint of improving heating efficiency, a step of blowing off an excess of water with an air knife or the like may be additionally performed at least before the heating step or at least in the middle of the heating step.

### Removal Step

The pattern forming method according to the present disclosure may include a step of removing at least one of the first resin pattern or the second resin pattern (hereinafter, called “removal step” in some cases). Hereinafter, sometimes the first resin pattern and the second resin pattern will be collectively called “resin pattern”. Unless otherwise specified, the term “resin pattern” includes either or both the first resin pattern and the second resin pattern.

Examples of the method of removing the resin pattern include a method of removing the resin pattern using a chemical. In a case where the resin pattern is removed using a chemical, the resin pattern may be dissolved or dispersed in the chemical.

The method of removing the resin pattern is preferably a method of removing the resin pattern by using a remover liquid. For example, by immersing the substrate having the resin pattern in the remover liquid, it is possible to remove the resin pattern.

The temperature of the remover liquid is preferably 30° C. to 80° C., and more preferably 50° C. to 80° C.

The time of immersion in the remover liquid is preferably 1 minute to 30 minutes.

From the viewpoint of removability, the content of water in the remover liquid is preferably 30% by mass or more, more preferably 50% by mass or more, and particularly preferably 70% by mass or more.

The remover liquid preferably contains an inorganic alkaline component or an organic alkaline component. Examples of inorganic alkaline component include sodium hydroxide and potassium hydroxide. Examples of organic alkaline component include a primary amine compound, a secondary amine compound, a tertiary amine compound, and a quaternary ammonium salt compound.

From the viewpoint of removability, the remover liquid preferably contains an organic alkaline component, and more preferably contains an amine compound.

From the viewpoint of removability, the content of the organic alkaline component with respect to the total mass of the remover liquid is preferably 0.01% by mass to 20% by mass, and more preferably 0.1% by mass to 10% by mass.

From the viewpoint of removability, the remover liquid preferably contains a surfactant. As the surfactant, known surfactants can be used without limitation.

From the viewpoint of removability, the content of the surfactant is preferably 0.1% by mass to 10% by mass with respect to the total mass of the remover liquid.

The remover liquid preferably contains a water-soluble organic solvent. Examples of the water-soluble organic solvent include dimethylsulfoxide, a lower alcohol, a glycol ether, and N-methylpyrrolidone.

Examples of the method of bringing the remover liquid into contact with the resin pattern in the removal step include a spray method, a shower method, and a paddle method.

As the remover liquid, it is also possible to use the strippers described in JP1999-021483A (JP-H11-021483A), JP2002-129067A, JP1995-028254A (JP-H07-028254A), JP2001-188363A, JP1992-048633A (JP-H04-048633A), and JP5318773B.

The removal of the first resin pattern and the removal of the second resin pattern may be performed simultaneously or separately. From the viewpoint of productivity, the removal of the first resin pattern and the removal of the second resin pattern are preferably performed simultaneously.

### Roll-to-Roll Method

The pattern forming method according to the present disclosure is preferably performed by a roll-to-roll method. As the roll-to-roll method, known roll-to-roll methods can be used without limitation. For example, in the pattern forming method according to the present disclosure, performing at least a step of unwinding the substrate and at least a step of winding the substrate before and after at least one step makes it possible to process the substrate while transporting the substrate.

### Other Steps

The pattern forming method according to the present disclosure may include steps other than the above steps. Examples of the steps other than the above steps include the following steps.

### Step of Reducing Visible Light Reflectivity

In a case where the substrate has a conductive layer, the pattern forming method according to the present disclosure may include a step of performing a treatment for reducing a visible light reflectivity of a part or entirety of the conductive layer.

Examples of the treatment for reducing the visible light reflectivity include an oxidation treatment. For example, in a case where the conductive layer contains copper, by converting the copper into copper oxide through the oxidation treatment, it is possible to reduce the visible light reflectivity of the conductive layer.

Preferred aspects of the treatment for reducing visible light reflectivity are described in paragraphs “0017” to “0025” of JP2014-150118A and paragraphs “0041”, “0042”, “0048”, and “0058” of JP2013-206315A, the contents of which are incorporated into the present specification by reference.

### Manufacturing Method of Circuit Board

The manufacturing method of a circuit board according to the present disclosure includes the pattern forming method according to the present disclosure. Comprising the above configuration, the manufacturing method of a circuit board according to the present disclosure can use the pattern forming method that can suppress the occurrence of exposure fogging and can form a resin pattern having excellent resolution. For example, using the resin pattern as an etching mask makes it possible to form a high-precision pattern. Furthermore, for example, the resin pattern can be used as a protective film for the conductive layer.

The pattern forming method used in the manufacturing method of a circuit board according to the present disclosure is as described above in the section of “Pattern forming method”, and preferred embodiments are also the same as described above.

Examples of the circuit board include a printed wiring board and a touch panel sensor.

### Laminate

The laminate according to the present disclosure includes a first photosensitive layer, a substrate, and a second photosensitive layer in this order, and comprises the following characteristics A and B.

Characteristic A: in a case where λₘ₁ represents a maximum sensitivity wavelength of the first photosensitive layer and λₘ₂ represents a maximum sensitivity wavelength of the second photosensitive layer, λₘ₁ and λₘ₂ satisfy a relation of λₘ₁ ≠ λₘ₂. The maximum sensitivity wavelength refers to a wavelength at which a minimum exposure amount is the smallest in a case where the minimum exposure amount at which the photosensitive layers react is determined as a spectral sensitivity for each wavelength of light.

Characteristic B: the substrate has a transmittance of at least 50% or more for light having the wavelengths λₘ₁ and λₘ₂.

The maximum sensitivity wavelength can be determined as follows, for example. In a case where the photosensitive layer is irradiated with light having a specific wavelength through a STOUFFER 4105 step wedge tablet, the minimum exposure amount at which the photosensitive material reacts is defined as Emin. Changing the irradiation wavelength makes it possible to obtain a spectral sensitivity curve. Because Emin varies with wavelengths, the wavelength at which Emin is minimized is the maximum sensitivity wavelength.

In a negative tone photosensitive layer, the minimum exposure amount at which the exposed portion remains can be adopted as Emin. On the other hand, in a positive tone photosensitive layer, the minimum exposure amount at which the exposed portion is removed can be adopted as Emin.

In a case where the light from the light source has a discrete light quantity distribution (just as g-line, h-line, and i-line) like a high-pressure mercury lamp, or in a case where the wavelength of the irradiation light is controlled using a filter or the like, among the wavelengths of light actually heating the photosensitive material, the wavelength that brings the highest sensitivity is adopted as the maximum sensitivity wavelength. For example, assume that a certain photosensitive material has a spectral sensitivity curve in which the lowest spectral sensitivity is found at 290 nm and the second lowest sensitivity is found at 365 nm (i-line). Because a high-pressure mercury lamp substantially does not emit light of 290 nm, in a case where the photosensitive material is exposed to the high-pressure mercury lamp, the maximum sensitivity wavelength is 365 nm.

Adopting the above aspect, the laminate according to the present disclosure can suppress the occurrence of exposure fogging and makes it possible to form a resin pattern having excellent resolution.

The reason why the laminate according to the present disclosure has the above effects is presumed as follows. As described above, for example, in a case where an ultraviolet absorbing material is used to increase the optical density of a photosensitive layer such that the occurrence of exposure fogging is suppressed, the resolution of the obtained resin pattern is likely to deteriorate. On the other hand, the pattern forming method according to the present disclosure includes the preparation step, the exposure step (1), the exposure step (2), and the developing step (1), and the maximum sensitivity wavelength λₘ₁ of the first photosensitive layer is different from the maximum sensitivity wavelength λₘ₂ of the second photosensitive layer. Therefore, even though the substrate has a transmittance of at least 50% or more for the light of the wavelengths λₘ₁ and λₘ₂, the first photosensitive layer and the second photosensitive layer can be exposed selectively or exposed by priority. Accordingly, the laminate according to the present disclosure can suppress the occurrence of exposure fogging and can form a resin pattern having excellent resolution.

Preferred aspects of each of the first photosensitive layer, substrate, and second photosensitive layer in the laminate are the same as the preferred aspects of the first photosensitive layer, substrate, and second photosensitive layer in the pattern forming method, except for what will be described later.

Furthermore, except for what will be described later, preferred aspects of each of the wavelengths λₘ₁ and λₘ₂ in the laminate are the same as the preferred aspects of the dominant wavelength λ₁ and λ₂ in the pattern forming method except that the dominant wavelength λ₁ and λ₂ are replaced with the wavelengths λₘ₁ and λₘ₂.

From the viewpoint of suppressing exposure fogging, the dominant wavelength λₘ₁ is preferably in a range of more than 395 nm and 500 nm or less, and more preferably in a range of 396 nm or more and 456 nm or less.

From the viewpoint of suppressing exposure fogging, the dominant wavelength λₘ₂ is preferably in a range of 250 nm or more and 395 nm or less, and more preferably in a range of 335 nm or more and 395 nm or less.

Furthermore, from the viewpoint of suppressing exposure fogging, the dominant wavelength λₘ₁ is even more preferably in a range of more than 395 nm and 500 nm or less and the dominant wavelength λₘ₂ is even more preferably in a range of 250 nm or more and 395 nm or less, and the dominant wavelength λₘ₁ is particularly preferably in a range of more than 396 nm and 456 nm or less and the dominant wavelength λₘ₂ is particularly preferably in a range of 335 nm or more and 395 nm or less.

From the viewpoint of exposure fogging suppression and resolution, it is preferable that the first photosensitive layer contain a substance absorbing light having the wavelength λₘ₂.

From the viewpoint of exposure fogging suppression and resolution, the transmittance of the first photosensitive layer for light having the wavelength λₘ₂ is preferably 70% or less, more preferably 50% or less, even more preferably 20% or less, particularly preferably 10% or less, and most preferably 5% or less. The lower limit of the transmittance is 0%.

From the viewpoint of exposure fogging suppression and resolution, it is preferable that the second photosensitive layer contain a substance absorbing light having the wavelength λm1.

Furthermore, from the viewpoint of exposure fogging suppression and resolution, the transmittance of the second photosensitive layer for light having the wavelength λₘ₁ is preferably 70% or less, more preferably 50% or less, even more preferably 20% or less, particularly preferably 10% or less, and most preferably 5% or less. The lower limit of the transmittance is 0%.

The substance absorbing light having the wavelength λₘ₂ is the same as the substance absorbing light having the dominant wavelength λ₂ described above, and preferred aspects are also the same for the substances. The substance absorbing light having the wavelength λₘ₁ is the same as the substance absorbing light having the dominant wavelength λ₁ described above, and preferred aspects are also the same for the substances.

From the viewpoint of exposure fogging suppression and resolution, it is preferable that the first photosensitive layer and the second photosensitive layer satisfy the following relations C and D.

$$3 \leq \left({\text{S}}_{\text{m12}} / {\text{S}}_{\text{m11}}\right) \qquad \text{Relation C:}$$

$$\text{3} \leq \left({\text{S}}_{\text{m21}} / {\text{S}}_{\text{m22}}\right) \qquad \text{Relation D:}$$

Sₘ₁₂ represents a spectral sensitivity of the first photosensitive layer to the wavelength λₘ₂, Sₘ₁₁ represents a spectral sensitivity of the first photosensitive layer to the wavelength λₘ₁, Sₘ₂₁ represents a spectral sensitivity of the second photosensitive layer to the wavelength λₘ₁, and Sₘ₂₂ represents a spectral sensitivity of the second photosensitive layer to the wavelength λₘ₂.

The value of each of Sₘ₁₂/Sₘ₁₁ and Sₘ₂₁/Sₘ₂₂ is preferably 3 or more, more preferably 4 or more, and particularly preferably 5 or more. The upper limit of the values of Sₘ₁₂/Sₘ₁₁ and Sₘ₂₁/Sₘ₂₂ is not particularly limited, and can be set to arbitrary values as long as the photosensitive layer has proper performance. The photosensitive layer having such performance can be obtained by means of adjusting the light absorption coefficient of the photosensitive layer for each of the wavelengths λₘ₁ and λₘ₂.

### EXAMPLES

Hereinafter, the present disclosure will be specifically described with reference to examples. Unless otherwise specified, “part” and “%” are based on mass.

### Term

The following abbreviations represent the following compounds, respectively.
“MAA”: methacrylic acid (manufactured by Tokyo Chemical Industry Co., Ltd.)
“MMA”: methyl methacrylate (manufactured by Tokyo Chemical Industry Co., Ltd.)
“PGMEA”: propylene glycol monomethyl ether acetate (manufactured by SHOWA DENKO K.K.)
“St”: styrene (manufactured by FUJIFILM Wako Pure Chemical Corporation)
“V-601”: dimethyl 2,2′-azobis(2-methylpropionate) (manufactured by FUJIFILM Wako Pure Chemical Corporation)

### Synthesis of Polymer B-1

Propylene glycol monomethyl ether acetate (PGMEA, SHOWA DENKO K.K., 116.5 parts by mass) was put in a three-neck flask and heated to 90° C. in a nitrogen atmosphere. A solution containing St (52.0 parts by mass), MMA (19.0 parts by mass), MAA (29.0 parts by mass), V-601 (4.0 parts by mass), and PGMEA (116.5 parts by mass) was added dropwise for 2 hours to the three-neck flask kept at 90° C. ± 2° C. After the dropwise addition finished, the solution was stirred at 90° C. ± 2° C. for 2 hours, thereby obtaining polymer B-1 (concentration of solid contents: 30% by mass, molecular weight: 70,000, glass transition temperature: 131° C., acid value: 189 mg KOH/g).

### Examples 1 to 12 and Comparative Example 1

A resin pattern was formed on both surfaces of the substrate by the following method.

### Preparation of Transfer Material

By using a slit-like nozzle, a temporary support (polyethylene terephthalate film, thickness: 16 µm, haze: 0.12%) was coated with the composition for forming a photosensitive layer having the makeup described in Table 1. The composition for forming a photosensitive layer on the temporary support was dried in a convection oven at 100° C. for 2 minutes, thereby forming a photosensitive layer. A protective film (polypropylene film, thickness: 12 µm, haze: 0.2%) was bonded to the photosensitive layer, thereby preparing a transfer material. The unit of the amount (added amount) of each component described in Table 1 is parts by mass.

### Preparation of Laminate

The transfer material selected according to the description in Table 2 was cut in 50 cm x 50 cm, and the protective film was peeled off from the transfer material. Then, under lamination conditions of a roll temperature of 90° C., a linear pressure of 0.8 MPa, and a linear speed of 3.0 m/min, the transfer material was bonded to both surfaces of a substrate (polyethylene terephthalate film, thickness: 40 µm). Specifically, a transfer material for forming the first photosensitive layer was bonded to one surface of the substrate, and a transfer material for forming the second photosensitive layer was bonded to the other surface of the substrate. Through the above procedure, a laminate was prepared.

### Pattern Formation

A glass mask (Duty ratio 1:1) having a line-and-space pattern with a line width of 3 µm to 40 µm was closely attached to both surfaces of the laminate, without peeling off the temporary support. The glass mask was disposed on both surfaces of the laminate, such that the line patterns of the glass mask were perpendicular to each other in a case where the laminate is seen in a plane view. Thereafter, the first photosensitive layer and the second photosensitive layer were exposed simultaneously. In a case where the first photosensitive layer and the second photosensitive layer are exposed simultaneously, the first photosensitive layer was exposed from a side of the substrate on which the first photosensitive layer is disposed, and the second photosensitive layer is exposed from a side of the substrate on which the second photosensitive layer is disposed.

The exposure conditions for each layer were determined as follows.

First photosensitive layer: the exposure amount was set such that the width of residual patterns fell into a range of 49.0 µm to 51.0 µm in a pattern portion of line 50 µm/space 50 µm in a case where the first photosensitive layer is exposed through the aforementioned glass mask under the exposure conditions not including 365 nm, left to stand for 1 hour after exposure, and developed.

Second photosensitive layer: the exposure amount was set such that the width of residual patterns fell into a range of 49.0 µm to 51.0 µm in a pattern portion of line 50 µm/space 50 µm in a case where the second photosensitive layer is exposed through the aforementioned glass mask under the exposure conditions not including 405 nm, left to stand for 1 hour after exposure, and developed.

The meanings of “exposure conditions not including 365 nm” and “exposure conditions not including 405 nm” described above are as follows.

“Exposure conditions not including 365 nm”: the photosensitive layer was exposed through a short wavelength cut filter (model number: LUO400, cutoff wavelength: 400 nm, manufactured by Asahi Spectra Co., Ltd.) by using an ultra-high-pressure mercury lamp (USH-2004MB, manufactured by Ushio Inc.). The dominant wavelength is 405 nm. In a case where the intensity of the dominant wavelength is 100%, the intensity at the wavelength of 365 nm is 0.5% or less.

“Exposure conditions not including 405 nm”: the photosensitive layer was exposed through a bandpass filter for mercury exposure (model number: HB0365, central wavelength: 365 nm, manufactured by Asahi Spectra Co., Ltd.) by using an ultra-high-pressure mercury lamp (USH-2004MB, manufactured by Ushio Inc.). The dominant wavelength is 365 nm. In a case where the intensity of the dominant wavelength is 100%, the intensity at a wavelength of 405 nm is 0.5% or less.

In addition, in the case of exposure conditions not including 365 nm, the exposure amount was measured through the aforementioned LUO400 cut filter by mounting an optical receiver for 405 nm (UVD-C405, manufactured by Ushio Inc.) on an illuminance meter (UIT-250, manufactured by Ushio Inc.). In the case of exposure conditions not including 405 nm, the exposure amount was measured through the aforementioned band pass filter (HB0365) by mounting an optical receiver for 365 nm (UVD-C365, manufactured by Ushio Inc.) on an illuminance meter.

After the exposed photosensitive layer was left to stand for 1 hour, the temporary support was peeled off, and then a resin pattern was formed by development. By using a 1.0% aqueous potassium carbonate solution (developer) at 28° C., the photosensitive layer was developed for 30 seconds by shower development. The first photosensitive layer and the second photosensitive layer were developed simultaneously.

### Evaluation

By using the substrates with a resin pattern prepared in Examples 1 to 12 and Comparative Example 1, resolution and exposure fogging were evaluated. Table 2 shows the evaluation results.

### Resolution

The line width of a pattern having the highest resolution among the resin patterns was defined as the final resolution. Based on the final resolution, the resolution was evaluated according to the following standards. In a case where the side wall portion of the pattern is significantly disrupted or in a case where trailing markedly occurs and makes the pattern connected to the adjacent pattern, it was decided that the pattern fails to be resolved.

### Standards

A: 20 µm or less

B: more than 20 µm and 30 µm or less

C: more than 30 µm, or the pattern fails to be resolved.

### Exposure Fogging

Within the surface of substrate with a resin pattern, an unexposed portion (only the portion where the substrate surface opposite to the unexposed portion is an exposed portion, the same shall be applied hereinafter in this paragraph) was observed, and exposure fogging was evaluated according to the following standards. In a case where exposure fogging occurs, residues derived from the photosensitive layer are observed in the unexposed portion.

### Standards

A: in a case where the unexposed portion is observed with an optical microscope at 50X magnification, residues are not found on any of the side of the substrate on which the first photosensitive layer is disposed and the side of the substrate on which the second photosensitive layer is disposed.

B: in a case where the unexposed portion is observed with an optical microscope at 50X magnification, residues are found on at least any of the side of the substrate on which the first photosensitive layer is disposed or the side of the substrate on which the second photosensitive layer is disposed.

### Measurement of Sensitivity

[E₁ᵣ/E₂ and E₂ᵣ/E_{1]}

The laminate prepared according to the method described in [Preparation of laminate] described above was exposed only from the second photosensitive layer side, then the first photosensitive layer was developed, and an exposure amount at which residues were generated in this process was defined as E₁ᵣ. From the obtained E₁ᵣ and the exposure amount of the second photosensitive layer E₂ shown in Table 2, E₁ᵣ/E₂ was determined. For the second photosensitive layer, E₂ᵣ/E₁ was determined in the same manner. The measurement results are shown in Table 2.

### S₁₂/S₁₁ and S₂₁/S₂₂

The laminate prepared according to the method described in [Preparation of laminate] described above was exposed through a 15-stage step tablet (manufactured by FUJIFILM Corporation) under the following conditions to determine the spectral sensitivity.

S₁₁: the minimum exposure amount at which a residual film is formed after a process of exposing the first photosensitive layer under the exposure condition not including 365 nm and then performing development.

S₁₂: the minimum exposure amount at which a residual film is formed after a process of exposing the first photosensitive layer under the exposure condition not including 405 nm and then performing development.

S2₁: the minimum exposure amount at which a residual film is formed after a process of exposing the second photosensitive layer under the exposure condition not including 365 nm and then performing development.

S₂₂: the minimum exposure amount at which a residual film is formed after a process of exposing the second photosensitive layer under the exposure condition not including 405 nm and then performing development.

From the obtained values, S₁₂/S₁₁ and S₂₁/S₂₂ were determined. The measurement results are shown in Table 2.

### Example 13

### Preparation of Thermoplastic Resin Composition 1

A thermoplastic resin composition 1 was prepared by mixing the following components together.
Propylene glycol monomethyl ether acetate solution of copolymer of benzyl methacrylate, methacrylic acid, and acrylic acid (concentration of solid contents: 30.0% by mass, Mw: 30,000, acid value: 153 mgKOH/g): 42.85 parts by mass
NK ESTER A-DCP (manufactured by SHIN-NAKAMURA CHEMICAL CO, LTD.): 5.03 parts by mass
8UX-015A (manufactured by TAISEI FINE CHEMICAL CO., LTD.): 2.31 parts by mass
ARONIX TO-2349 (manufactured by TOAGOSEI CO., LTD.): 0.77 parts by mass
MEGAFACE F-552 (manufactured by DIC Corporation): 0.03 parts by mass
Methyl ethyl ketone (manufactured by SANKYO CHEMICAL CO., LTD.): 39.50 parts by mass
Propylene glycol monomethyl ether acetate (manufactured by SHOWA DENKO K.K.): 9.51 parts by mass

### Preparation of Thermoplastic Resin Composition 2

A thermoplastic resin composition 2 was prepared by mixing the following components together.
Propylene glycol monomethyl ether acetate solution of copolymer of benzyl methacrylate, methacrylic acid, and acrylic acid (concentration of solid contents: 30.0% by mass, Mw: 30,000, acid value: 153 mgKOH/g): 42.85 parts by mass
NK ESTER A-DCP (manufactured by SHIN-NAKAMURA CHEMICAL CO, LTD.): 4.33 parts by mass
8UX-015A (manufactured by TAISEI FINE CHEMICAL CO., LTD.): 2.31 parts by mass
ARONIX TO-2349 (manufactured by TOAGOSEI CO., LTD.): 0.77 parts by mass
MEGAFACE F-552 (manufactured by DIC Corporation): 0.03 parts by mass
Methyl ethyl ketone (manufactured by SANKYO CHEMICAL CO., LTD.): 39.50 parts by mass
Propylene glycol monomethyl ether acetate (manufactured by SHOWA DENKO K.K.): 9.51 parts by mass
Compound having the following structure (photoacid generator, compound synthesized according to the method described in paragraph “0227” of JP2013-47765A): 0.32 parts by mass

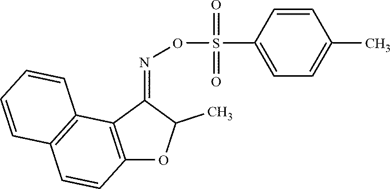 [SMILES: Cc1ccc(S(=O)(=O)O/N=C2/c3c(ccc4ccccc34)OC2C)cc1]

Compound having the following structure (colorant developing color by acid): 0.08 parts by mass

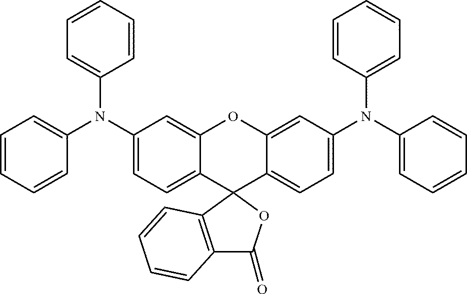 [SMILES: O=C1OC2(c3ccc(N(c4ccccc4)c4ccccc4)cc3Oc3cc(N(c4ccccc4)c4ccccc4)ccc32)c2ccccc21]

Solvent Yellow 56 (manufactured by Tokyo Chemical Industry Co., Ltd.): 0.3 parts by mass

### Preparation of Interlayer Composition

An interlayer composition was prepared by mixing the following components together.
KURARAY POVAL PVA-205 (manufactured by KURARAY CO., LTD.): 3.22 parts by mass
Polyvinylpyrrolidone K-30 (manufactured by NIPPON SHOKUBAI CO., LTD.): 1.49 parts by mass
MEGAFACE F-444 (manufactured by DIC Corporation): 0.0015 parts by mass
Deionized water: 38.12 parts by mass
Methanol (manufactured by MITSUBISHI GAS CHEMICAL COMPANY, INC.): 57.17 parts by mass

### Preparation of Transfer Material 6A

By using a slit-like nozzle, a temporary support (polyethylene terephthalate film, thickness: 16 µm, haze: 0.12%) was coated with the thermoplastic resin composition 1, such that the coating width was 1.0 m and the layer thickness was 3.0 µm after drying. The formed coating film of the thermoplastic resin composition was dried at 80° C. for 40 seconds, thereby forming a thermoplastic resin layer. By using a slit-like nozzle, the formed thermoplastic resin layer was coated with the interlayer composition, such that the coating width was 1.0 m and the layer thickness was 1.2 µm after drying. The coating film of the interlayer composition was dried at 80° C. for 40 seconds, thereby forming an interlayer. By using a slit-like nozzle, the formed interlayer was coated with a composition 4A for forming a photosensitive layer described in Table 1, such that the coating width was 1.0 m and the layer thickness was 3.0 µm after drying, followed by drying for 2 minutes in a convection oven at 100° C., thereby forming a photosensitive layer. A protective film (polypropylene film, thickness: 12 µm, haze: 0.2%) was bonded to the photosensitive layer, thereby preparing a transfer material 6A.

### Preparation of Transfer Material 4B

By using a slit-like nozzle, a temporary support (polyethylene terephthalate film, thickness: 16 µm, haze: 0.12%) was coated with a thermoplastic resin composition 2, such that the coating width was 1.0 m and the layer thickness was 3.0 µm after drying. The formed coating film of the thermoplastic resin composition was dried at 80° C. for 40 seconds, thereby forming a thermoplastic resin layer. By using a slit-like nozzle, the formed thermoplastic resin layer was coated with the interlayer composition, such that the coating width was 1.0 m and the layer thickness was 1.2 µm after drying. The coating film of the interlayer composition was dried at 80° C. for 40 seconds, thereby forming an interlayer. By using a slit-like nozzle, the formed interlayer was coated with a composition 3B for forming a photosensitive layer described in Table 1, such that the coating width was 1.0 m and the layer thickness was 3.0 µm after drying, followed by drying for 2 minutes in a convection oven at 100° C., thereby forming a photosensitive layer. A protective film (polypropylene film, thickness: 12 µm, haze: 0.2%) was bonded to the photosensitive layer, thereby preparing a transfer material 4B.

### Preparation of Laminate, Pattern Formation, and Evaluation

By using the transfer material 6A and the transfer material 4B, a substrate with a resin pattern was prepared according to the method described in the section of “Preparation of laminate” and the section of “Pattern formation” described above. By using the obtained substrate with a resin pattern, the resolution and exposure fogging described above in the section of “Evaluation” were evaluated. Table 2 shows the evaluation results.

### Measurement of Sensitivity

Sensitivity was measured according to the method described above in the section of “Measurement of sensitivity”. The measurement results are shown in Table 2.

TABLE 1

| Transfer material | | 1A | 2A | 3A | 4A | 5A | 1B | 2B | 3B |
|---|---|---|---|---|---|---|---|---|---|
| Thickness | | 3 µm | 3 µm | 3 µm | 3 µm | 3 µm | 3 µm | 3 µm | 3 µm |
| Composition for forming photosensitive layer | | 1A | 2A | 3A | 4A | 5A | 1B | 2B | 3B |
| Polymer | B-1 30% solution | 24.7 | 24.7 | 24.7 | 24.7 | - | 23.84 | 23.59 | 22.77 |
| | Copolymer of benzyl methacrylate and methacrylic acid (Monomer ratio: 80/20) | - | - | - | - | 20.26 | - | - | - |
| Photoradical generator (Photopolymerization initiator) | B-CIM | 0.25 | 0.25 | - | 0.25 | - | - | - | 0.8 |
| | 379EG | - | - | - | - | - | 0.45 | - | - |
| | OXE-01 | - | - | - | - | 0.32 | - | - | - |
| | OXE-02 | - | - | - | - | - | - | 0.4 | - |
| | 907 | - | - | 0.25 | - | - | - | - | - |
| Sensitizer | Sensitizer A | 0.04 | - | - | - | - | - | - | - |
| | Sensitizer B | - | - | - | 0.15 | - | - | - | - |
| | Sensitizer C | - | - | - | - | - | - | - | 0.07 |
| | Sensitizer D | - | 0.04 | - | - | - | - | - | - |
| | Sensitizer E | - | - | 0.04 | - | - | - | - | - |
| Chain transfer agent | Chain transfer agent A | 1.8 | 1.8 | 1.8 | 1.8 | - | 1.8 | 1.8 | 1.8 |
| Polymerizable compound | NK Ester BPE-500 | 4.9 | 4.9 | 4.9 | 4.9 | - | 4.9 | 4.9 | 4.9 |
| | ARONIX M250 | 0.5 | 0.5 | 0.5 | 0.5 | 5.64 | 0.5 | 0.5 | 0.5 |
| Polymerization inihibitor | 1-Phenyl-3-pyrazolidone 1% solution | 0.11 | 0.11 | 0.11 | 0.11 | - | 0.11 | 0.11 | 0.11 |
| | Phenothiazine 5% solution | 0.35 | 0.35 | 0.35 | 0.35 | - | 0.35 | 0.35 | 0.7 |
| Solvent | PGMEA | 26.1 | 26.1 | 26.1 | 26.1 | 31.3 | 26.1 | 26.1 | 26.1 |
| | MEK | 37.5 | 37.5 | 37.5 | 37.5 | 39.3 | 38.2 | 38.4 | 38.4 |
| | MeOH | 2 | 2 | 2 | 2 | - | 2 | 2 | 2 |
| UV absorber | UV absorber A | - | - | - | - | | 0.1 | 0.1 | 0.1 |
| Coloring material | LCV 3% solution | 1.7 | 1.7 | 1.7 | 1.7 | | 1.7 | 1.7 | 1.7 |
| Carbon black | Carbon black dispersion | - | - | - | - | 3.11 | - | - | - |
| Surfactant | MEGAFACE F552 | 0.05 | 0.05 | 0.05 | 0.05 | - | 0.05 | 0.05 | 0.05 |
| | MEGAFACE F551A | - | - | - | - | 0.118 | - | - | - |

Details of the components listed in Table 1 will be shown below.

### Polymer

“Copolymer of benzyl methacrylate and methacrylic acid”: concentration of solid contents 30%, PGMEA solution

### Photoradical Generator

“B-ClM″: 2-(2-chlorophenyl)-4,5-diphenylimidazole dimer (manufactured by Hampford Research Inc.)

“OXE-01”: IRGACURE OXE-01 (manufactured by BASF Japan Ltd.)

“OXE-02”: IRGACURE OXE-02 (manufactured by BASF Japan Ltd.)

“379EG”: Omnirad 379EG (manufactured by IGM Resins B.V)

“907”: Omnirad 907 (manufactured by IGM Resins B.V.)

### Sensitizer

“Sensitizer A”: compound represented by the following structural formula

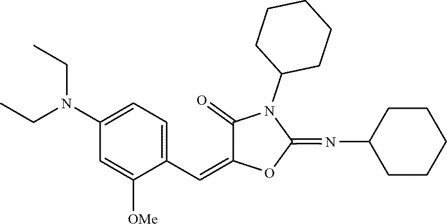 [SMILES: CCN(CC)c1ccc(/C=C2/OC(=NC3CCCCC3)N(C3CCCCC3)C2=O)c(OC)c1]

“Sensitizer B″: coumarin 7 (manufactured by Tokyo Chemical Industry Co., Ltd.)

“Sensitizer C″: 4,4′-bis(dimethylamino)benzophenone (manufactured by Tokyo Chemical Industry Co., Ltd.)

“Sensitizer D”: 10-butyl-2-chloroacridone (manufactured by KUROGANE KASEI Co., Ltd.)

“Sensitizer E”: KAYACURE DETX-S (trade name) (manufactured by Nippon Kayaku Co., Ltd.)

### Chain Transfer Agent

“Chain transfer agent A″: N-phenylcarbamoylmethyl-N-carboxymethylaniline (manufactured by FUJIFILM Wako Pure Chemical Corporation)

### Polymerizable Compound

“ARONIX M250”: trade name (manufactured by TOAGOSEI CO., LTD.)

“NK ESTER BPE-500”: trade name (manufactured by SHIN-NAKAMURA CHEMICAL CO, LTD.)

### Polymerization Inhibitor

“1-Phenyl-3-pyrazolidone”: manufactured by FUJIFILM Wako Pure Chemical Corporation

“Phenothiazine”: manufactured by FUJIFILM Wako Pure Chemical Corporation

### Solvent

“MEK”: methyl ethyl ketone (manufactured by SANKYO CHEMICAL CO., LTD.)

“MeOH”: Methanol (manufactured by Mitsui Chemicals, Inc.)

### Coloring Material

“LCV”: leuco Crystal Violet (colorant, manufactured by YAMADA CHEMICAL CO., LTD.)

### UV Absorber

“UV absorber A”: diethylamino-phenylsulfonyl-based ultraviolet absorber (manufactured by DAITO KAGAKU KOGYO K.K.)

### Carbon Black

“Carbon black dispersion liquid”: Concentration of solid contents 38% (manufactured by TOKYO PRINTING INK MFG. CO., LTD.)

### Surfactant

“MEGAFACE F552”: trade name (manufactured by DIC Corporation)

“MEGAFACE F551A”: trade name (manufactured by DIC Corporation)

TABLE 2

| | First photosensitive layer | | | Second photosensitive layer | | | Exposure conditions | | | | E₁/E₂ | E₂/E₁; | S₁₂/S₁₁ | S₂₂/S₁₂ | Resolution | Exposure fogging |
|---|---|---|---|---|---|---|---|---|---|---|---|---|---|---|---|---|
| | | | | | | | First photosensitive layer | | Second photosensitive layer | | | | | | | |
| | Type of transfer material | Type of composition | Thickness [µm] | Type of transfer material material | Type of composition | Thickness [µm] | Exposure waveleng | Exposure amount [mJ/cm²] | Exposure waveleng | Exposure amount [mJ/cm²] | | | | | | |
| Example 1 | 1A | 1A | 3 | 1B | 1B | 3 | Not including 365 mm | 120 | Not including 405 mm | 150 | 1.10 | 1.52 | 4.0 | 4.2 | A | A |
| Example 2 | 1A | 1A | 3 | 2B | 2B | 3 | Not including 365 mm | 120 | Not including 405 mm | 60 | 1.31 | 1.55 | 4.0 | 8.2 | A | A |
| Example 3 | 1A | 1A | 3 | 3B | 3B | 3 | Not including 365 mm | 120 | Not including 405 mm | 120 | 1.23 | 1.24 | 4.0 | 4.0 | A | A |
| Example 4 | 2A | 2A | 3 | 1B | 1B | 3 | Not including 365 mm | 110 | Not including 405 mm | 150 | 1.12 | 1.64 | 3.5 | 4.2 | A | A |
| Exampie 5 | 2A | 2A | 3 | 2B | 2B | 3 | Not including 365 mm | 110 | Not including 405 mm | 60 | 1.27 | 1.61 | 3.5 | 8.2 | A | A |
| Example 6 | 2A | 2A | 3 | 3B | 3B | 3 | Not including 365 mm | 110 | Not including 405 mm | 120 | 1.10 | 1.33 | 3.5 | 4.0 | A | A |
| Example 7 | 3A | 3A | 3 | 1B | 1B | 3 | Not including 365 mm | 140 | Not including 405 mm | 150 | 1.10 | 1.48 | 3.0 | 4.2 | B | A |
| Example 8 | 3A | 3A | 3 | 2B | 2B | 3 | Not including 365 mm | 140 | Not including 405 mm | 60 | 1.18 | 1.48 | 3.0 | 8.2 | B | A |
| Example 9 | 3A | 3A | 3 | 3B | 3B | 3 | Not including 365 mm | 140 | Not including 405 mm | 120 | 1.13 | 1.20 | 3.0 | 4.0 | B | A |
| Example 10 | 4A | 4A | 3 | 1B | 1B | 3 | Not including 365 mm | 110 | Not including 405 mm | 150 | 1.11 | 1.60 | 5.8 | 4.2 | A | A |
| Example 11 | 4A | 4A | 3 | 2B | 2B | 3 | Not including 365 mm. | 110 | Not including 405 mm | 60 | 1.42 | 1.62 | 5.8 | 8.2 | A | A |
| Example 12 | 4A | 4A | 3 | 3B | 3B | 3 | Not including 365 mm | 110 | Not including 405 mm | 120 | 1.31 | 1.34 | 5.8 | 4.0 | A | A |
| Example 13 | 6A | 4A | 5 | 4B | 3B | 5 | Not including 365 mm | 110 | Not including 405 mm | 120 | 1.32 | 1.34 | 5.9 | 4.1 | A | A |
| Comparative Example 1 | 5A | 5A | 3 | 5A | 5A | 3 | – | 100 | – | 100 | 1.00 | 1.67 | 0.3 | 2.9 | C | B |

The laminates of Examples 1 to 13 satisfied the characteristics A and B.

In Table 2, the following terms and symbols described in the column of “Exposure conditions” have the following meanings.

“Not including 365 nm”: the photosensitive layer was exposed through a short wavelength cut filter (model number: LUO400, cutoff wavelength: 400 nm, manufactured by Asahi Spectra Co., Ltd.) by using an ultra-high-pressure mercury lamp (USH-2004MB, manufactured by Ushio Inc.). The dominant wavelength is 405 nm. In a case where the intensity of the dominant wavelength is 100%, the intensity at the wavelength of 365 nm is 0.5% or less.

“Not including 405 nm”: the photosensitive layer was exposed through a bandpass filter for mercury exposure (model number: HB0365, central wavelength: 365 nm, manufactured by Asahi Spectra Co., Ltd.) by using an ultra-high-pressure mercury lamp (USH-2004MB, manufactured by Ushio Inc.). The dominant wavelength is 365 nm. In a case where the intensity of the dominant wavelength is 100%, the intensity at a wavelength of 405 nm is 0.5% or less.

“-”: Exposure was performed using an ultra-high-pressure mercury lamp (USH-2004MB, manufactured by Ushio Inc.) without using a wavelength selective filter.

In Examples 1 to 13, the dominant wavelength of the exposure wavelength in the step of exposing the first photosensitive layer is different from the dominant wavelength of the exposure wavelength in the step of exposing the second photosensitive layer. On the other hand, in Comparative Example 1, the dominant wavelength of the exposure wavelength for exposing the first photosensitive layer is the same as the dominant wavelength of the exposure wavelength for exposing the second photosensitive layer. Furthermore, in Comparative Example 1, the first photosensitive layer and the second photosensitive layer each contain carbon black as an ultraviolet absorbing material.

As is evident from Table 2, in Examples 1 to 13, the occurrence of exposure fogging can be further suppressed, and a resin pattern having higher resolution can be formed, compared to Comparative Example 1.

### Examples 14 to 27

### Abbreviation

The following abbreviations represent the following compounds, respectively.
“A-1”: propylene glycol monomethyl ether acetate solution of copolymer of styrene/methacrylic acid/methyl methacrylate (concentration of solid contents: 30.0% by mass, ratio of monomers: 52% by mass/29% by mass/19% by mass, Mw: 70,000)
“A-2”: propylene glycol monomethyl ether acetate solution of copolymer of benzyl methacrylate/methacrylic acid (concentration of solid contents: 30.0% by mass, ratio of monomers: 80% by mass/20% by mass, Mw: 30,000, acid value: 153 mgKOH/g)
“A-3”: KURARAY POVAL PVA-205 (manufactured by KURARAY CO., LTD.)
“A-4”: polyvinylpyrrolidone K-30 (manufactured by NIPPON SHOKUBAI CO., LTD.)
“B-1”: BPE-500 (manufactured by SHIN-NAKAMURA CHEMICAL CO, LTD.)
“B-2”: M-270 (manufactured by TOAGOSEI CO., LTD.)
“B-3”: NK ESTER A-DCP (manufactured by SHIN-NAKAMURA CHEMICAL CO, LTD.)
“B-4”: 8UX-015A (manufactured by TAISEI FINE CHEMICAL CO., LTD.)
“B-5”: ARONIX TO-2349 (manufactured by TOAGOSEI CO., LTD.)
“B-6”: KAYARAD DPHA (manufactured by Nippon Kayaku Co., Ltd.)
“C-1”: B-CIM (manufactured by KUROGANE KASEI Co., Ltd.)
“C-2”: Omnirad 379EG (manufactured by IGM Resins B.V.)
“C-3”: Irgacure OXE-01 (manufactured by BASF Japan Ltd.)
“C-4”: sensitizer A
“C-5”: coumarin 7 (manufactured by Tokyo Chemical Industry Co., Ltd.)
“C-6”: 4,4′-bis(dimethylamino)benzophenone (manufactured by Tokyo Chemical Industry Co., Ltd.)
“C-7”: 10-butyl-2-chloroacridone (manufactured by KUROGANE KASEI Co., Ltd.)
“C-8”: Irgacure OXE-02 (manufactured by BASF Japan Ltd.)
“D-1”: TDP-G (manufactured by Kawaguchi Chemical Industry Co., LTD.)
“D-2”: 1-phenyl-3-pyrazolidone (manufactured by FUJIFILM Wako Pure Chemical Corporation)
“E-1”: leuco Crystal Violet (manufactured by Tokyo Chemical Industry Co., Ltd.)
“E-2”: N-phenylcarbamoylmethyl-N-carboxymethylaniline (manufactured by FUJIFILM Wako Pure Chemical Corporation)
“E-3”: Solvent Yellow 56 (manufactured by Tokyo Chemical Industry Co., Ltd., substance absorbing light of 405 nm)
“E-4”: diethylamino-phenylsulfonyl-based ultraviolet absorber (manufactured by DAITO KAGAKU KOGYO K.K., substance absorbing light of 365 nm)
“E-5”: CBT-1 (manufactured by JOHOKU CHEMICAL CO., LTD.)
“E-6”: F-552 (manufactured by DIC Corporation)
“E-7”: F-444 (manufactured by DIC Corporation)
“F-1”: methyl ethyl ketone (manufactured by SANKYO CHEMICAL CO., LTD.)
“F-2”: propylene glycol monomethyl ether acetate (manufactured by SHOWA DENKO K.K.)
“F-3”: deionized water
“F-4”: methanol (manufactured by MITSUBISHI GAS CHEMICAL COMPANY, INC.)

### Preparation of Thermoplastic Resin Composition

The compounds selected according to the description in Table 3 were mixed together, thereby preparing thermoplastic resin compositions 1a to 3a.

TABLE 3

| Thermoplastic resin composition | 1a | 2a | 3a |
|---|---|---|---|
| A-2 | 42.85 | 42.02 | 42.15 |
| B-3 | 5.03 | 5.03 | 5.03 |
| B-4 | 2.31 | 2.31 | 2.31 |
| B-5 | 0.77 | 0.77 | 0.77 |
| E-3 | - | 0.25 | - |
| E-4 | - | - | 0.10 |
| E-6 | 0.03 | 0.03 | 0.03 |
| F-1 | 39.50 | 40.08 | 40.10 |
| F-2 | 9.51 | 9.51 | 9.51 |

### Preparation of Interlayer Composition

The following compounds were mixed together, thereby preparing an interlayer composition 2.
A-3: 3.22 parts by mass
A-4: 1.49 parts by mass
E-7: 0.0015 parts by mass
F-3: 38.12 parts by mass
F-4: 57.17 parts by mass

### Preparation of Composition for Forming Photosensitive Layer

The compounds selected according to the description in Table 4 were mixed together, thereby preparing photosensitive resin compositions 6A to 10A and 4B to 8B.

TABLE 4

| | Composition for forming first photosensitive layer | | | | | Composition for forming second photosensitive layer | | | | |
|---|---|---|---|---|---|---|---|---|---|---|
| | 6A | 7A | 8A | 9A | 10A | 4B | 5B | 6B | 7B | 8B |
| A-1 | 21.83 | 21.33 | 21.33 | 21.33 | 21.33 | 22.77 | 22.37 | 22.37 | 18.60 | 24.57 |
| B-1 | 4.90 | 4.90 | 3.30 | 4.90 | 4.90 | 4.90 | 4.90 | 3.30 | 4.90 | 4.90 |
| B-2 | 0.50 | 0.50 | 0.50 | 0.50 | 0.50 | 0.50 | 0.50 | 0.50 | 0.50 | 0.50 |
| B-6 | - | - | 1.60 | - | - | - | - | 1.60 | - | - |
| C-1 | 1.00 | 1.00 | 1.00 | 1.00 | 1.00 | 0.80 | 0.80 | 0.80 | - | - |
| C-2 | - | - | - | - | - | - | - | - | 2.00 | - |
| C-3 | - | - | - | - | - | - | - | - | - | 0.21 |
| C-4 | - | - | - | 0.15 | - | - | - | - | - | - |
| C-5 | 0.15 | 0.15 | 0.15 | - | - | - | - | - | - | - |
| C-6 | - | - | - | - | - | 0.07 | 0.07 | 0.07 | - | - |
| C-7 | - | - | - | - | 0.15 | - | - | - | - | - |
| D-1 | 0.0175 | 0.0175 | 0.0175 | 0.0175 | 0.0175 | 0.04 | 0.04 | 0.04 | 0.04 | 0.04 |
| D-2 | 0.0011 | 0.0011 | 0.0011 | 0.0011 | 0.0011 | 0.0011 | 0.0011 | 0.0011 | 0.0011 | 0.0011 |
| E-1 | 0.051 | 0.051 | 0.051 | 0.051 | 0.051 | 0.05 | 0.05 | 0.05 | 0.05 | 0.05 |
| E-2 | 1.80 | 1.80 | 1.80 | 1.80 | 1.80 | 1.80 | 1.80 | 1.80 | 1.80 | 1.80 |
| E-3 | - | - | - | - | - | - | 0.12 | - | 0.12 | 0.12 |
| E-4 | - | 0.15 | - | 0.15 | 0.15 | 0.10 | 0.10 | 0.10 | 0.10 | 0.10 |
| E-5 | 0.12 | 0.12 | 0.12 | 0.12 | 0.12 | 0.12 | 0.12 | 0.12 | 0.12 | 0.12 |
| E-6 | 0.05 | 0.05 | 0.05 | 0.05 | 0.05 | 0.05 | 0.05 | 0.05 | 0.05 | 0.05 |
| F-1 | 41.48 | 41.83 | 41.83 | 41.83 | 41.83 | 40.70 | 40.98 | 40.98 | 43.62 | 39.44 |
| F-2 | 26.10 | 26.10 | 26.10 | 26.10 | 26.10 | 26.10 | 26.10 | 26.10 | 26.10 | 26.10 |
| F-4 | 2.00 | 2.00 | 2.00 | 2.00 | 2.00 | 2.00 | 2.00 | 2.00 | 2.00 | 2.00 |

### Preparation of Transfer Material

According to the description in Table 5, by using a slit-like nozzle, the surface of a temporary support (polyethylene terephthalate film, thickness: 16 µm, haze: 0.12%) was coated with the thermoplastic resin composition, such that the coating width was 1.0 m and the layer thickness was 3.0 µm after drying. The thermoplastic resin composition was dried at 80° C. for 40 seconds, thereby forming a thermoplastic resin layer.

By using a slit-like nozzle, the surface of the thermoplastic resin layer was coated with the interlayer composition 2, such that the coating width was 1.0 m and the layer thickness was 1.2 µm after drying. The interlayer composition 2 was dried at 80° C. for 40 seconds, thereby forming an interlayer.

According to the description in Table 5, by using a slit-like nozzle, the surface of the interlayer was coated with a photosensitive resin composition, such that the coating width was 1.0 m and the layer thickness was 3.0 µm after drying. The photosensitive resin composition was dried at 100° C. for 2 minutes, thereby forming a photosensitive layer.

A protective film (polypropylene film, thickness: 12 µm, haze: 0.2%) was disposed on the surface of the photosensitive layer.

Through the above procedure, a transfer material was prepared (see Table 5).

### Preparation of Laminate

The transfer material selected according to the description in Table 5 was cut in 50 cm x 50 cm, and the protective film was peeled off from the transfer material. Then, under lamination conditions of a roll temperature of 90° C., a linear pressure of 0.8 MPa, and a linear speed of 3.0 m/min, the transfer material was bonded to both surfaces of a substrate (polyethylene terephthalate film, thickness: 40 µm). Specifically, a transfer material for forming the first photosensitive layer (that is, a first transfer material) was bonded to one surface of the substrate, and a transfer material (that is, a second transfer material) for forming the second photosensitive layer was bonded to the other surface of the substrate. Through the above procedure, a laminate was prepared.

### Pattern Formation

According to the method described above in the section of “Pattern formation”, a substrate with a resin pattern was prepared.

### Evaluation

By using the substrates with a resin pattern, resolution and exposure fogging were evaluated. Table 5 shows the evaluation results.

### Resolution

The line width of a pattern having the highest resolution among the resin patterns was defined as the final resolution. Based on the final resolution, the resolution was evaluated according to the following standards. In a case where the side wall portion of the pattern is significantly disrupted or in a case where trailing markedly occurs and makes the pattern connected to the adjacent pattern, the resolution was graded E. In the evaluation, D is preferable, C is more preferable, B is more preferable, and A is particularly preferable.

### Standards

A: 10 µm or less

B: more than 10 µm and 18 µm or less

C: more than 18 µm and 20 µm or less

D: more than 20 µm and 30 µm or less

E: more than 30 µm, or the pattern fails to be resolved.

### Measurement of Sensitivity

Sensitivity was measured according to the method described above in the section of “Measurement of sensitivity”. The measurement results are shown in Table 5.

TABLE 5

| | First transfer material | | Second transfer material | | Exposure Condition | | | | Er² E₂ | Es²E₁ | S₁₅ S22 | S₂₃ S₁₂ | Exposure logging | Resolution on first photosensitive layer side | Resolution on second photosentive layer side |
|---|---|---|---|---|---|---|---|---|---|---|---|---|---|---|---|
| | | | | | First photosensitive layer | | Secend photosensitive layer | | | | | | | | |
| | Thermplastic resin compostion | Composition for forming first photosentive layer | Thermoplastic resin composition | Composition for forming secend photosentive layer | Exposure wavelengh | Exposure amount [ml/cm²] | Exposure amount | Exposure amount [ml/cm²] | | | | | | | |
| Example 14 | 3a | 6A | 2a | 4B | Not including 365 µm | 120 | Not including 405 µm | 60 | 1.30 | 1.34 | 5.8 | 4.1 | A | A | A |
| Example 15 | 2a | 8A | 2a | 6B | Not including 365 µm | 120 | Not including 405 µm | 60 | 1.30 | 1.38 | 5.9 | 4.0 | A | A | A |
| Example 16 | 1a | 7A | 1a | 5B | Not including 365 µm | 120 | Not including 405 µm | 60 | 1.29 | 1.30 | 5.7 | 4.1 | A | A | A |
| Example 17 | 1a | 7A | 1a | 7B | Not including 365 µm | 120 | Not including 405 µm | 180 | 1.16 | 1.48 | 5.7 | 4.2 | A | A | B |
| Example 18 | 1a | 7A | 1a | 8B | Not including 365 µm | 120 | Not including 405 µm | 70 | 1.27 | 1.45 | 3.7 | 7.6 | A | A | B |
| Example 19 | 1a | 9A | 1a | 5B | Not including 365 µm 1 | 10 | Not including 405 µm | 60 | 1.25 | 1.31 | 3. 4 | 4.1 | A | A | A |
| Example 20 | 1a | 9A | 1a | 7B | Not including 365 µm | 110 | Notincluding 405 µm | 180 | 1.11 | 1.49 | 5.4 | 4.2 | A | A | B |
| Example 21 | 1a | 9A | 1a | 8B | Not including 365 µm | 10 | Not including 405 µm | 70 | 1.23 | 1.47 | 5.4 | 7.6 | A | A | B |
| Example 22 | 1a | 10A | 1a | 5B | Not including 365 µm | 160 | Not including 405 µm | 60 | 1.20 | 1.25 | 3.5 | 4.1 | A | B | A |
| Example 23 | 1a | 10A | 1a | 7B | Not including 365 µm | 160 | Not including 405 µm | 180 | 1.10 | 1.40 | 3.5 | 4.2 | A | B | B |
| Example 24 | 1a | 10A | 1a | 8B | Not including 365 µm | 160 | Not including 405 µm | 70 | 1.19 | 1.40 | 3.5 | 7.6 | A | B | B |
| Example 25 | 1a | 6A | 1a | 4B | Not including 365 µm | 120 | Not including 405 µm | 60 | 1.31 | 1.34 | 5.8 | 4.0 | A | C | C |
| Example 26 | 3a | 6A | 1a | 4B | Not including 365 µm | 120 | Not including 405 µm | 60 | 1.30 | 1.34 | 5.8 | 4.1 | A | C | A |
| Example 27 | 1a | 6A | 2a | 4B | Not including 365 µm | 120 | Not including 405 µm 60 | 60 | 1.11 | 1.35 | 5.8 | 4.1 | A | A | C |

The laminates of Examples 14 to 27 satisfied the characteristics A and B.

As shown in Table 5, it has been confirmed that in Examples 14 to 27, the occurrence of exposure fogging can be suppressed, and a resin pattern having excellent resolution can be obtained.

### Example 28

### Preparation of Absorption Filter A

The following compounds were mixed together, thereby preparing a composition for an absorption filter A. The meanings of the following abbreviations are the same as the meanings of the above abbreviations.
A-2: 25.2 parts by mass
B-6: 5.2 parts by mass
C-8: 0.10 parts by mass
E-3: 0.13 parts by mass
F-1: 60.9 parts by mass
F-2: 8.4 parts by mass

A glass substrate (Eagle XG, manufactured by Corning Incorporated.) was spin-coated with the composition for an absorption filter A such that the film thickness was 3.6 µm after drying, followed by pre-baking at 80° C. for 120 seconds. Then, by using a high-pressure mercury lamp, the composition for an absorption filter A was exposed at 100 mJ, followed by post-baking at 140° C. for 30 minutes, thereby obtaining an absorption filter A.

### Preparation of Absorption Filter B

The following compounds were mixed together, thereby preparing a composition for an absorption filter B. The meanings of the following abbreviations are the same as the meanings of the above abbreviations.
A-2: 25.2 parts by mass
B-6: 5.2 parts by mass
C-8: 0.10 parts by mass
E-4: 0.13 parts by mass
F-1: 60.9 parts by mass
F-2: 8.4 parts by mass

A glass substrate (Eagle XG, manufactured by Corning Incorporated.) was spin-coated with the composition for an absorption filter B such that the film thickness was 3.0 µm after drying, followed by prebaking at 80° C. for 120 seconds. Then, by using a high-pressure mercury lamp, the composition for an absorption filter B was exposed at 100 mJ, followed by post-baking at 140° C. for 30 minutes, thereby obtaining an absorption filter B.

### Evaluation

A substrate with a resin pattern was prepared by the same procedure as in Example 25, except that in the pattern formation of Example 25 described above, the absorption filter B is disposed between the glass mask on the first photosensitive layer side and the short wavelength cut filter (LUO400), the absorption filter A was disposed between the glass mask on the second photosensitive layer side and the bandpass filter for mercury exposure (HB0365), and then the first photosensitive layer and the second photosensitive layer were exposed. By using the obtained substrate with a resin pattern, the same evaluation as in Example 25 was performed. Both the “resolution on the first transfer material side” and “resolution on the second transfer material side” were graded A. Presumably, the disposition of the absorption filter A absorbing the light for exposing the first photosensitive layer may inhibit the first photosensitive layer from being exposed again to the exposure light reflected by the bandpass filter for mercury exposure (HB0365) for mercury exposure, and the disposition of the absorption filter B absorbing the light for exposing the second photosensitive layer may inhibit the second photosensitive layer from being exposed again to the exposure light reflected by the short wavelength cut filter (LUO400), which may lead to the above results. The evaluation result of “exposure fogging” was A.

The laminate of Example 28 satisfied the characteristics A and B.

### Examples 29 to 50

### Abbreviation

The following abbreviations represent the following compounds, respectively.
“AA-1”: propylene glycol monomethyl ether acetate solution of copolymer of styrene/methacrylic acid/methyl methacrylate (concentration of solid contents: 30.0% by mass, ratio of monomers: 52% by mass/29% by mass/19% by mass, Mw: 70,000)
“AA-2”: propylene glycol monomethyl ether acetate solution of copolymer of benzyl methacrylate/methacrylic acid (concentration of solid contents: 30.0% by mass, ratio of monomers: 80% by mass/20% by mass, Mw: 30,000, acid value: 153 mgKOH/g)
“AA-3”: KURARAY POVAL PVA-205 (manufactured by KURARAY CO., LTD.)
“AA-4”: polyvinylpyrrolidone K-30 (manufactured by NIPPON SHOKUBAI CO., LTD.)
“AB-1”: BPE-500 (manufactured by SHIN-NAKAMURA CHEMICAL CO, LTD.)
“AB-2”: M-270 (manufactured by TOAGOSEI CO., LTD.)
“AB-3”: NK ESTER A-DCP (manufactured by SHIN-NAKAMURA CHEMICAL CO, LTD.)
“AB-4”: 8UX-015A (manufactured by TAISEI FINE CHEMICAL CO., LTD.)
“AB-5”: ARONIX TO-2349 (manufactured by TOAGOSEI CO., LTD.)
“AB-6”: KAYARAD DPHA (manufactured by Nippon Kayaku Co., Ltd.)
“AB-7”: NK ESTER 4G (manufactured by SHIN-NAKAMURA CHEMICAL CO, LTD.)
“AB-8”: NK ESTER A-GLY-3E (manufactured by SHIN-NAKAMURA CHEMICAL CO, LTD.)
“AC-1”: B-CIM (manufactured by KUROGANE KASEI Co., Ltd.)
“AC-2”: Omnirad 379EG (manufactured by IGM Resins B.V)
“AC-3”: Irgacure OXE-01 (manufactured by BASF Japan Ltd.)
“AC-4”: the sensitizer A
“AC-5”: coumarin 7 (manufactured by Tokyo Chemical Industry Co., Ltd.)
“AC-6”: 4,4′-bis(dimethylamino)benzophenone (manufactured by Tokyo Chemical Industry Co., Ltd.)
“AC-7”: 10-butyl-2-chloroacridone (manufactured by KUROGANE KASEI Co., Ltd.)
“AD-1”: TDP-G (manufactured by Kawaguchi Chemical Industry Co., LTD.)
“AD-2”: 1-phenyl-3-pyrazolidone (manufactured by FUJIFILM Wako Pure Chemical Corporation)
“AE-1”: leuco Crystal Violet (manufactured by Tokyo Chemical Industry Co., Ltd.)
“AE-2”: N-phenylcarbamoylmethyl-N-carboxymethylaniline (manufactured by FUJIFILM Wako Pure Chemical Corporation)
“AE-3”: Solvent Yellow 56 (manufactured by Tokyo Chemical Industry Co., Ltd., substance absorbing light of 405 nm)
“AE-4”: Solvent Yellow 4 (manufactured by Tokyo Chemical Industry Co., Ltd., substance absorbing light of 405 nm)
“AE-5”: Solvent Green 3 (manufactured by Tokyo Chemical Industry Co., Ltd., substance absorbing light of 405 nm)
“AE-6”: Acid Yellow 3 (manufactured by Tokyo Chemical Industry Co., Ltd., substance absorbing light of 405 nm)
“AE-7”: MACROLEX (registered trademark) Yellow E2R (manufactured by LANXESS, substance absorbing light of 405 nm)
“AE-8”: diethylamino-phenylsulfonyl-based ultraviolet absorber (manufactured by DAITO KAGAKU KOGYO K.K., substance absorbing light of 365 nm)
“AE-9”: Tinuvin 477 (manufactured by BASF Japan Ltd., substance absorbing light of 365 nm)
“AE-10”: Tinuvin 477-DW(N) (manufactured by BASF Japan Ltd., substance absorbing light of 365 nm)
“AE-11”: Tinuvin 360 (manufactured by BASF Japan Ltd., substance absorbing light of 365 nm)
“AE-12”: CBT-1 (manufactured by JOHOKU CHEMICAL CO., LTD.)
“AE-13”: F-552 (manufactured by DIC Corporation)
“AE-14”: F-444 (manufactured by DIC Corporation)
“AE-15”: Bonasorb UA-3911 (indole-based compound, manufactured by ORIENT CHEMICAL INDUSTRIES CO., LTD, substance absorbing light of 405 nm)
“AE-16”: Bonasorb UA-3912 (indole-based compound, manufactured by ORIENT CHEMICAL INDUSTRIES CO., LTD, substance absorbing light of 405 nm)
“AE-17”: FDB-009 (manufactured by Yamada Chemical Co., Ltd., substance absorbing light of 405 nm)
“AE-18”: compound represented by the following structural formula (substance absorbing light of 405 nm)

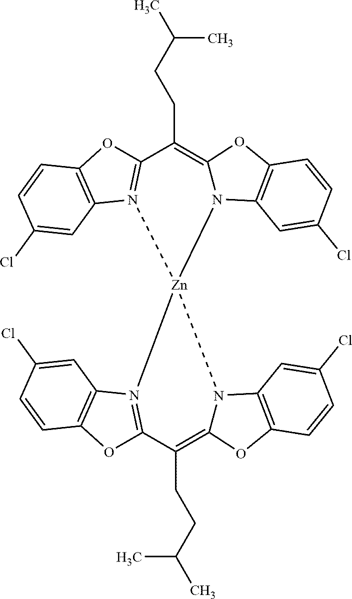

“AE-19”: compound represented by the following structural formula (substance absorbing light of 405 nm)
   t-Bu represents a t-butyl group, and Et represents an ethyl group.

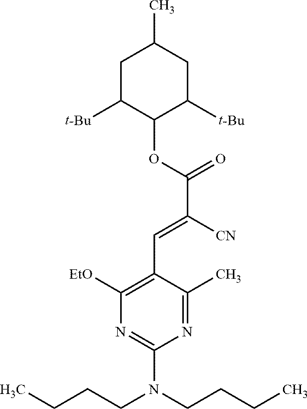 [SMILES: CCCCN(CCCC)c1nc(C)c(/C=C(\C#N)C(=O)OC2C(C(C)(C)C)CC(C)CC2C(C)(C)C)c(OCC)n1]

“AE-20”: compound represented by the following structural formula (substance absorbing light of 405 nm)

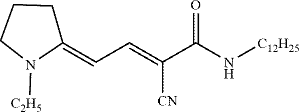

“AE-21”: compound represented by the following structural formula (substance absorbing light of 405 nm)

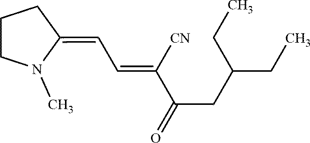 [SMILES: CCC(CC)CC(=O)/C(C#N)=C/C=C1/CCCN1C]

“AE-22”: compound represented by the following structural formula (substance absorbing light of 405 nm)

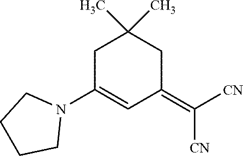 [SMILES: CC1(C)CC(N2CCCC2)=CC(=C(C#N)C#N)C1]

“AE-23”: compound represented by the following structural formula (substance absorbing light of 405 nm) [0584]

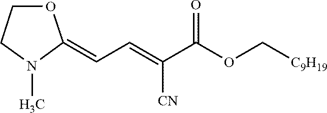

“AF-1”: methyl ethyl ketone (manufactured by SANKYO CHEMICAL CO., LTD.)
“AF-2”: propylene glycol monomethyl ether acetate (manufactured by SHOWA DENKO K.K.)
“AF-3”: deionized water
“AF-4”: methanol (manufactured by MITSUBISHI GAS CHEMICAL COMPANY, INC.)

### Preparation of Thermoplastic Resin Composition

The compounds selected according to the description in Table 6 were mixed together, thereby preparing thermoplastic resin compositions A1a to A15a.

TABLE 6

| Theroplastic resin composition | A1a | A2a | A3a | A4a | A5a | A6a | A7a | A8a | A9ₐ | A10a | A11a | A12a | A13ₐ | A14a | A15a |
|---|---|---|---|---|---|---|---|---|---|---|---|---|---|---|---|
| AA-2 | 42.85 | 42.02 | 42.02 | 42.02 | 41.15 | 42.15 | 42.02 | 42.02 | 42.02 | 42.02 | 42.02 | 42.02 | 42.02 | 42.02 | 42.02 |
| AB-3 | 5.02 | 5.03 | 5.03 | 5.03 | 5.03 | 5.03 | 5.03 | 5.03 | 5.03 | 5.03 | 5.03 | 5.03 | 5.03 | 5.03 | 5.03 |
| AB-4 | 2.31 | 2.31 | 2.31 | 2.31 | 2.31 | 2.31 | 2.31 | 2.31 | 2.31 | 2.31 | 2.31 | 2.31 | 2.31 | 2.31 | 2.31 |
| AB-5 | 0.77 | 0.77 | 0.77 | 0.77 | 0.77 | 0.77 | 0.77 | 0.77 | 0.77 | 0.77 | 0.77 | 0.77 | 0.77 | 0.77 | 0.77 |
| AB-3 | - | 0.25 | - | - | - | - | - | - | - | - | - | - | - | - | - |
| AE-4 | - | - | 0.25 | - | - | - | - | - | - | - | - | - | - | - | - |
| AE-5 | - | - | - | 0.23 | - | - | - | - | - | - | - | - | - | - | - |
| AE-8 | - | - | - | - | 0.10 | - | 0.10 | 0.10 | 0.10 | 0.10 | 0.10 | 0.10 | 0.10 | 0.10 | 0.10 |
| AE-9 | - | - | - | - | - | 0.10 | - | - | - | - | - | - | - | - | - |
| AE-15 | - | - | - | - | - | - | 0.20 | - | - | - | - | - | - | - | - |
| AE-16 | - | - | - | - | - | - | - | 0.20 | - | - | - | - | - | - | - |
| AE-17 | - | - | - | - | - | - | - | - | 0.20 | - | - | - | - | - | - |
| AE-18 | - | - | - | - | - | - | - | - | - | 0.20 | - | - | - | - | - |
| AE-19 | - | - | - | - | - | - | - | - | - | - | 0.20 | - | - | - | - |
| AE-20 | - | - | - | - | - | - | - | - | - | - | - | 0.20 | - | - | - |
| AE-21 | - | - | - | - | - | - | - | - | - | - | - | - | 0.20 | - | - |
| AE-21 | - | - | - | - | - | - | - | - | - | - | - | - | - | 0.20 | - |
| AE-23 | - | - | - | - | - | - | - | - | - | - | - | - | - | - | 0.20 |
| AE-6 | 0.03 | 0.03 | 0.03 | 0.03 | 0.03 | 0.03 | - | - | - | - | - | - | - | - | - |
| AF-1 | 39.50 | 40.08 | 40.08 | 48.03 | 40.10 | 40.20 | 40.00 | 40.06 | 40.06 | 40.06 | 40.06 | 40.06 | 40.05 | 40.06 | 40.06 |
| AF-2 | 9.51 | 9.51 | 9.51 | 9.51 | 9.51 | 9.51 | 9.51 | 9.51 | 9.51 | 9.51 | 9.51 | 9.51 | 9.51 | 9.51 | 9.51 |

### Preparation of Interlayer Composition

The compounds selected according to the description in Table 7 were mixed together, thereby preparing interlayer compositions 1b to 3b.

TABLE 7

| Interlayer composition | 1b | 2b | 3b |
|---|---|---|---|
| AA-3 | 3.22 | 3.22 | 3.22 |
| AA-4 | 1.49 | 1.49 | 1.49 |
| AE-6 | - | 0.0025 | - |
| AE-10 | - | - | 0.0025 |
| AE-14 | 0.0015 | 0.0015 | 0.0015 |
| AF-3 | 38.12 | 38.12 | 38.12 |
| AF-4 | 57.17 | 57.17 | 57.17 |

### Preparation of Composition for Forming Photosensitive Layer

The compounds selected according to the description in Table 8 were mixed together, thereby preparing photosensitive resin compositions 1c to 8c and 1d to 9d.

TABLE 8

| | First photosensitive resincomposition | | | | | | | | Second photosensitive resin composition | | | | | | | | |
|---|---|---|---|---|---|---|---|---|---|---|---|---|---|---|---|---|---|
| | 1c | 2c | 3c | 4c | 5c | 6c | 7c | 8c | 1d | 2d | 3d | | 5d | 6d | 7d | 8d | 9d |
| AA-1 | 21.83 | 21.33 | 21.33 | 21.33 | 21.33 | 21.33 | 21.33 | 21.33 | 22.77 | 22.37 | 22.37 | 22.37 | 18.60 | 24.57 | 22.37 | 22.37 | 22.37 |
| AB-1 | 4.90 | 3.30 | 3.30 | 3.30 | 4.90 | 4.90 | 4.90 | 4.90 | 4.90 | 3.30 | 3.30 | 3.30 | 4.90 | 4.90 | 4.90 | 4.90 | 4.90 |
| AB-2 | 0.50 | 0.50 | 9.50 | 0.50 | 0.50 | 0.50 | 0.50 | 0.50 | 0.50 | 0.50 | 9.50 | 0.50 | 0.50 | 0.50 | 0.50 | 0.50 | 9.50 |
| AB-6 | - | 1.60 | - | - | - | - | - | - | - | 1.60 | - | - | - | - | - | - | - |
| AB-7 | - | - | 1.60 | - | - | - | - | - | - | - | 1.60 | - | - | - | - | - | - |
| AB-8 | - | - | - | 1.60 | - | - | - | - | - | - | - | 1.60 | - | - | - | - | - |
| AC-1 | 1.00 | 1.00 | 1.00 | 1.00 | 1.00 | 1.00 | 1.00 | 1.00 | 0.80 | 0.50 | 0.80 | 0.80 | - | - | 0.80 | 0.80 | 0.80 |
| AC-2 | - | - | - | - | - | - | - | - | - | - | - | - | 2.00 | - | - | - | - |
| AC-3 | - | - | - | - | - | - | - | - | - | - | - | - | - | 0.21 | - | - | - |
| AC-4 | - | - | - | - | 0.15 | - | - | - | - | - | - | - | - | - | - | - | - |
| AC-5 | 0.15 | 0.15 | 0.15 | 0.15 | - | - | 0.15 | 0.15 | - | - | - | - | - | - | - | - | - |
| AC-6 | - | - | - | - | - | - | - | - | 0.07 | 0.07 | 0.07 | 0.07 | - | - | 0.07 | 0.07 | 0.07 |
| AC-7 | - | - | - | - | - | 0.15 | - | - | - | - | - | - | - | - | - | - | - |
| AD-1 | 0.0175 | 0.0175 | 0.0175 | 0.0175 | 0.0175 | 0.01 75 | 0.0175 | 0.0175 | 0.04 | 0.04 | 0.04 | 0.04 | 0.04 | 0.04 | 0.04 | 0.04 | 0.04 |
| AD-2 | 0.0011 | 0.0011 | 0.0011 | 0.0011 | 0.0011 | 0.0011 | 0.0011 | 0.0011 | 0.0011 | 0.0011 | 0.0011 | 0.0011 | 0.0011 | 0.0011 | 0.0011 | 0.0011 | 0.0011 |
| AE-1 | 0.051 | 0.051 | 0.051 | 0.051 | 0.051 | 0.051 | 0.051 | 0.051 | 0.05 | 0.05 | 0.05 | 0.05 | 0.05 | 0.05 | 0.05 | 0.05 | 0.05 |
| AE-2 | 1.80 | 1.80 - | 1.80 | 1.80 | 1.80 | 1.80 | 1.80 | 1.80 | 1.80 | 1.80 | 1.80 | 1.80 | 1.80 | 1.80 | 1.80 | 1.80 | 1.80 |
| AE-3 | - | - | - | - | - | - | - | - | - | - | - | - | - | - | 0.12 | - | - |
| AE-4 | - | - | - | - | - | - | - | - | - | - | - | - | - | - | - | 0.12 | - |
| AE-5 | - | - | - | - | - | - | - | - | - | - | - | - | - | - | - | - | 0.12 |
| AE-8 | - | - | - | - | - | - | 0.15 | - | - | - | - | - | - | - | - | - | - |
| AE-9 | - | - | - | - | - | - | - | 0.05 | - | - | - | - | - | - | - | - | - |
| AE-5 | 0.12 | 0.12 | 0.12 | 0.12 | 0.12 | 0.12 | 0.12 | 0.12 | 0.12 | 0.12 | 0.12 | 0.12 | 0.12 | 0.12 | 0.12 | 0.12 | 012 |
| AE-6 | 0.05 | 0.05 | 0.05 | 0.05 | 0.05 | 0.05 | 0.05 | 0.05 | 0.05 | 0.05 | 0.05 | 0.05 | 0.05 | 0.05 | 0.05 | 0.05 | 0.05 |
| AF-1 | 41.48 | 41.83 | 41.83 | 41.83 | 41.83 | 41.83 | 41.83 | 41.83 | 40.70 | 40.98 | 40.98 | 40.98 | 43.62 | 39.44 | 40.98 | 40.98 | 40.98 |
| AF-2 | 26.10 | 26.10 | 26.10 | 26.10 | 26.10 | 26.10 | 26.10 | 26.10 | 26.10 | 26.10 | 26.10 | 26.10 | 26.10 | 26.10 | 26.10 | 26.10 | 26.10 |
| AF-4 | 2.00 | 2.00 | 2.00 | 2.00 | 2.00 | 2.00 | 2.00 | 2.00 | 2.00 | 2.00 | 2.00 | 2.00 | 2.00 | 2.00 | 2.00 | 2.00 | 2.00 |

### Preparation of Transfer Material

By using a slit-like nozzle, the surface of a temporary support (polyethylene terephthalate film, thickness: 16 µm, haze: 0.12%) was coated with the thermoplastic resin composition described in Table 9, such that the coating width was 1.0 m and the layer thickness was 3.0 µm after drying. The thermoplastic resin composition was dried at 80° C. for 40 seconds, thereby forming a thermoplastic resin layer.

By using a slit-like nozzle, the surface of the thermoplastic resin layer was coated with the interlayer composition described in Table 9, such that the coating width was 1.0 m and the layer thickness was 1.2 µm after drying. The interlayer composition 2 was dried at 80° C. for 40 seconds, thereby forming an interlayer.

By using a slit-like nozzle, the surface of the interlayer was coated with the photosensitive resin composition described in Table 9, such that the coating width was 1.0 m and the layer thickness was 3.0 µm after drying. The photosensitive resin composition was dried at 100° C. for 2 minutes, thereby forming a photosensitive layer.

A protective film (polypropylene film, thickness: 12 µm, haze: 0.2%) was disposed on the surface of the photosensitive layer.

Through the above procedure, a transfer material was prepared (see Table 9).

### Preparation of Laminate

The transfer material selected according to the description in Table 9 was cut in 50 cm x 50 cm, and the protective film was peeled off from the transfer material. Then, under lamination conditions of a roll temperature of 90° C., a linear pressure of 0.8 MPa, and a linear speed of 3.0 m/min, the transfer material was bonded to both surfaces of a substrate (polyethylene terephthalate film, thickness: 40 µm). Specifically, a transfer material for forming the first photosensitive layer (that is, a first transfer material) was bonded to one surface of the substrate, and a transfer material (that is, a second transfer material) for forming the second photosensitive layer was bonded to the other surface of the substrate. Through the above procedure, a laminate was prepared.

### Pattern Formation

According to the method described above in the section of “Pattern formation”, a substrate with a resin pattern was prepared.

### Evaluation

By using the substrates with a resin pattern, resolution and exposure fogging were evaluated according to the evaluation method described above. The evaluation results are shown in Table 9.

TABLE 9

| | First photosensitive layer | | | Second photosensitive layer | | | Exposure conditions | | | | S₁₂/ S₁₁ | S₂₂/ S₁₂ | Exposure foggging | Resolution on first photosensitive material side | Resolution on second photosensitive material side |
|---|---|---|---|---|---|---|---|---|---|---|---|---|---|---|---|
| | | | | | | | First photosensitive layer | | Second photosensitive layer | | | | | | |
| | Thermoplastic resin composition | Interlayer composition | Photosensitive resin composition | Thermoplasti c resin | Interlayer composition | Photosensit ive resin composition | Exposure wavelength | Exposure amount [ml/cm²] | Exposurewavelength | Exposure amount [ml/cm²] | | | | | |
| Example 29 | A1a | 1b | 1c | A1a | 1b | 1d | Not including 365 nm | 120 | Not including 405 nm | 60 | 5.8 | 4.1 | A | C | C |
| Example30 | A5a | 1b | 1c | A2a | 1b | 1d | Not including 355 nm | 120 | Not including 405 nm | 60 | 5.8 | 4.2 | A | A | A |
| Ex ample31 | A5a | 1b | 1c | A3a | 1b | 1d | Not including 365 nm | 120 | Not including 405 nm | 60 | 5.8 | 4.1 | A | A | A |
| Example 32 | A5a | 1b | 1c | A4a | 1b | 1d | Not including 365 nm | 120 | Not including 405 nm | 70 | 5.8 | 4.2 | A | A | A |
| Example 33 | A6a | 1b | k | A2a | 1b | 1d | Not including 365 nm | 130 | Not including 405 nm | 60 | 5.8 | 4.2 | A | A | A |
| Example 34 | A1a | 3b | 1c | A1a | 2b | 1d | Not including 365 nm | 120 | Not including 405 nm | 60 | 5.8 | 4.0 | A | A | A |
| Example 35 | 35 | 1b | 2c | A2a | 1b | 1d | Not including 365 nm | 110 | Not including 405 nm | 60 | 5.7 | 4.1 | A | A | A |
| Example 36 | A5a | 1b | 3c | A2a | 1b | 1d | Not including 365 nm | 120 | Not including 405 nm | 60 | 5.8 | 4.1 | A | A | A |
| Example 37 | A5a | 1b | 4c | A2a | 1b | 1d | Not including 365 nm | 120 | Not including 405 nm | 60 | 5.7 | 4.1 | A | A | A |
| Example 38 | A5a | 1b | 5c | A2a | 1b | 1d | Not including 365 nm | 160 | Notincluding 405 nm | 60 | 4.8 | 4. 1 | A | A | A |
| Example 39 | A5a | 1b | 6c | A2a | 1b | 1d | Not including 365 nm | 160 | Not including 405 nm | 60 | 3.2 | 4.1 | A | A | A |
| Example 40 | A5a | 1b | 1c | A2a | 1b | 2d | Not including 365 nm | 120 | Not including 405 nm | 70 | 5.8 | 4.0 | A | A | A |
| Example 41 | A5a | 1b | 1c | A2a | 1b | 3d | Not including 365 nm | 120 | Not including 405 nm | 60 | 5.8 | 4.1 | A | A | A |
| Example 42 | A5a | 1b | 1c | A2a | 1b | 4d | Not including 365 nm | 120 | Not including 405 nm | 60 | 5.8 | 4.1 | A | A | A |
| Example 43 | A5a | 1b | 1c | A2a | 1b | 5d | Not including 365 nm | 120 | Not including 405 nm | 90 | 5.8 | 3.6 | A | A | A |
| Example 44 | A5a | 1b | 1c | A2a | 1b | 6d | Not including 365 nm | 120 | Not including 405 nm | 70 | 5.8 | 3.9 | A | A | A |
| Example 45 | A1 a | 1b | 7c | A1a | 1b | 70 | Not including365 nm | 120 | Not including 405 nm | 80 | 4.2 | 3. 6 | A | A | A |
| Example 46 | A1a | 1b | 7c | A1a | 1b | 8d | Not including 365 nm | 120 | Not including 405 nm | 80 | 4.2 | 3.4 | A | A | A |
| Example 47 | A1a | 1b | 7c | A1a | 1b | 9d | Not including 365 nm | 120 | Not including 405 nm | 70 | 4.2 | 3. 4 | A | A | A |
| Example48 | A1a | 1b | 8c | A1a | 1b | 7d | Not including 365 nm | 130 | Not including 405 nm | 80 | 4.0 | 3.6 | A | A | A |
| Example 49 | A1a | 1b | 8c | A1a | 1b | 8d | Not including 365 nm | 130 | Not including 405 nm | 80 | 4. 0 | 3. 4 | A | A | A |
| Example 50 | A1a | 1b | 8c | A1a | 1b | 9d | Not including 365 nm | 130 | Not including 405 nm | 70 | 4.0 | 3.4 | A | A | A |

The laminates of Examples 29 to 50 satisfied the characteristics A and B.

As shown in Table 9, it has been confirmed that in Examples 29 to 50, the occurrence of exposure fogging can be suppressed, and a resin pattern having excellent resolution can be obtained.

### Example 51

### Preparation of PET Film

By the method described in paragraph “0060” of JP 1994-306192A (JP-H06-306192A), an ultraviolet-absorbing polyethylene terephthalate film (hereinafter, called “PET (A)”) was prepared. As an ultraviolet absorber, instead of the dye described in the above publication, AE-11 described above was used to adjust the absorption material, such that the film had a transmittance of 30% for light having a wavelength of 350 nm to 380 nm.

In addition, by the method described in paragraph “0060” of JP1994-306192A (JP-H06-306192A), a colored polyethylene terephthalate film (hereinafter, called “PET (B)”) was prepared. As a coloring dye, instead of the dye described in the above publication, AE-7 described above was used to adjust the dye amount, such that the film had a transmittance of 30% for light having a wavelength of 405 nm to 440 nm.

### Preparation of Photosensitive Transfer Material

By using a slit-like nozzle, PET (A) was coated with a thermoplastic resin composition A1a, such that the coating with was 1.0 m and the layer thickness was 3.0 µm after drying. The formed coating film of the thermoplastic resin composition was dried at 80° C. for 40 seconds, thereby forming a thermoplastic resin layer.

By using a slit-like nozzle, the surface of the formed thermoplastic resin layer was coated with an interlayer composition 1b, such that the coating width was 1.0 m and the layer thickness was 1.2 µm after drying. The coating film of the interlayer composition was dried at 80° C. for 40 seconds, thereby forming an interlayer.

By using a slit-like nozzle, the surface of the formed interlayer was coated with a photosensitive resin composition 1c, such that the coating with was 1.0 m and the layer thickness was 3.0 µm after drying, followed by drying at 100° C. for 2 minutes, thereby forming a photosensitive layer. A protective film (polypropylene film, thickness: 12 µm, haze: 0.2%) was bonded to the photosensitive layer, thereby preparing a photosensitive transfer material A.

By using a slit-like nozzle, PET (B) was coated with a thermoplastic resin composition A1a, such that the coating with was 1.0 m and the layer thickness was 3.0 µm after drying. The formed coating film of the thermoplastic resin composition was dried at 80° C. for 40 seconds, thereby forming a thermoplastic resin layer.

By using a slit-like nozzle, the surface of the formed thermoplastic resin layer was coated with an interlayer composition 1b, such that the coating width was 1.0 m and the layer thickness was 1.2 µm after drying. The coating film of the interlayer composition was dried at 80° C. for 40 seconds, thereby forming an interlayer.

By using a slit-like nozzle, the surface of the formed interlayer was coated with a photosensitive resin composition 1d, such that the coating with was 1.0 m and the layer thickness was 3.0 µm after drying, followed by drying at 100° C. for 2 minutes, thereby forming a photosensitive layer. A protective film (polypropylene film, thickness: 12 µm, haze: 0.2%) was bonded to the photosensitive layer, thereby preparing a photosensitive transfer material B.

Between the obtained photosensitive transfer materials, the photosensitive transfer material A corresponds to a first photosensitive transfer material (exposed to light not including 365 nm), and the photosensitive transfer material B corresponds to a second photosensitive transfer material (exposed to light not including 405 nm)

By using the photosensitive transfer materials A and B, performance evaluation was carried out in the same manner as in Example 29. Excellent results were obtained for both the exposure fogging and the resolution of the photosensitive transfer materials A and B.

The laminate of Example 51 satisfied the characteristics A and B.

### Examples 52 to 73

By using the same laminates as in Examples 29 to 50, under the evaluation conditions shown in Table 10, resolution and exposure fogging were evaluated according to the evaluation method described above. The results are shown in Table 10.

TABLE 10

| | + First photosensitive layer | | | Second photosensitive layer | | | Exposure conditions | | | | [symbol] | [symbol] | Exposure fogging | Resolution on first photosensitive material side | Resolution on second photosensitive material side |
|---|---|---|---|---|---|---|---|---|---|---|---|---|---|---|---|
| | | | | | | | First photosensitive layer | | Second photosensitive layer | | | | | | |
| | Thermoplastic resin composition | Interlayer composition | Photosensitive resin | Thermoplastic resin composition | Interlayer composition | Photosensitive resin composition | Exposure wavelength | Exposure amount [ml/cm] | Exposure wavelength | Exposure amount [ml/cm] | | | | | |
| Example 52 | A1a | 1b | 1c | A1a | 1b | 1d | Not including wavelength of 405 nm or less- | 130 | Not including wavelength of 405 nm or more | 60 | 5.8 | 4.5 | A | C | C |
| Example 53 | A5a | 1b | 1c | A2a | 1b | 1d | Not including wavelength of 405 nm or less | 130 | Not including wavelength of 405 nm or more | 60 | 5.8 | 4.6 | A | A | A |
| Example 54 | A5a | 1b | 1c | A3a | 1b | 1d | Not including wavelength of 405 nm or less | 130 | Not including wavelength of 405 nm or more | 60 | 5.8 | 4.4 | A | A | A |
| Example 55 | A5a | 1b | 1c | A4a | 1b | 1d | Not including wavelength of 405 nm or less | 130 | Not including wavelength of 405 nm or more | [symbol] | 5.8 | 4.5 | A | A | A |
| Example 56 | [symbol] | 1b | 1c | A2a | 1b | 1d | Not including wavelength of 405 nm or less | 130 | Not including wavelength of 405 nm or more | 60 | 5.8 | 4.5 | A | A | A |
| Example 57 | [symbol] | [symbol] | 2c | A1a | 2b | 1d | Not including wavelength of 405 nm or less | 130 | Not including wavelength of 405 nm or more | 60 | 5.8 | 4.3 | A | A | A |
| Example 58 | A5a | 1b | 3c | A2a | 1b | 1d | Not including wavelength of 405 nm or less | 115 | Not including wavelength of 405 nm or more | 60 | 5.7 | 4.2 | A | A | A |
| Example 59 | A5a | 1b | 4c | A2a | 1b | 1d | Not including wavelength of 405 nm or less | 130 | Not including wavelength of 405 nm or more | 60 | 5.8 | 4.5 | A | A | A |
| Example 60 | A5a | 1b | 5c | A2a | 1b | 1d | Not including wavelength of 405 nm or less | 135 | Not including wavelength of 405 nm or more | 60 | 5.7 | 4.4 | A | A | A |
| Example 61 | A5a | 1b | 6c | A2a | 1b | 1d | Not including wavelength of 405 nm or less | 180 | Not including wavelength of 405 nm or more | 60 | 4.8 | 4.3 | A | A | A |
| Example 62 | A5a | 1b | 1c | A2a | 1b | 1d | Not including wavelength of 405 nm or less | 180 | Not including wavelength of 405 nm or more | 60 | 3.2 | 4.2 | A | A | A |
| Example 63 | A5a | 1b | 1c | A2a | 1b | 2d | Not including wavelength of 405 nm or less | 130 | Not including wavelength of 405 nm or more | 70 | 5.8 | 4.1 | A | A | A |
| Example 64 | A5a | 1b | 1c | A2a | 1b | 3d | Not including wavelength of 405 nm or less | 130 | Not including wavelength of 405 nm or more | 60 | 5.8 | 4.4 | A | A | A |
| Example 65 | A5a | 1b | 1c | A2a | 1b | 4d | Not including wavelength of 405 nm or less | 130 | Not including wavelength of 405 nm or more | 60 | 5.8 % | 4.3 | A | A | A |
| Example 66 | A5a | 1b | 1c | A2a | 1b | 5d | Not including wavelength of 405 nm or less | 130 | Not including wavelength of 405 nm or more | 90 | 5.8 | 3.6 | A | A | A |
| Example 67 | A5a | 1b | 1c | A2a | 1b | 6d | Not including wavelength of 405 nm or less | 130 | Not including wavelength of 405 nm or more | 70 | 5.8 | 3.9 | A | A | A |
| Example 68 | A1a | 1b | 7c | A1a | 1b | 7d | Not including wavelength of 405 nm or less | 130 | Not including wavelength of 405 nm or more | 80 | 4.2 | 3.9 | A | A | A |
| Example 69 | A1a | 1b | 7c | A1a | 1b | 8d | Not including wavelength of 405 nm or less | 130 | Not including wavelength of 405 nm or more | 80 | 4.2 | [symbol] | A | A | A |
| Example 70 | A1a | 1b | 7c | A1a | 1b | 9d | Not including wavelength of 405 nm or less | 130 | Not including wavelength of 405 nm or more | 70 | 4.2 | [symbol] | A | A | A |
| Example 71 | A1a | 1b | 8c | A1a | 1b | 7d | Not including wavelength of 405 nm or less | 145 | Not including wavelength of 405 nm or more | 80 | 4.0 | 3.9 | A | A | A |
| Example 72 | A1a | 1b | 8c | A1a | 1b | 8d | Not including wavelength of 405 nm or less | 145 | Not including wavelength of 405 nm or more | 80 | 4.0 | 3.7 | A | A | A |
| Example73 | A1a | 1b | 8a | A1a | 1b | 8d | Not including wavelength of 405 nm or less | 145 | Not including wavelength of 405 nm or more | 70 | 4.0 | 3.7 | A | A | A |

[symbol]

indicates text missing or illegible when filed

The laminates of Examples 52 to 73 satisfied the characteristics A and B.

The meanings of “not including wavelength of 405 nm or less” and “not including wavelength of 405 nm or more” described above are as follows.

“Exposure conditions not including wavelength of 405 nm or less”: the photosensitive layer was exposed through a short wavelength cut filter (model number: LU0422, cutoff wavelength: 422 nm, manufactured by Asahi Spectra Co., Ltd.) by using an ultra-high-pressure mercury lamp (USH-2004MB, manufactured by Ushio Inc.). The dominant wavelength is 436 nm. In a case where the intensity of the dominant wavelength is 100%, the intensity at the wavelength of 365 nm is 0.5% or less.

“Not including wavelength of 405 nm or more”: the photosensitive layer was exposed through a bandpass filter for mercury exposure (model number: HB0365, central wavelength: 365 nm, manufactured by Asahi Spectra Co., Ltd.) by using an ultra-high-pressure mercury lamp (USH-2004MB, manufactured by Ushio Inc.). The dominant wavelength is 365 nm. In a case where the intensity of the dominant wavelength is 100%, the intensity at wavelengths of 405 nm and 436 nm is 0.5% or less.

In addition, in the case of exposure conditions not including a wavelength of 405 nm or less, the exposure amount was measured through the aforementioned LU0422 cut filter by mounting an optical receiver for 405 nm (UVD-C405, manufactured by Ushio Inc.) on an illuminance meter (UIT-250, manufactured by Ushio Inc.). In the case of exposure conditions not including a wavelength of 405 nm or more, the exposure amount was measured through the aforementioned bandpass filter (HB0365) by mounting an optical receiver for 365 nm (UVD-C365, manufactured by Ushio Inc.) on an illuminance meter.

As is evident from Table 10, even though the evaluation conditions were changed, the laminate according to the present disclosure could be excellent in exposure fogging and resolution performance.

### Examples 74 to 107

### Abbreviation

The following abbreviations represent the following compounds, respectively.
“BA-1”: propylene glycol monomethyl ether acetate solution of copolymer of styrene/methacrylic acid/methyl methacrylate (concentration of solid contents: 30.0% by mass, ratio of monomers: 52% by mass/29% by mass/19% by mass, Mw: 70,000)
“BB-1”: BPE-500 (manufactured by SHIN-NAKAMURA CHEMICAL CO, LTD.)
“BB-2”: NK ESTER HD-N (manufactured by SHIN-NAKAMURA CHEMICAL CO, LTD.)
“BB-3”: NK ESTER NOD-N (manufactured by SHIN-NAKAMURA CHEMICAL CO, LTD.)
“BB-4”: NK ESTER A-HD-N (manufactured by SHIN-NAKAMURA CHEMICAL CO, LTD.)
“BB-5”: NK ESTER 4G (manufactured by SHIN-NAKAMURA CHEMICAL CO, LTD.)
“BB-6”: SARTOMER SR454 (manufactured by Arkema S.A.)
“BB-7”: NK ESTER A-TMPT (manufactured by SHIN-NAKAMURA CHEMICAL CO, LTD.)
“BB-8”: polyethylene glycol dimethacrylate obtained by adding an average of 15 mol of ethylene oxide and an average of 2 mol of propylene oxide to both ends of bisphenol A
“BB-9”: NK ESTER A-9300-1CL (manufactured by SHIN-NAKAMURA CHEMICAL CO, LTD.)
“BC-1”: B-CIM (manufactured by KUROGANE KASEI Co., Ltd.)
“BC-2”: SB-PI 701 (obtained from SANYO TRADING CO., LTD.)
“BC-3”: 4,4′-bis(dimethylamino)benzophenone (manufactured by Tokyo Chemical Industry Co., Ltd.)
“BC-4”: 2-isopropylthioxanthone (manufactured by Tokyo Chemical Industry Co., Ltd.)
“BC-5”: coumarin 7 (manufactured by Tokyo Chemical Industry Co., Ltd.)
“BC-6”: hexyl 7-(diethylamino)coumarin-3-carboxylate (manufactured by Tokyo Chemical Industry Co., Ltd.)
“BC-7”: coumarin 314 (manufactured by Tokyo Chemical Industry Co., Ltd.)
“BC-8”: coumarin 521T (manufactured by Tokyo Chemical Industry Co., Ltd.)
“BC-9”: coumarin 334 (manufactured by Sigma-Aldrich Japan K.K.)
“BC-10”: 3-acetyl-7-(diethylamino)coumarin (manufactured by FUJIFILM Wako Pure Chemical Corporation)
“BD-1”: TDP-G (manufactured by Kawaguchi Chemical Industry Co., LTD.)
“BD-2”: 1-phenyl-3-pyrazolidone (manufactured by FUJIFILM Wako Pure Chemical Corporation)
“BE-1”: leuco Crystal Violet (manufactured by Tokyo Chemical Industry Co., Ltd.)
“BE-2”: N-phenylcarbamoylmethyl-N-carboxymethylaniline (manufactured by FUJIFILM Wako Pure Chemical Corporation)
“BE-5”: CBT-1 (manufactured by JOHOKU CHEMICAL CO., LTD.)
“BE-6”: F-552 (manufactured by DIC Corporation)
“BF-1”: methyl ethyl ketone (manufactured by SANKYO CHEMICAL CO., LTD.)
“BF-2”: propylene glycol monomethyl ether acetate (manufactured by SHOWA DENKO K.K.)
“BF-4”: methanol (manufactured by MITSUBISHI GAS CHEMICAL COMPANY, INC.)

### Preparation of Composition for Forming Photosensitive Layer

The compounds selected according to the description in Table 11 or 12 were mixed together, thereby preparing photosensitive resin compositions 1e to 14e and 1f to 11f.

TABLE 11

first photosensitive resin composition

| | 1c | 2c | 3c | 4c | 5c | 6c | 7c | 8c | 9c | 10c | 11c | 12c | 13e | 14e |
|---|---|---|---|---|---|---|---|---|---|---|---|---|---|---|
| BA-1 | 21.83 | 21.83 | 21.83 | 21.83 | 21.83 | 21.83 | 21.83 | 21.83 | 21.83 | 21.83 | 21.83 | 21.83 | 21.83 | 21.83 |
| BB-1 | 3.30 | 3.30 | 3.30 | 3.30 | 3.30 | 3.30 | 3.30 | 3.30 | 3.30 | 3.30 | 3.30 | 4.00 | 2.30 | 3.35 |
| BB-2 | 2.10 | - | - | - | - | - | 2.10 | 2.10 | 2.10 | 2.10 | 2.10 | - | - | - |
| BB-3 | - | 2.10 | - | - | - | - | - | - | - | - | - | - | - | - |
| BB-4 | - | - | 2.10 | - | - | - | - | - | - | - | - | - | - | - |
| BB-5 | - | - | - | 2.10 | - | - | - | - | - | - | - | - | - | - |
| BB-6 | - | - | - | - | 2.10 | - | - | - | - | - | - | 0.70 | 0.75 | 0.70 |
| BB-7 | - | - | - | - | - | 2.10 | - | - | - | - | - | 0.70 | 0.75 | - |
| BB-8 | - | - | - | - | - | - | - | - | - | - | - | - | 1.60 | - |
| BB-9 | - | - | - | - | - | - | - | - | - | - | - | - | - | 1.00 |
| BC-1 | 1.00 | 1.00 | 1.00 | 1.00 | 1.00 | 1.00 | 1.00 | 1.00 | 1.00 | 1.00 | 1.00 | 1.00 | 1.00 | 1.00 |
| BC-2 | - | - | - | - | - | - | - | - | - | - | - | - | - | - |
| BC-3 | - | - | - | - | - | - | - | - | - | - | - | - | - | - |
| BC-4 | - | - | - | - | - | - | - | - | - | - | - | - | - | - |
| BC-5 | - | - | - | - | - | - | 0.15 | - | - | - | - | 0.15 | 0.15 | 0.15 |
| BC-6 | - | - | - | - | - | - | - | 0.15 | - | - | - | - | - | - |
| BC-7 | - | - | - | - | - | - | - | - | 0.15 | - | - | - | - | - |
| BC-8 | - | - | - | - | - | - | - | - | - | 0.15 | - | - | - | - |
| BC-9 | - | - | - | - | - | - | - | - | - | - | 0.15 | - | - | - |
| BC-10 | 0.15 | 0.15 | 0.15 | 0.15 | 0.15 | 0.15 | - | - | - | - | - | - | - | - |
| BD-1 | 0.02 | 0.0175 | 0.0175 | 0.0175 | 0.02 | 0.0175 | 0.02 | 0.02 | 0.02 | 0.02 | 0.02 | 0.02 | 0.02 | 0.02 |
| BD-2 | 0.00 | 0.0011 | 0.0011 | 0.0011 | 0.00 | 0.0011 | 0.00 | 0.00 | 0.00 | 0.00 | 0.00 | 0.00 | 0.00 | 0.00 |
| BE-1 | 0.05 | 0.05 | 0.05 | 0.05 | 0.05 | 0.05 | 0.05 | 0.05 | 0.05 | 0.05 | 0.05 | 0.05 | 0.05 | 0.05 |
| BE-2 | 1.80 | 1.80 | 1.80 | 1.80 | 1.80 | 1.80 | 1.80 | 1.80 | 1.80 | 1.80 | 1.80 | 1.80 | 1.80 | 1.80 |
| BE-5 | 0.12 | 0.12 | 0.12 | 0.12 | 0.12 | 0.12 | 0.12 | 0.12 | 0.12 | 0.12 | 0.12 | 0.12 | 0.12 | 0.12 |
| BE-6 | 0.05 | 0.05 | 0.05 | 0.05 | 0.05 | 0.05 | 0.05 | 0.05 | 0.05 | 0.05 | 0.05 | 0.05 | 0.05 | 0.05 |
| BF-1 | 41.48 | 41.48 | 41.48 | 41.48 | 41.48 | 41.48 | 41.48 | 41.48 | 41.48 | 41.48 | 41.48 | 41.48 | 41.48 | 41.83 |
| BF-2 | 26.10 | 26.10 | 26.10 | 26.10 | 26.10 | 26.10 | 26.10 | 26.10 | 26.10 | 26.10 | 26.10 | 26.10 | 26.10 | 26.10 |
| BF-4 | 2.00 | 2.00 | 2.00 | 2.00 | 2.00 | 2.00 | 2.00 | 2.00 | 2.00 | 2.00 | 2.00 | 2.00 | 2.00 | 2.00 |

TABLE 12

Secondphotosensitiveresin composition

| | 1f | 2f | 3f | 4f | 5f | 6f | 7f | 8f | 9f | 10f | 11f |
|---|---|---|---|---|---|---|---|---|---|---|---|
| BA-1 | 22.59 | 22.59 | 22.59 | 22.59 | 22.59 | 22.59 | 22.59 | 22.59 | 22.59 | 22.59 | 22.64 |
| BB-1 | 3.30 | 3.30 | 3.30 | 3.30 | 3.30 | 3.30 | 3.30 | 3.30 | 4.00 | 2.30 | 3.45 |
| BB-2 | 2.10 | - | - | - | - | - | 2.10 | 2.10 | - | - | - |
| BB-3 | - | 2.10 | - | - | - | - | - | - | - | - | - |
| BB-4 | - | - | 2.10 | - | - | - | - | - | - | - | - |
| BB-5 | - | - | - | 2.10 | - | - | - | - | - | - | - |
| BB-6 | - | - | - | - | 2.10 | - | - | - | 0.70 | 0.75 | 0.80 |
| BB-7 | - | - | - | - | - | 2.10 | - | - | 0.70 | 0.75 | - |
| BB-8 | - | - | - | - | - | - | - | - | - | 1.60 | - |
| BB-9 | - | - | - | - | - | - | - | - | - | - | 1.10 |
| BC-1 | 0.80 | 0.80 | 0.80 | 0.80 | 0.80 | 0.80 | 0.80 | 0.80 | 0.80 | 0.80 | 0.80 |
| BC- 2 | 0.07 | 0.07 | 0.07 | 0.07 | 0.07 | 0.07 | | | 0.07 | 0.07 | 0.07 |
| BC-3 | - | - | - | - | - | - | 0.07 | - | - | - | - |
| BC-4 | - | - | - | - | - | - | - | 0.07 | - | - | - |
| BC-5 | - | - | - | - | - | - | - | - | - | - | - |
| BC-6 | - | - | - | - | - | - | - | - | - | - | - |
| BC-7 | - | - | - | - | - | - | - | - | - | - | - |
| BC-8 | - | - | - | - | - | - | - | - | - | - | - |
| BC-9 | - | - | - | - | - | - | - | - | - | - | - |
| BC-10 | - | - | - | - | - | - | - | - | - | - | - |
| BD-1 | 0.04 | 0.035 | 0.035 | 0.035 | 0.04 | 0.035 | 0.04 | 0.04 | 0.04 | 0.04 | 0.04 |
| BD-2 | 0.00 | 0.00 11 | 0.0011 | 0.0011 | 0.00 | 0.001 1 | 0.05 | 0.00 | 0.05 | 0.00 | 0.00 |
| BE-1 | 0.05 | 0.05 | 0.05 | 0.05 | 0.05 | 0.05 | 0.05 | 0.05 | 0.05 | 0.05 | 0.05 |
| BE-2 | 1.80 | 1.80 | 1.80 | 1.80 | 1.80 | 1.80 | 1.80 | 1.80 | 1.80 | 1.80 | 1.80 |
| BE-5 | 0.12 | 0.12 | 0.12 | 0.12 | 0.12 | 0.12 | 0.12 | 0.12 | 0.12 | 0.12 | 0.12 |
| BE-6 | 0.05 | 0.05 | 0.05 | 0.05 | 0.05 | 0.05 | 0.05 | 0.05 | 0.05 | 0.05 | 0.05 |
| BF-1 | 40.98 | 40.88 | 40.98 | 40.98 | 40.98 | 40.98 | 40.98 | 40.98 | 40.98 | 40.98 | 40.98 |
| BF-2 | 26.10 | 26.10 | 26.10 | 26.10 | 26.10 | 26.10 | 26.10 | 26.10 | 26.10 | 26.10 | 26.10 |
| BF-4 | 2.00 | 2.00 | 2.00 | 2.00 | 2.00 | 2.00 | 2.00 | 2.00 | 2.00 | 2.00 | 2.00 |

### Preparation of Transfer Material

By using a slit-like nozzle, the surface of a temporary support (polyethylene terephthalate film, thickness: 16 µm, haze: 0.12%) was coated with the thermoplastic resin composition described in Table 13 or 14, such that the coating width was 1.0 m and the layer thickness was 3.0 µm after drying. The thermoplastic resin composition was dried at 80° C. for 40 seconds, thereby forming a thermoplastic resin layer.

By using a slit-like nozzle, the surface of the thermoplastic resin layer was coated with the interlayer composition described in Table 13 or 14, such that the coating width was 1.0 m and the layer thickness was 1.2 µm after drying. The interlayer composition 2 was dried at 80° C. for 40 seconds, thereby forming an interlayer.

By using a slit-like nozzle, the surface of the interlayer was coated with the photosensitive resin composition described in Table 13 or 14, such that the coating width was 1.0 m and the layer thickness was 3.0 µm after drying. The photosensitive resin composition was dried at 100° C. for 2 minutes, thereby forming a photosensitive layer.

A protective film (polypropylene film, thickness: 12 µm, haze: 0.2%) was disposed on the surface of the photosensitive layer.

Through the above procedure, a transfer material was prepared (see Table 13 or 14).

### Preparation of Laminate

The transfer material selected according to the description in Table 13 or 14 was cut in 50 cm x 50 cm, and the protective film was peeled off from the transfer material. Then, under lamination conditions of a roll temperature of 90° C., a linear pressure of 0.8 MPa, and a linear speed of 3.0 m/min, the transfer material was bonded to both surfaces of a substrate (polyethylene terephthalate film, thickness: 40 µm). Specifically, a transfer material for forming the first photosensitive layer (that is, a first transfer material) was bonded to one surface of the substrate, and a transfer material (that is, a second transfer material) for forming the second photosensitive layer was bonded to the other surface of the substrate. Through the above procedure, a laminate was prepared.

### Pattern Formation

According to the method described above in the section of “Pattern formation”, a substrate with a resin pattern was prepared.

### Evaluation

By using the substrates with a resin pattern, resolution and exposure fogging were evaluated according to the evaluation method described above. The evaluation results are shown in Table 13 or 14.

TABLE 13

| | First photosensitive layer | | | Second photosensitive layer | | | Exposure conditions | | | | S₁₂/S₁₁ | S₂₁/S₂₂ | Exposure fogging | Resolution on first photosensitive material side | Resolution on second photosensitive material side |
|---|---|---|---|---|---|---|---|---|---|---|---|---|---|---|---|
| | | | | | | | First photosensitive layer | | Second photosensitive layer | | | | | | |
| | Thermoplastic resin composition | Interlayer composition | Photosensitive resin composition | Thermoplastic resin composition | Interlayer composition | Photosensitive resin composition | Exposure wavelength | Exposure xxxxx [ml/cm²] | Exposure wavelength | Exposure amount [ml/cm²] | | | | | |
| Example 74 | A5a | 1h | 1c | A2a | 1b | 1f | Not including wavelength of 405 nm or less | 130 | Not including wavelength of 405 nm or more | 60 | 7.6 | 4.6 | A | A | A |
| Example 75 | A5a | 1b | 2c | A2a | 1b | 1f | Not including wavelength of 405 nm or less | 130 | Not including wavelength of 405 nm or more | 60 | 7.6 | 4.6 | A | A | A |
| Example 76 | A5a | 1b | 3c | A2a | 1b | 1f | Not including wavelength of 405 nm or less | 130 | Not including wavelength of 405 nm or more | 60 | 7.4 | 4.6 | A | A | A |
| Example 77 | A5a | 1b | 4c | A2a | 1b | 1f | Not including wavelength of 405 nm or less | 130 | Not including wavelength of 405 nm or more | 60 | 7.2 | 4.6 | A | A | A |
| Example 78 | A5a | 1b | 5c | A2a | 1b | 1f | Not inluding wavelength of 405 nm or less | 130 | Not including wavelength of 405 nm or more | 60 | 7.3 | 4.6 | A | B | A |
| Example 79 | A5a | 1b | 6c | A2a | 1b | 1f | Not including wavelength of 405 nm or less | 130 | Not including wavelength of 405 nm or more | 60 | 7.2 | 4.6 | A | B | A |
| Example 80 | A5a | 1b | 7c | A2a | 1b | 1f | Not including wavelength of 405 nm or less | 130 | Not including wavelength of 405 nm or more | 60 | 5.9 | 4.6 | A | A | A |
| Example 81 | A5a | 1b | 8c | A2a | 1b | 1f | Not including wavelength of 405 nm or less | 150 | Not including wavelength of 405 nm or more | 60 | 6.4 | 4.6 | | A | A |
| Example 82 | A5a | 1b | 9c | A2a | 1b | 1f | Not including wavelength of 405 nm or less | 120 | Not including wavelength of 405 nm or more | 60 | 7.8 | 4.6 | A | A | A |
| Example 83 | A5a | 1b | 10c | A2a | 1b | 1f | Not including wavelength of 405 nm or less | 120 | Not including wavelength of 405 nm or more | 60 | 7.8 | 4.6 | A | A | A |
| Example 84 | A5a | 1b | 11c | A2a | 1b | 1f | Not including wavelength of 405 nm or less | 130 | Not including wavelength of 405 nm or more | 60 | 7.9 | 4.6 | A | A | A |
| Example 85 | A5a | 1b | 12c | A2a | 1b | 1f | Not including wavelength of 405 nm or less | 130 | Not including wavelength of 405 nm or more | 60 | 6.0 | 4.6 | A | A | A |
| Example 86 | A5a | 1b | 13c | A2a | 1b | 1f | Not including wavelength of 405 nm or less | 130 | Not including wavelength of 405 nm or more | 60 | 5.9 | 4.6 | A | A | A |
| Example 87 | A5a | 1b | 14c | A2a | 1b | 1f | Not including wavelength of 405 nm or less | 130 | Not including wavelength of 405 nm or more | 60 | 5.8 | 4.6 | A | A | A |
| Example 88 | A5a | 1b | 1c | A2a | 1b | 2f | Not including wavelength of 405 nm or less | 130 | Not including waveleength of 405 nm or more | 60 | 7.6 | 4.6 | A | A | A |
| Example 89 | A5a | 1b | 1c | A2a | 1b | 3f | Not including wavelength of 405 nm or less | 130 | Not including wavelength of 405 nm or more | 60 | 7.6 | 4.2 | A | A | A |
| Example 90 | A5a | 1b | 1c | A2a | 1b | 4f | Not including wavelength of 405 nm or less | 130 | Not including wavelength of 405 nm or more | 60 | 7.6 | 4.5 | A | A | A |
| Example 91 | A5a | 1b | 1c | A2a | 1b | 5f | Not including wavelength of 405 nm or less | 130 | Not including wavelength of 405 nm or more | 60 | 7.6 | 4.4 | A | A | B |
| Example 92 | A5a | 1b | 1c | A2a | 1b | 6f | Not including wavelength of 405 nm or less | 130 | Not including wavelength of 405 nm or more | 60 | 7.6 | 4.2 | A | A | B |
| Example 93 | A5a | 1b | 1e | A2a | 1b | 7f | Not including wavelength of 405 nm or less | 130 | Not including wavelength of 405 nm or more | 60 | 7.6 | 4.7 | A | A | A |
| Example 94 | A5a | 1b | 1e | A2a | 1b | 8f | Not including wavelength of 405 nm or less | 130 | Not including wavelength of 405 nm or more | 80 | 7.6 | 3.7 | A | A | A |
| Example 95 | A5a | 1b | 1c | A2a | 1b | 9f | Not including wavelength of 405 nm or less | 130 | Not including wavelength of 405 nm or more | 60 | 7.6 | 4.2 | A | A | A |
| Example 96 | A5a | 1b | 1c | A2a | 1b | 10f | Not including wavelength of 405 nm or less | 130 | Not including wavelength of 405 nm or more | 60 | 7.6 | 4.1 | A | A | A |
| Example 97 | A5a | 1b | 1c | A2a | 1b | 11f | Not including wavelength of 405 nm or less | 130 | Not including wavelength of 405 nm or more | 60 | 7.6 | 4.2 | A | A | A |
| Example 98 | A5a | 1b | 1e | A2a | 1b | 1f | Not including 365 nm | 130 | Not including 405 nm | 60 | 7.6 | 4.1 | A | A | A |

TABLE 14

| | First photosensitive layer | | | Sound photosensitive layer | | | Exposure conditions | | | | Sis Sir | Su Sig | Exposue fogging | Resolution on first photosensitive material side | Resolution on second photosensitive material side |
|---|---|---|---|---|---|---|---|---|---|---|---|---|---|---|---|
| | | | | | | | First photosensitive layer | | Second photosensitive layer | | | | | | |
| | Thermoplastic composition | Interlayer composition | Photosensitive resin composition | Themoplastic resin comotion | Interlayer composition | photosensitive resin composition | Exposure wavelength | Exposure amount [ml/cm] | Exposure wavelength | Exposure amount [ml/cm] | | | | | |
| Example 99 | A7a | 1b | 1c | A2a | 1b | 1f | Not including wavelength of 405 nm or less | 130 | Not including wavelength of 40 nm or more | 60 | 9.0 | 4.6 | A | A | A |
| Example 100 | A8a | 1b | 1k | A2a | 1b | 1f | Not including wavelength of 405 nm or less | 130 | Not including wavelength of 40 nm or more | 60 | 9.2 | 4.6 | A | A | A |
| Example 101 | A9a | 1b | 1c | A2a | 1b | 1f | Not including wavelength of 405 nm or less | 130 | Not including wavelength of 40 nm or more | 60 | 9.0 | 4.6 | A | A | A |
| Example 102 | A10a | 1b | 1k | A2a | 1b | 1f | Not including wavelength of 405 nm or less | 130 | Not including wavelength of 40 nm or more | 60 | 9.1 | 4.6 | A | A | A |
| Example 103 | A11a | 1b | 1k | A2a | 1b | 1f | Not including wavelength of 405 nm or less | 130 | Not including wavelength of 40 nm or more | 60 | 8.3 | 4.6 | A | A | A |
| Example 104 | A12a | 1b | 1e | A2a | 1b | 1f | Not including wavelength of 405 nm or less | 130 | Not including wavelength of 40 nm or more | 60 | 9.4 | 4.6 | A | A | A |
| Example 105 | A13a | 1b | 1k | A2a | 1b | 1f | Not including wavelength of 405 nm or less | 130 | Not including wavelength of 40 nm or more | 60 | 8.5 | 4.6 | A | A | A |
| Example 106 | A14a | 1b | 1k | A2a | 1b | 1f | Not including wavelength of 405 nm or less | 130 | Not including wavelength of 40 nm or more | 60 | 9.3 | 4.6 | A | A | A |
| Example 107 | A15a | 1b | 1k | A2a | 1b | 1f | Not including wavelength of 405 nm or less | 130 | Not including wavelength of 40 nm or more | 60 | 9.4 | 4.6 | A | A | A |

The laminates of Examples 74 to 107 satisfied the characteristics A and B.

The meanings and exposure conditions of “not including a wavelength of 405 nm or less”, “not including a wavelengths of 405 nm or more”, “not including 365 nm”, and ”“not including 405 nm” are the same as described above.

As is evident from Tables 13 and 14, the laminate according to the present disclosure could be excellent in exposure fogging and resolution performance.

### Preparation of Thermoplastic Resin Composition, Interlayer Composition, and Photosensitive in Composition

The components described in Tables 15 to 17 were mixed together, thereby preparing a thermoplastic resin composition, an interlayer composition, and a photosensitive resin composition.

The abbreviations for the components described in Tables 15 to 17 means the following.
EA-1: propylene glycol monomethyl ether acetate solution of styrene/methacrylic acid/methyl methacrylate = 52/29/19 (% by mass) copolymer (concentration of solid contents 30.0%, Mw 70,000)
EA-2: propylene glycol monomethyl ether acetate solution of copolymer of benzyl methacrylate, methacrylic acid, and acrylic acid (concentration of solid contents 30.0%, Mw 30,000, acid value 153 mgKOH/g)
EA-3: KURARAY POVAL PVA-205 (manufactured by KURARAY CO., LTD.)
EA-4: polyvinylpyrrolidone K-30 (manufactured by NIPPON SHOKUBAI CO., LTD.)
EB-1: NK ESTER BPE-500 (manufactured by SHIN-NAKAMURA CHEMICAL CO, LTD.)
EB-2: NK ESTER HD-N (manufactured by SHIN-NAKAMURA CHEMICAL CO, LTD.)
EB-3: NK ESTER A-DCP (manufactured by SHIN-NAKAMURA CHEMICAL CO, LTD.)
EB-4: 8UX-015A (manufactured by TAISEI FINE CHEMICAL CO., LTD.): 2.31 parts
EB-5: ARONIX TO-2349 (manufactured by TOAGOSEI CO., LTD.)
EB-6: LIGHT ACRYLATE DPE-6A (manufactured by KYOEISHA CHEMICAL CO., LTD.)
EC-1: B-CIM (manufactured by KUROGANE KASEI Co., Ltd.)
EC-2: SB-PI 701 (obtained from SANYO TRADING CO., LTD.)
EC-3: 3-acetyl-7-(diethylamino)coumarin (manufactured by FUJIFILM Wako Pure Chemical Corporation)
EC-4: Irgacure OXE02 (manufactured by BASF Japan Ltd.)
ED-1: TDP-G (manufactured by Kawaguchi Chemical Industry Co., LTD.)
ED-2: 1-phenyl-3-pyrazolidone (manufactured by FUJIFILM Wako Pure Chemical Corporation)
EE-1: leuco Crystal Violet (manufactured by Tokyo Chemical Industry Co., Ltd.)
EE-2: N-phenylcarbamoylmethyl-N-carboxymethylaniline (manufactured by FUJIFILM Wako Pure Chemical Corporation)
EE-3: Solvent Yellow 56 (manufactured by Tokyo Chemical Industry Co., Ltd.)
EE-4: CBT-1 (manufactured by JOHOKU CHEMICAL CO., LTD.)
EE-5: diethylamino-phenylsulfonyl-based ultraviolet absorber (manufactured by DAITO KAGAKU KOGYO K.K.)
EE-6: Tinuvin 970 (manufactured by BASF Japan Ltd.)
EE-7: MEGAFACE F-552 (manufactured by DIC Corporation)
EE-8: MEGAFACE F-444 (manufactured by DIC Corporation)
EF-1: methyl ethyl ketone (manufactured by SANKYO CHEMICAL CO., LTD.)
EF-2: propylene glycol monomethyl ether acetate (manufactured by SHOWA DENKO K.K.)
EF-3: deionized water
EF-4: methanol (manufactured by MITSUBISHI GAS CHEMICAL COMPANY, INC.)

TABLE 15

| Thermoplastic resin composition | B1a | B2a | B3a | B4a |
|---|---|---|---|---|
| EA-2 | 42.85 | 42.02 | 42.15 | 41.82 |
| EB-3 | 5.03 | 5.03 | 5.03 | 5.03 |
| EB-4 | 2.31 | 2.31 | 2.31 | 2.31 |
| EB-5 | 0.77 | 0.77 | 0.77 | 0.77 |
| EE-3 | - | 0.25 | - | - |
| EE-5 | - | - | 0.10 | 0.10 |
| EE-6 | - | - | - | 0.10 |
| EE-7 | 0.03 | 0.03 | 0.03 | 0.03 |

TABLE 16

| Interlayer composition | B1b |
|---|---|
| EA-3 | 3.22 |
| EA-4 | 1.49 |
| EE-8 | 0.00 |
| EF-3 | 38.12 |
| EF-4 | 57.17 |

TABLE 17

| Photosensitive resin composition | First photosensitive resin composition | Second photosensitive resin composition |
|---|---|---|
| | B1c | B1d |
| EA-1 | 21.83 | 22.59 |
| EB-1 | 3.30 | 3.30 |
| EB-2 | 2.10 | 2.10 |
| EC-1 | 1.00 | 0.80 |
| EC-2 | - | 0.07 |
| EC-3 | 0.15 | - |
| ED-1 | 0.02 | 0.04 |
| ED-2 | 0.00 | 0.00 |
| EE-1 | 0.05 | 0.05 |
| EE-2 | 1.80 | 1.80 |
| EE-4 | - | - |
| EE-4 | 0.12 | 0.12 |
| EE-7 | 0.05 | 0.05 |
| EF-1 | 41.48 | 40.98 |
| EF-2 | 26.10 | 26.10 |
| EF-4 | 2.00 | 2.00 |

The numerical value of each component in Tables 15 to 17 represents the mass ratio.

### Example 108

### Preparation of Photosensitive Transfer Material

By using a slit-like nozzle, a temporary support (polyethylene terephthalate film, thickness: 16 µm, haze: 0.12%) was coated with the thermoplastic resin composition described in Table 18, such that the coating width was 1.0 m and the layer thickness was 3.0 µm after drying. The formed coating film of the thermoplastic resin composition was dried at 80° C. for 40 seconds, thereby forming a thermoplastic resin layer.

By using a slit-like nozzle, the surface of the formed thermoplastic resin layer was coated with THE interlayer composition described in Table 18, such that the coating width was 1.0 m and the layer thickness was 1.2 µm after drying. The coating film of the interlayer composition was dried at 80° C. for 40 seconds, thereby forming an interlayer.

By using a slit-like nozzle, the surface of the formed interlayer was coated with the composition for forming a photosensitive layer described in Table 18, such that the coating width was 1.0 m and the layer thickness was 3.0 µm after drying, followed by drying for 2 minutes in a convection oven at 100° C., thereby forming a photosensitive layer. A protective film (polypropylene film, thickness: 12 µm, haze: 0.2%) was bonded to the photosensitive layer, thereby preparing a photosensitive transfer material 108A.

In addition, a photosensitive transfer material 108B consisting of a thermoplastic resin layer, an interlayer, and a photosensitive layer was prepared in the same manner as described above, except that each of the compositions described in Table 18 was used.

### Preparation of Laminate

The photosensitive transfer material 108A selected according to the description in Table 18 was cut in 50 cm x 50 cm, and the protective film was peeled off from the photosensitive transfer material 108A. Then, under the lamination conditions of a roll temperature of 90° C., a linear pressure of 0.8 MPa, and a linear velocity of 3.0 m/min, the photosensitive transfer material 108A from which the protective film was peeled off was bonded to both surfaces of a substrate (film including a substrate that consists of a polyethylene terephthalate film and a conductive layer that is laminated on both surfaces of the substrate and contains a resin in which silver nanowires are dispersed, trade name: ClearOhm, manufactured by Cambrios film solutions). Specifically, the photosensitive transfer material 108A (that is, a first transfer material) for forming the first photosensitive layer was bonded to one surface of the substrate, and the photosensitive transfer material 108B (that is, a second transfer material) for forming the second photosensitive layer was bonded to the other surface of the substrate. Through the above procedure, a laminate was prepared.

### Preparation of Wiring Circuit

A glass mask on which a wiring pattern was drawn was closely attached to both surfaces of the laminate without peeling off the temporary support. Under the conditions described in Table 18, the first photosensitive layer and the second photosensitive layer were exposed simultaneously. In a case where the first photosensitive layer and the second photosensitive layer are exposed simultaneously, the first photosensitive layer was exposed from a side of the substrate on which the first photosensitive layer is disposed, and the second photosensitive layer is exposed from a side of the substrate on which the second photosensitive layer is disposed.

The meanings of “not including wavelength of 405 nm or less” and “not including wavelength of 405 nm or more” in Table 18 are as follows.

“Exposure conditions not including wavelength of 405 nm or less”: the photosensitive layer was exposed through a short wavelength cut filter (model number: LU0422, cutoff wavelength: 422 nm, manufactured by Asahi Spectra Co., Ltd.) by using an ultra-high-pressure mercury lamp (USH-2004MB, manufactured by Ushio Inc.). The dominant wavelength is 436 nm. In a case where the intensity of the dominant wavelength is 100%, the intensity at the wavelength of 365 nm is 0.5% or less.

“Not including wavelength of 405 nm or more”: the photosensitive layer was exposed through a bandpass filter for mercury exposure (model number: HB0365, central wavelength: 365 nm, manufactured by Asahi Spectra Co., Ltd.) by using an ultra-high-pressure mercury lamp (USH-2004MB, manufactured by Ushio Inc.). The dominant wavelength is 365 nm. In a case where the intensity of the dominant wavelength is 100%, the intensity at wavelengths of 405 nm and 436 nm is 0.5% or less.

In addition, in the case of exposure conditions not including a wavelength of 405 nm or less, the exposure amount was measured through the aforementioned LU0422 cut filter by mounting an optical receiver for 405 nm (UVD-C405, manufactured by Ushio Inc.) on an illuminance meter (UIT-250, manufactured by Ushio Inc.). In the case of exposure conditions not including a wavelength of 405 nm or more, the exposure amount was measured through the aforementioned bandpass filter (HB0365) by mounting an optical receiver for 365 nm (UVD-C365, manufactured by Ushio Inc.) on an illuminance meter.

After the exposed photosensitive layer was left to stand for 1 hour, the temporary support was peeled off, and then a resin pattern was formed by development. By using a 1.0% aqueous potassium carbonate solution (developer) at 28° C., the photosensitive layer was developed for 30 seconds by shower development. The first photosensitive layer and the second photosensitive layer were developed simultaneously.

Wet etching was performed on the obtained resist pattern, such that silver nanowires in the portion where the resist pattern was not formed were removed. The resist pattern was etched for 60 seconds by shower etching using a 40% aqueous ferric nitrate (III) solution at 40° C.

After the etching, a 2.38% aqueous TMAH solution at 60° C. was sprayed on the residual resist pattern by shower such that the resist was removed, thereby obtaining a wiring pattern. The obtained wiring pattern had excellent electrical characteristics on both surfaces of the substrate.

### Examples 109 to 111

A wiring pattern was formed in the same manner as in Example 108, except that the photosensitive transfer material described in Table 18 was used. As in Example 108, a wiring pattern having excellent electrical characteristics was obtained.

### Example 112

### Preparation of Photosensitive Transfer Material

By using a slit-like nozzle, a temporary support (polyethylene terephthalate film, thickness: 16 µm, haze: 0.12%) was coated with the thermoplastic resin composition described in Table 18, such that the coating width was 1.0 m and the layer thickness was 3.0 µm after drying. The formed coating film of the thermoplastic resin composition was dried at 80° C. for 40 seconds, thereby forming a thermoplastic resin layer.

By using a slit-like nozzle, the surface of the formed thermoplastic resin layer was coated with THE interlayer composition described in Table 18, such that the coating width was 1.0 m and the layer thickness was 1.2 µm after drying. The coating film of the interlayer composition was dried at 80° C. for 40 seconds, thereby forming an interlayer.

By using a slit-like nozzle, the surface of the formed interlayer was coated with the composition for forming a photosensitive layer described in Table 18, such that the coating width was 1.0 m and the layer thickness was 3.0 µm after drying, followed by drying for 2 minutes in a convection oven at 100° C., thereby forming a photosensitive layer. A protective film (polypropylene film, thickness: 12 µm, haze: 0.2%) was bonded to the photosensitive layer, thereby preparing a photosensitive transfer material 112A.

In addition, a photosensitive transfer material 112B consisting of a thermoplastic resin layer, an interlayer, and a photosensitive layer was prepared in the same manner as described above, except that each of the compositions described in Table 18 was used.

### Preparation of Laminate

A conductive substrate (film including a substrate that consists of a polyethylene terephthalate film and a conductive layer that is laminated on both surfaces of the substrate and contains a resin in which silver nanowires are dispersed, trade name: ClearOhm, manufactured by Cambrios film solutions) was coated with an organic film-forming liquid having the following composition, such that the film thickness was 30 nm after drying. Specifically, one surface of the conductive substrate was coated with the organic film-forming liquid and pre-baked at 100° C. for 2 minutes, and then the other surface was coated with the liquid under the same conditions and then pre-baked under the same conditions. Thereafter, the conductive substrate was exposed from both surfaces to a high-pressure mercury lamp at 1,000 mJ/cm². The conductive substrate was then post-baked at 140° C. for 30 minutes, thereby forming an organic film on the conductive substrate.

### Organic Film-Forming Liquid

EA-2: 1.7 parts

EB-6: 0.41 parts

EC-4: 0.01 parts

EF-1: 47.88 parts

EF-2: 50 parts

The photosensitive transfer materials 112A and 112B were cut in 50 cm x 50 cm, and the protective film was peeled off from the transfer material. Then, under the lamination conditions of a roll temperature of 90° C., a linear pressure of 0.8 MPa, and a linear velocity of 3.0 m/min, the transfer material was bonded to both surfaces of the conductive substrate on which the organic film was formed as above. Specifically, the photosensitive transfer material 112A (that is, a first photosensitive transfer material) for forming the first photosensitive layer was bonded to one surface of the substrate, and the photosensitive transfer material 112B (that is, a second photosensitive transfer material) for forming the second photosensitive layer was bonded to the other surface of the substrate. Through the above procedure, a laminate was prepared.

### Preparation of Wiring Circuit

A wiring circuit was prepared in the same manner as in Example 108. The obtained wiring pattern had excellent electrical characteristics on both surfaces of the substrate.

### Examples 113 to 115

A wiring pattern was formed in the same manner as in Example 112, except that the photosensitive transfer material described in Table 18 was used. As in Example 112, a wiring pattern having excellent electrical characteristics was obtained.

TABLE 18

| | First photosensitive layer | | | | Second photosenstive layer | | | | Exposure conditions | | | |
|---|---|---|---|---|---|---|---|---|---|---|---|---|
| | | | | | | | | | First photosenstive layer | | Second photosenstive layer | |
| | Thermoplastic resin composition | Interlayer composition | Photosenstive resin composition | Photosensitive transfer material | Thermoplastic resin composition | Interlayer composition | Photosensitive resin composition | Photosensitive transfer material | Exposure wavelength | Exposure amount [mlcm¹] | Exposure wavelength | Exposure amount [mlcm¹] |
| Example 108 | B3a | B1b | B1c | 108A | B1a | B1b | B1d | 108B | Not including wavelength of 405 nm or less | 130 | Not including wavelength of 405 nm or more | 60 |
| Example 109 | B4a | B1b | B1c | 109A | B1a | B1b | B1d | 109B | Not including wavelength of 405 nm or less | 130 | Not including wavelength of 405 nm or more | 60 |
| Example 110 | B3a | B1b | B1c | 110A | B2a | B1b | B1d | 110B | Not including wavelength of 405 nm or less | 130 | Not including wavelength of 405 nm or more | 60 |
| Example 111 | B4a | B1b | B1c | 111A | B2a | B1b | B1d | 111B | Not including wavelength of 405 nm or less | 130 | Not inlcuding wavelength of 405 nm or more | 60 |
| Example 112 | B3a | B1b | B1c | 112A | B1a | B1b | B1d | 112B | Not including wavelength of 405 nm or less | 130 | Not including wavelength of 405 nm or more | 60 |
| Example 113 | B4a | B1b | B1c | 113A | B1a | B1b | B1d | 113B | Not including wavelength of 405 nm or less | 130 | Not including wavelength of 405 nm or more | 60 |
| Example 114 | B3a | B1b | B1c | 114A | B2a | B1b | B1d | 114B | Not including wavelength of 405 nm or less | 130 | Not including wavelength of 405 nm or more | 60 |
| Example 115 | B4a | B1b | B1c | 115A | B2a | B1b | B1d | 115B | Not including wavelength of 405 nm or less | 130 | Not including wavelength of 405 nm or more | 60 |

The entirety of the disclosure of Japanese Patent Application No. 2020-090044 filed on May 22, 2020, the disclosure of Japanese Patent Application No. 2020-130726 filed on Jul. 31, 2020, the disclosure of Japanese Patent Application No. 2020-165594 filed on Sep. 30, 2020, the disclosure of Japanese Patent Application No. 2020-199018 filed on Nov. 30, 2020, the disclosure of Japanese Patent Application No. 2020-215028 filed on Dec. 24, 2020, the disclosure of Japanese Patent Application No. 2021-069927 filed on Apr. 16, 2021 are incorporated into the present specification by reference.

All of documents, patent applications, and technical standards described in the present specification are incorporated into the present specification by reference to approximately the same extent as a case where it is specifically and respectively described that the respective documents, patent applications, and technical standards are incorporated by reference.

What is claimed is:

1. A pattern forming method comprising:
a step of preparing a laminate having a first photosensitive layer, a substrate having a region transparent to an exposure wavelength, and a second photosensitive layer in this order;
a step of exposing the first photosensitive layer;
a step of exposing the second photosensitive layer;
a step of developing the exposed first photosensitive layer to form a first resin pattern; and
a step of developing the exposed second photosensitive layer to form a second resin pattern;
wherein a dominant wavelength λ₁ of an exposure wavelength in the step of exposing the first photosensitive layer and a dominant wavelength λ₂ of an exposure wavelength in the step of exposing the second photosensitive layer satisfy a relation of λ₁ ≠ λ₂.

2. The pattern forming method according to claim 1,
wherein a photosensitive compound contained in the first photosensitive layer is different from a photosensitive compound contained in the second photosensitive layer.

3. The pattern forming method according to claim 1,
wherein the following relations 1 and 2 are satisfied for the first photosensitive layer and the second photosensitive layer,
$$1.1 \leq {\text{E}}_{1 \text{r}} / {\text{E}}_{2} \qquad \text{Relation 1:}$$
$$1.1 \leq {\text{E}}_{\text{2r}} / {\text{E}}_{1} \qquad \text{Relation 2:}$$
where E₁ᵣ represents a maximum exposure amount at which the first photosensitive layer does not react in a case where the first photosensitive layer is exposed to light having the dominant wavelength λ₂ from a side of the second photosensitive layer of the laminate, E₂ represents an exposure amount in a case where the second photosensitive layer is exposed to light having the dominant wavelength λ₂ in the step of exposing the second photosensitive layer, E₂ᵣ represents a maximum exposure amount at which the second photosensitive layer does not react in a case where the second photosensitive layer is exposed to light having the dominant wavelength λ₁ from a side of the first photosensitive layer of the laminate, and E₁ represents an exposure amount in a case where the first photosensitive layer is exposed to light having the dominant wavelength λ₁ in the step of exposing the first photosensitive layer.

4. The pattern forming according to claim 1,
wherein the following relations 3 and 4 are satisfied for the first photosensitive layer and the second photosensitive layer,
$$3 \leq {\text{S}}_{12} / {\text{S}}_{11} \qquad \text{Relation 3:}$$
$$3 \leq {\text{S}}_{21} / {\text{S}}_{22} \qquad \text{Relation 4:}$$
where S₁₂ represents a spectral sensitivity of the first photosensitive layer to the dominant wavelength λ₂, S₁₁ represents a spectral sensitivity of the first photosensitive layer to the dominant wavelength λ₁, S₂₁ represents a spectral sensitivity of the second photosensitive layer to the dominant wavelength λ₁, and S₂₂ represents a spectral sensitivity of the second photosensitive layer to the dominant wavelength λ₂.

5. The pattern forming method according to claim 1,
wherein the first photosensitive layer contains a substance absorbing light having the dominant wavelength λ₂, and/or the second photosensitive layer contains a substance absorbing light having the dominant wavelength λ₁.

6. The pattern forming method according to claim 1,
wherein the laminate has at least one layer selected from the group consisting of a layer that is disposed between the substrate and the first photosensitive layer and contains a substance absorbing light having the dominant wavelength λ₂, a layer that is disposed on the substrate via the first photosensitive layer and contains a substance absorbing light having the dominant wavelength λ₂, a layer that is disposed between the substrate and the second photosensitive layer and contains a substance absorbing light having the dominant wavelength λ₁, and a layer that is disposed on the substrate via the second photosensitive layer and contains a substance absorbing light having the dominant wavelength λ₁.

7. The pattern forming method according to claim 5,
wherein either the substance absorbing light having the dominant wavelength λ₂ or the substance absorbing light having the dominant wavelength λ₁ is a substance having a maximum absorption wavelength λₘₐₓ in a wavelength range of 400 nm or more.

8. The pattern forming method according to claim 1,
wherein a member absorbing light having the dominant wavelength λ₂ is disposed between the first photosensitive layer and a light source for exposing the first photosensitive layer and/or a member absorbing light having the dominant wavelength λ₁ is disposed between the second photosensitive layer and a light source for exposing the second photosensitive layer.

9. The pattern forming method according to claim 8,
wherein either the member absorbing light having the dominant wavelength λ₂ or the member absorbing light having the dominant wavelength λ₁ is a member containing a substance having a maximum absorption wavelength λₘₐₓ in a wavelength range of 400 nm or more.

10. The pattern forming method according to claim 1,
wherein the laminate has at least one conductive layer on at least one surface of the substrate.

11. The pattern forming method according to claim 1,
wherein the laminate has at least one conductive layer on both surfaces of the substrate.

12. The pattern forming method according to claim 1,
wherein the laminate has at least one conductive layer on at least one surface of the substrate, and
a conductive layer having a composition different from a composition of the conductive layer is additionally formed on at least a partial region of the conductive layer.

13. The pattern forming method according to claim 1,
wherein the laminate has at least one conductive layer on at least one surface of the substrate, and
the conductive layer has two or more regions having different compositions within the substrate.

14. The pattern forming method according to claim 10,
wherein at least one of the conductive layers is a layer containing a metal oxide.

15. The pattern forming method according to claim 10,
wherein at least one of the conductive layers is a layer containing at least one material selected from the group consisting of metal nanowires and metal nanoparticles.

16. The pattern forming method according to claim 10, further comprising:
a step of etching the conductive layers by using at least either the first resin pattern or the second resin pattern as a mask.

17. The pattern forming method according to claim 1,
wherein the first photosensitive layer and the second photosensitive layer each independently comprise a polymer having an acid group, a polymerizable compound, and a photopolymerization initiator.

18. The pattern forming method according to claim 17,
wherein the polymerizable compound comprises an alkylene oxide-modified bisphenol A di(meth)acrylate.

19. The pattern forming method according to claim 17,
wherein the photopolymerization initiator comprises a 2,4,5-triarylimidazole dimer.

20. The pattern forming method according to claim 17,
wherein the first photosensitive layer further comprises a sensitizer.

21. The pattern forming method according to claim 20,
wherein the sensitizer comprises a coumarin compound.

22. A manufacturing method of a circuit board, comprising:
the pattern forming method according to claim 1.

23. A laminate comprising, in the following order:
a first photosensitive layer;
a substrate; and
a second photosensitive layer,
wherein the laminate has the following characteristics A and B,
characteristic A: in a case where λₘ₁ represents a maximum sensitivity wavelength of the first photosensitive layer and λₘ₂ represents a maximum sensitivity wavelength of the second photosensitive layer, λₘ₁ and λₘ₂ satisfy a relation of λₘ₁ ≠ λₘ₂ where the maximum sensitivity wavelength refers to a wavelength at which a minimum exposure amount is the smallest in a case where the minimum exposure amount at which the photosensitive layers react is determined as a spectral sensitivity for each wavelength of light,
characteristic B: the substrate has a transmittance of at least 50% or more for light having the wavelengths λₘ₁ and λₘ₂.

24. The laminate according to claim 23,
wherein the wavelength λₘ₁ is in a range of more than 395 nm and 500 nm or less, and
the wavelength λₘ₂ is in a range of 250 nm or more and 395 nm or less.

25. The laminate according to claim 23,
wherein the first photosensitive layer contains a substance absorbing light having the wavelength λₘ₂.

26. The laminate according to claim 23,
wherein the second photosensitive layer contains a substance absorbing light having the wavelength λₘ₁.

27. The laminate according to claim 23,
wherein the following relations C and D are satisfied for the first photosensitive layer and the second photosensitive layer,
$$3 \leq {\text{S}}_{\text{m12}} / {\text{S}}_{\text{m11}} \qquad \text{Relation C:}$$
$$3 \leq {\text{S}}_{\text{m21}} / {\text{S}}_{\text{m22}} \qquad \text{Relation D:}$$
where Sₘ₁₂ represents a spectral sensitivity of the first photosensitive layer to the wavelength λₘ₂, Sₘ₁₁ represents a spectral sensitivity of the first photosensitive layer to the wavelength λₘ₁, Sₘ₂₁ represents a spectral sensitivity of the second photosensitive layer to the wavelength λₘ₁, and Sₘ₂₂ represents a spectral sensitivity of the second photosensitive layer to the wavelength λₘ₂.

28. The laminate according to claim 23,
wherein the first photosensitive layer has a transmittance of 70% or less for light having the wavelength λₘ₂.

29. The laminate according to claim 23,
wherein the second photosensitive layer has a transmittance of 70% or less for light having the wavelength λₘ₁.

30. The laminate according to claim 23,
wherein the laminate has at least one conductive layer on at least one surface of the substrate.

31. The laminate according to claim 23,
wherein the laminate has at least one conductive layer on at least one surface of the substrate, and
on at least a partial region of the conductive layer, a conductive layer having a composition different from a composition of the conductive layer is additionally formed.

32. The laminate according to claim 23,
wherein the laminate has at least one conductive layer on at least one surface of the substrate, and
the conductive layer has two or more regions having different compositions within the substrate.

33. The laminate according to claim 23,
wherein the laminate has at least one conductive layer on both surfaces of the substrate.

34. The laminate according to claim 30,
wherein at least one of the conductive layers is a layer containing a metal oxide.

35. The laminate according to claim 30,
wherein at least one of the conductive layers is a layer containing at least one material selected from the group consisting of metal nanowires and metal nanoparticles.

36. The laminate according to claim 23,
wherein the first photosensitive layer and the second photosensitive layer each independently comprise a polymer having an acid group, a polymerizable compound, and a photopolymerization initiator.

37. The laminate according to claim 36,
wherein the polymerizable compound comprises an alkylene oxide-modified bisphenol A di(meth)acrylate.

38. The laminate according to claim 36,
wherein the photopolymerization initiator comprises a 2,4,5-triarylimidazole dimer.

39. The laminate according to claim 36,
wherein the first photosensitive layer further comprises a sensitizer.

40. The laminate according to claim 39,
wherein the sensitizer comprises a coumarin compound.
